(19) United States
(12) Patent Application Publication
(10) Pub. No.: US 2013/0168250 A1
(43) Pub. Date: Jul. 4, 2013

(54) Droplet Actuator Systems, Devices and Methods

(71) Applicants: Michael Fogleman, Cary, NC (US); Ryan A. Sturmer, Durham, NC (US); Gregory F. Smith, Cary, NC (US)

(72) Inventors: Michael Fogleman, Cary, NC (US); Ryan A. Sturmer, Durham, NC (US); Gregory F. Smith, Cary, NC (US)

(73) Assignee: ADVANCED LIQUID LOGIC INC, Research Triangle Park, NC (US)

(21) Appl. No.: 13/822,990

(22) PCT Filed: Sep. 15, 2011
(86) PCT No.: PCT/US2011/051691

§ 371 Date: Mar. 13, 2013

Related U.S. Application Data
(60) Provisional application No. 61/383,375, filed on Sep. 16, 2010.
(60) Provisional application No. 61/385,492, filed on Sep. 22, 2010.

(51) Int. Cl. B81B 7/02

(52) U.S. Cl. CPC B81B 7/02
USPC 204/547; 204/549

(57) ABSTRACT

The present invention is directed to droplet actuator systems, devices, and methods. In one embodiment, a microfluidic article of manufacture is provided. The microfluidic article of manufacture includes a first substrate; a second substrate separated from the first substrate to form a droplet operations gap; gap height setting spacers associated with the first and/or second substrate or situated between the first and second substrates; a spring forcing the second substrate against the gap height setting spacers, thereby establishing a substantially uniform gap height between the first and second substrates; and electrodes associated with the first and/or second substrate and configured to conduct droplet operations in the droplet operations gap.

### 1 RELATED APPLICATIONS

In addition to the patent applications cited herein, each of which is incorporated herein by reference, this patent application is related to and claims priority to U.S. Provisional Patent Application Nos. 61/383,375, filed on Sep. 16, 2010, entitled “Droplet Actuator Systems, Devices and Methods”; and 61/385,492, filed on Sep. 22, 2010, entitled “Droplet Actuator Systems, Devices and Methods” the entire disclosures of which are incorporated herein by reference.

### 2 FIELD OF THE INVENTION

The present invention generally relates to droplet actuator systems, devices, and methods. In particular, the present invention is directed to droplet actuator systems, devices, and methods that improve the use of droplet actuators and other microfluidic devices.

### 3 BACKGROUND OF THE INVENTION

A droplet actuator typically includes one or more substrates configured to form a surface or droplet operations gap for conducting droplet operations. The one or more substrates establish a droplet operations gap in which droplet operations are conducted. The one or more substrates may also include electrodes arranged to conduct the droplet operations. The droplet operations substrate or the droplet operations gap between the substrates may be coated or filled with a filler fluid that is immiscible with the liquid that forms the droplets. There is a need for designs, methods, processes, and techniques that improve the use of droplet actuators and other microfluidic devices.

### 4 BRIEF DESCRIPTION OF THE INVENTION

The present invention is directed to droplet actuator systems, devices, and methods.

In one embodiment, a microfluidic article of manufacture is provided. The microfluidic article of manufacture includes a first substrate; a second substrate separated from the first substrate to form a droplet operations gap; gap height setting spacers associated with the first and/or second substrate or situated between the first and second substrates; a spring forcing the second substrate against the gap height setting spacers, thereby establishing a substantially uniform gap height between the first and second substrates; and electrodes associated with the first and/or second substrate and configured to conduct droplet operations in the droplet operations gap. The spring may be one of a set of cantilever springs formed integrally with the first substrate. The spring may include mating features, and the mating features may be affixed to corresponding mating features on the first substrate. The spring may be a flat spring or a torsion spring. The gap height setting spacers may be spacers formed as an integral component of the first substrate, spacers formed as an integral component of the second substrate, or a spacer layer situated between the first and second substrates. The electrodes may be arranged for conducting electrowetting-mediated or dielectrophoresis-mediated droplet operations. The droplet operations may be effected in a droplet operations gap. The droplet operations may include electrowetting-mediated or dielectrophoresis-mediated droplet operations.

In another embodiment, a droplet actuator apparatus is provided. The apparatus may include a droplet actuator and an impedance sensing apparatus arranged to sense impedance at the electrical control channels. The droplet actuator further includes a substrate comprising electrodes arranged for conducting droplet operations; contacts on the substrate arranged to provide electrical connectivity for coupling the substrate to an instrument for controlling the droplet operations; and electrical control channels electrically coupling the contacts with the electrodes.

In yet another embodiment, a method of testing a microfluidic chip controlled by control channels is provided. The method may include testing impedance at the control channels while selectively activating the control channels and correlating impedance with functionality of the control channels.

In still yet another embodiment, a method of measuring droplet volume in a droplet actuator is provided. The method may include providing the droplet in a droplet operations gap of a droplet actuator, the droplet having a droplet footprint which correlates to the volume of the droplet; situating the droplet atop an arrangement of electrodes wherein each electrode is significantly smaller than the droplet footprint; measuring impedance across the droplet operations gap at each electrode of the arrangement of electrodes to provide impedance measurements; using the impedance measurements to determine the footprint of the droplet; and calculating volume of the droplet based on the footprint of the droplet. Each electrode of the arrangement may have an area which is less than ⅕, 1/10, 1/20, or 1/100 of the area of the footprint of the droplet. The method may further, after the step of using the impedance measurements to determine the footprint of the droplet, include deactivating a portion of the electrodes of the electrode arrangement in a manner selected to cause the footprint of the droplet to attain a substantially circular shape. The method may further, after the step of using the impedance measurements to determine the footprint of the droplet, include deactivating a portion of the electrodes of the electrode arrangement in a stepwise and substantially concentric manner beginning with outer electrodes of the electrode arrangement and proceeding inwardly to cause the footprint of the droplet to attain a substantially circular shape. The method may further, after the step of using the impedance measurements to determine the footprint of the droplet, include deactivating a first portion of the electrodes and leaving activated a second portion of the electrodes which underlies the droplet in a region which has an area that is smaller than the footprint of the droplet. The droplet actuator may include a set of droplet operations electrodes of which each droplet operations electrode is substantially larger than the electrodes of the arrangement of electrodes, and wherein the step of using the impedance measurements to determine the footprint of the droplet, includes transporting the droplet using electrodes of the droplet operations electrodes onto the arrangement of electrodes. The droplet actuator may include a set of droplet operations electrodes of which each droplet operations electrode is substantially larger than the electrodes of the arrangement of electrodes, and wherein the step of using the impedance measurements to determine the footprint of the droplet, includes transporting the droplet using electrodes of the droplet operations electrodes onto the arrangement of electrodes and wherein the droplet operations electrodes and the arrangement of electrodes, or a subset of the arrangement of electrodes, operate as electrowetting electrodes to facilitate the transport of the droplet onto the arrangement of electrodes. The method may further include transporting the droplet away from the arrangement of electrodes following the step of using the impedance measurements to determine the footprint of the droplet, for example, by using a set of droplet operations.

In still yet another embodiment, a method of manipulating a droplet in a droplet actuator is provided. The method may further include conducting droplet operations on a droplet operations surface using electrodes and alternating current to situate a droplet atop an electrode; applying a first direct current to the electrode for a predetermined period of time, the first direct current causing a droplet operations surface at the electrode to become charged; applying an opposite direct-current for a period of time sufficient to substantially discharge the droplet operations surface at the electrode; conducting further droplet operations on the droplet operations surface using the droplet and electrodes and alternating current to transport the droplet away from the electrode.

In still yet another embodiment, a method of manipulating a droplet in a droplet actuator is provided. The method may include applying a first direct current to an electrode for a predetermined period of time to retain a droplet at the electrode, the first direct current causing a droplet operations surface at the electrode to become charged; applying an opposite direct-current for a period of time sufficient to substantially discharge the droplet operations surface at the electrode; and transporting the droplet away from the electrode. The first direct current may be applied during imaging of the droplet.

In still yet another embodiment, a method of transporting a droplet in a droplet actuator is provided. The method may include, on a droplet actuator installed in an instrument for operating the droplet actuator, applying a first direct current to an electrode for a predetermined period of time to retain a droplet at the electrode, the first direct current causing a droplet operations surface at the electrode to become charged; and removing a droplet actuator from the instrument and transporting the droplet actuator away from the instrument, wherein the droplet is retained in position during the transporting. The method may further include, after the step of removing a droplet actuator from the instrument and transporting it away from the instrument and the droplet retained in position during the transporting, installing the droplet actuator and a separate instrument. The separate instrument may be an instrument for measuring property of the droplet, a separate droplet actuator, a storage device, a device for retaining the droplet actuator while removing the droplet, a device for removing the droplet, a device for incubating the droplet, or a device for imaging the droplet. The method may further comprising applying an opposite direct-current for a period of time sufficient to substantially discharge the droplet operations surface at the electrode; and transporting the droplet away from the electrode.

In still yet another embodiment, a method of transporting a droplet is provided. The method may include providing a droplet at a charged electrode on a droplet actuator; attempting to transport the droplet away from the charged electrode; and determining the time from initiation of the attempting step until the droplet is successfully transported away from the charged electrode and/or one or more electrical properties required to successfully transport the droplet away from the charged electrode. The method step of attempting to transport the droplet away from the charged electrode may include activating an adjacent electrowetting electrode while deactivating the charged electrode. The method step of attempting to transport the droplet away from the charged electrode may include dielectrophoretic transport of the droplet. The method may further include changing the temperature of the droplet during the step of attempting to transport the droplet away from the charged electrode. The method step of attempting to transport the droplet away from the charged electrode may include activating an adjacent electrowetting electrode while discharging the charged electrode. The activating may include gradually increasing voltage at the adjacent electrode, and the method may further include measuring the voltage at which the droplet is successfully transported away from the charged electrode. The method step of determining the time from initiation of the attempting step until the droplet is successfully transported away from the charged electrode and/or one or more electrical properties required to successfully transport the droplet away from the charged electrode, may include monitoring impedance at a position on the droplet actuator which is adjacent to the charged electrode. The timing of transport may be correlated with a physical or chemical property of the droplet. The one or more electrical characteristics required to induce transport may be correlated with a physical or chemical property of the droplet. The one or more transport characteristics of the droplet may be correlated with a physical or chemical property of the droplet. The droplet may include an assay droplet. The one or more electrical properties may include voltage applied to the adjacent electrode, amperage applied to the adjacent electrode, and/or one or more specific electrical waveforms applied to the adjacent electrode. The transporting may include electrowetting-mediated droplet or dielectrophoresis-mediated droplet operations.

In still yet another embodiment, a droplet actuator system is provided. The system may include one or more droplet operations surfaces; a first set of electrodes on the one or more droplet operations surfaces, wherein each of the a first set of electrodes is coupled to one or more of the first voltage supply channels; and a second set of electrodes on the one or more droplet operations surfaces, wherein each of the a first set of electrodes is coupled to one or more of the second voltage supply channels. The one or more droplet operations surfaces may include a first set of voltage supply channels for supplying a first voltage; and a second set of voltage supply channels for supplying a second voltage which is substantially higher than the first voltage. Each of the first set of voltage supply channels may be electrically and switchably coupled to a first voltage supply source. Each of the second set of voltage supply channels may be electrically and switchably coupled to a second voltage supply source. The first set of electrodes and second set of electrodes may be configured to interact with each other to conduct one or more droplet operations and/or droplet dispensing operations. The second set of electrodes may be proximate to one or more external reservoirs and may be arranged to transport droplets from the one or more extra reservoirs into a droplet operations gap of the droplet actuator. Each of the second set of electrodes may also be coupled to the first voltage supply channels.

### 5 DEFINITIONS

As used herein, the following terms have the meanings indicated.

“Activate,” with reference to one or more electrodes, means affecting a change in the electrical state of the one or more electrodes which, in the presence of a droplet, results in a droplet operation. Activation of an electrode can be accomplished using alternating or direct current. Any suitable voltage may be used. For example, an electrode may be activated using a voltage which is greater than about 150 V, or greater than about 200 V, or greater than about 250 V, or from about 275 V to about 375 V, or about 300 V. Where alternating current is used, any suitable frequency may be employed. For example, an electrode may be activated using alternating current having a frequency from about 1 Hz to about 100 Hz, or from about 10 Hz to about 60 Hz, or from about 20 Hz to about 40 Hz, or about 30 Hz.

“Bead,” with respect to beads on a droplet actuator, means any bead or particle that is capable of interacting with a droplet on or in proximity with a droplet actuator. Beads may be any of a wide variety of shapes, such as spherical, generally spherical, egg shaped, disc shaped, cubical, amorphous and other three dimensional shapes. The bead may, for example, be capable of being subjected to a droplet operation in a droplet on a droplet actuator or otherwise configured with respect to a droplet actuator in a manner which permits a droplet on the droplet actuator to be brought into contact with the bead on the droplet actuator and/or off the droplet actuator. Beads may be provided in a droplet, in a droplet operations gap, or on a droplet operations surface. Beads may be provided in a reservoir that is external to a droplet operations gap or situated apart from a droplet operations surface, and the reservoir may be associated with a flow path that permits a droplet including the beads to be brought into a droplet operations gap or into contact with a droplet operations surface. Beads may be manufactured using a wide variety of materials, including for example, resins, and polymers. The beads may be any suitable size, including for example, microbeads, microparticles, nanobeads and nanoparticles. In some cases, beads are magnetically responsive; in other cases beads are not significantly magnetically responsive. For magnetically responsive beads, the magnetically responsive material may constitute substantially all of a bead, a portion of a bead, or only one component of a bead. The remainder of the bead may include, among other things, polymeric material, coatings, and moieties which permit attachment of an assay reagent. Examples of suitable beads include flow cytometry microbeads, polystyrene microparticles and nanoparticles, functionalized polystyrene microparticles and nanoparticles, coated polystyrene microparticles and nanoparticles, silica microbeads, fluorescent microspheres and nanospheres, functionalized fluorescent microspheres and nanospheres, coated fluorescent microspheres and nanospheres, color dyed microparticles and nanoparticles, magnetic microparticles and nanoparticles, superparamagnetic microparticles and nanoparticles (e.g., DYNABEADS® particles, available from Invitrogen Group, Carlsbad, Calif.), fluorescent microparticles and nanoparticles, coated magnetic microparticles and nanoparticles, ferromagnetic microparticles and nanoparticles, coated ferromagnetic microparticles and nanoparticles, and those described in U.S. Patent Publication Nos. 20050260686, entitled “Multiplex flow assays preferably with magnetic particles as solid phase,” published on Nov. 24, 2005; 20030132538, entitled “Encapsulation of discrete quanta of fluorescent particles,” published on Jul. 17, 2003; 20050118574, entitled “Multiplexed Analysis of Clinical Specimens Apparatus and Method,” published on Jun. 2, 2005; 20050277197. Entitled “Microparticles with Multiple Fluorescent Signals and Methods of Using Same,” published on Dec. 15, 2005; 20060159962, entitled “Magnetic Microspheres for use in Fluorescence-based Applications,” published on Jul. 20, 2006; the entire disclosures of which are incorporated herein by reference for their teaching concerning beads and magnetically responsive materials and beads. Beads may be pre-coupled with a biomolecule or other substance that is able to bind to and form a complex with a biomolecule. Beads may be pre-coupled with an antibody, protein or antigen, DNA/RNA probe or any other molecule with an affinity for a desired target. Examples of droplet actuator techniques for immobilizing magnetically responsive beads and/or non-magnetically responsive beads and/or conducting droplet operations protocols using beads are described in U.S. patent application Ser. No. 11/639,566, entitled “Droplet-Based Particle Sorting,” filed on Dec. 15, 2006; U.S. Patent Application No. 61/039,183, entitled “Multiplexing Bead Detection in a Single Droplet,” filed on Mar. 25, 2008; U.S. Patent Application No. 61/047,789, entitled “Droplet Actuator Devices and Droplet Operations Using Beads,” filed on Apr. 25, 2008; U.S. Patent Application No. 61/086,183, entitled “Droplet Actuator Devices and Methods for Manipulating Beads,” filed on Aug. 5, 2008; International Patent Application No. PCT/US2008/053545, entitled “Droplet Actuator Devices and Methods Employing Magnetic Beads,” filed on Feb. 11, 2008; International Patent Application No. PCT/US2008/058018, entitled “Bead-based Multiplexed Analytical Methods and Instrumentation,” filed on Mar. 24, 2008; International Patent Application No. PCT/US2008/058047, “Bead Sorting on a Droplet Actuator,” filed on Mar. 23, 2008; and International Patent Application No. PCT/US2006/047486, entitled “Droplet-based Biochemistry,” filed on Dec. 11, 2006; the entire disclosures of which are incorporated herein by reference. Bead characteristics may be employed in the multiplexing aspects of the invention. Examples of beads having characteristics suitable for multiplexing, as well as methods of detecting and analyzing signals emitted from such beads, may be found in U.S. Patent Publication No. 20080305481, entitled “Systems and Methods for Multiplex Analysis of PCR in Real Time,” published on Dec. 11, 2008; U.S. Patent Publication No. 20080151240, “Methods and Systems for Dynamic Range Expansion,” published on Jun. 26, 2008; U.S. Patent Publication No. 20070207513, entitled “Methods, Products, and Kits for Identifying an Analyte in a Sample,” published on Sep. 6, 2007; U.S. Patent Publication No. 20070064990, entitled “Methods and Systems for Image Data Processing,” published on Mar. 22, 2007; U.S. Patent Publication No. 20060159962, entitled “Magnetic Microspheres for use in Fluorescence-based Applications,” published on Jul. 20, 2006; U.S. Patent Publication No. 20050277197, entitled “Microparticles with Multiple Fluorescent Signals and Methods of Using Same,” published on Dec. 15, 2005; and U.S. Patent Publication No. 20050118574, entitled “Multiplexed Analysis of Clinical Specimens Apparatus and Method,” published on Jun. 2, 2005.

“Droplet” means a volume of liquid on a droplet actuator. Typically, a droplet is at least partially bounded by a filler fluid. For example, a droplet may be completely surrounded by a filler fluid or may be bounded by filler fluid and one or more surfaces of the droplet actuator. As another example, a droplet may be bounded by filler fluid, one or more surfaces of the droplet actuator, and/or the atmosphere. As yet another example, a droplet may be bounded by filler fluid and the atmosphere. Droplets may, for example, be aqueous or non-aqueous or may be mixtures or emulsions including aqueous and non-aqueous components. Droplets may take a wide variety of shapes; nonlimiting examples include generally disc shaped, slug shaped, truncated sphere, ellipsoid, spherical, partially compressed sphere, hemispherical, ovoid, cylindrical, combinations of such shapes, and various shapes formed during droplet operations, such as merging or splitting or formed as a result of contact of such shapes with one or more surfaces of a droplet actuator. For examples of droplet fluids that may be subjected to droplet operations using the approach of the invention, see International Patent Application No. PCT/US 06/47486, entitled, “Droplet-Based Biochemistry,” filed on Dec. 11, 2006. In various embodiments, a droplet may include a biological sample, such as whole blood, lymphatic fluid, serum, plasma, sweat, tear, saliva, sputum, cerebrospinal fluid, amniotic fluid, seminal fluid, vaginal excretion, serous fluid, synovial fluid, pericardial fluid, peritoneal fluid, pleural fluid, transudates, exudates, cystic fluid, bile, urine, gastric fluid, intestinal fluid, fecal samples, liquids containing single or multiple cells, liquids containing organelles, fluidized tissues, fluidized organisms, liquids containing multi-celled organisms, biological swabs and biological washes. Moreover, a droplet may include a reagent, such as water, deionized water, saline solutions, acidic solutions, basic solutions, detergent solutions and/or buffers. Other examples of droplet contents include reagents, such as a reagent for a biochemical protocol, such as a nucleic acid amplification protocol, an affinity-based assay protocol, an enzymatic assay protocol, a sequencing protocol, and/or a protocol for analyses of biological fluids. A droplet may include one or more beads.

“Droplet Actuator” means a device for manipulating droplets. For examples of droplet actuators, see Pamula et al., U.S. Pat. No. 6,911,132, entitled “Apparatus for Manipulating Droplets by Electrowetting-Based Techniques,” issued on Jun. 28, 2005; Pamula et al., U.S. patent application Ser. No. 11/343,284, entitled “Apparatuses and Methods for Manipulating Droplets on a Printed Circuit Board,” filed on filed on Jan. 30, 2006; Pollack et al., International Patent Application No. PCT/US2006/047486, entitled “Droplet-Based Biochemistry,” filed on Dec. 11, 2006; Shenderov, U.S. Pat. Nos. 6,773,566, entitled “Electrostatic Actuators for Microfluidics and Methods for Using Same,” issued on Aug. 10, 2004 and 6,565,727, entitled “Actuators for Microfluidics Without Moving Parts,” issued on Jan. 24, 2000; Kim and/or Shah et al., U.S. patent application Ser. Nos. 10/343,261, entitled “Electrowetting-driven Micropumping,” filed on Jan. 27, 2003, 11/275,668, entitled “Method and Apparatus for Promoting the Complete Transfer of Liquid Drops from a Nozzle,” filed on Jan. 23, 2006, 11/460,188, entitled “Small Object Moving on Printed Circuit Board,” filed on Jan. 23, 2006, 12/465,935, entitled “Method for Using Magnetic Particles in Droplet Microfluidics,” filed on May 14, 2009, and 12/513,157, entitled “Method and Apparatus for Real-time Feedback Control of Electrical Manipulation of Droplets on Chip,” filed on Apr. 30, 2009; Velev, U.S. Pat. No. 7,547,380, entitled “Droplet Transportation Devices and Methods Having a Fluid Surface,” issued on Jun. 16, 2009; Sterling et al., U.S. Pat. No. 7,163,612, entitled “Method, Apparatus and Article for Microfluidic Control via Electrowetting, for Chemical, Biochemical and Biological Assays and the Like,” issued on Jan. 16, 2007; Becker and Gascoyne et al., U.S. Pat. Nos. 7,641,779, entitled “Method and Apparatus for Programmable fluidic Processing,” issued on Jan. 5, 2010, and 6,977,033, entitled “Method and Apparatus for Programmable fluidic Processing,” issued on Dec. 20, 2005; Decre et al., U.S. Pat. No. 7,328,979, entitled “System for Manipulation of a Body of Fluid,” issued on Feb. 12, 2008; Yamakawa et al., U.S. Patent Pub. No. 20060039823, entitled “Chemical Analysis Apparatus,” published on Feb. 23, 2006; Wu, International Patent Pub. No. WO/2009/003184, entitled “Digital Microfluidics Based Apparatus for Heat-exchanging Chemical Processes,” published on Dec. 31, 2008; Fouillet et al., U.S. Patent Pub. No. 20090192044, entitled “Electrode Addressing Method,” published on Jul. 30, 2009; Fouillet et al., U.S. Pat. No. 7,052,244, entitled “Device for Displacement of Small Liquid Volumes Along a Micro-catenary Line by Electrostatic Forces,” issued on May 30, 2006; Marchand et al., U.S. Patent Pub. No. 20080124252, entitled “Droplet Microreactor,” published on May 29, 2008; Adachi et al., U.S. Patent Pub. No. 20090321262, entitled “Liquid Transfer Device,” published on Dec. 31, 2009; Roux et al., U.S. Patent Pub. No. 20050179746, entitled “Device for Controlling the Displacement of a Drop Between two or Several Solid Substrates,” published on Aug. 18, 2005; Dhindsa et al., “Virtual Electrowetting Channels Electronic Liquid Transport with Continuous Channel Functionality,” Lab Chip, 10:832-836 (2010); the entire disclosures of which are incorporated herein by reference, along with their priority documents. Certain droplet actuators will include one or more substrates arranged with a droplet operations gap therebetween and electrodes associated with (e.g., layered on, attached to, and/or embedded in) the one or more substrates and arranged to conduct one or more droplet operations. For example, certain droplet actuators will include a base (or bottom) substrate, droplet operations electrodes associated with the substrate, one or more dielectric layers atop the substrate and/or electrodes, and optionally one or more hydrophobic layers atop the substrate, dielectric layers and/or the electrodes forming a droplet operations surface. A top substrate may also be provided, which is separated from the droplet operations surface by a gap, commonly referred to as a droplet operations gap. Various electrode arrangements on the top and/or bottom substrates are discussed in the above-referenced patents and applications and certain novel electrode arrangements are discussed in the description of the invention. During droplet operations it is preferred that droplets remain in continuous contact or frequent contact with a ground or reference electrode. A ground or reference electrode may be associated with the top substrate facing the gap, the bottom substrate facing the gap, in the gap. Where electrodes are provided on both substrates, electrical contacts for coupling the electrodes to a droplet actuator instrument for controlling or monitoring the electrodes may be associated with one or both plates. In some cases, electrodes on one substrate are electrically coupled to the other substrate so that only one substrate is in contact with the droplet actuator. In one embodiment, a conductive material (e.g., an epoxy, such as MASTER BOND™ Polymer System EP79, available from Master Bond, Inc., Hackensack, N.J.) provides the electrical connection between electrodes on one substrate and electrical paths on the other substrates, e.g., a ground electrode on a top substrate may be coupled to an electrical path on a bottom substrate by such a conductive material. Where multiple substrates are used, a spacer may be provided between the substrates to determine the height of the gap therebetween and define dispensing reservoirs. The spacer height may, for example, be from about 5 μm to about 600 μm, or about 100 μm to about 400 μm, or about 200 μm to about 350 μm, or about 250 μm to about 300 μm, or about 275 μm. The spacer may, for example, be formed of a layer of projections form the top or bottom substrates, and/or a material inserted between the top and bottom substrates. One or more openings may be provided in the one or more substrates for forming a fluid path through which liquid may be delivered into the droplet operations gap. The one or more openings may in some cases be aligned for interaction with one or more electrodes, e.g., aligned such that liquid flowed through the opening will come into sufficient proximity with one or more droplet operations electrodes to permit a droplet operation to be effected by the droplet operations electrodes using the liquid. The base (or bottom) and top substrates may in some cases be formed as one integral component. One or more reference electrodes may be provided on the base (or bottom) and/or top substrates and/or in the gap. Examples of reference electrode arrangements are provided in the above referenced patents and patent applications. In various embodiments, the manipulation of droplets by a droplet actuator may be electrode mediated, e.g., electrowetting mediated or dielectrophoresis mediated or Coulombic force mediated. Examples of other techniques for controlling droplet operations that may be used in the droplet actuators of the invention include using devices that induce hydrodynamic fluidic pressure, such as those that operate on the basis of mechanical principles (e.g. external syringe pumps, pneumatic membrane pumps, vibrating membrane pumps, vacuum devices, centrifugal forces, piezoelectric/ultrasonic pumps and acoustic forces); electrical or magnetic principles (e.g. electroosmotic flow, electrokinetic pumps, ferrofluidic plugs, electrohydrodynamic pumps, attraction or repulsion using magnetic forces and magnetohydrodynamic pumps); thermodynamic principles (e.g. gas bubble generation/phase-change-induced volume expansion); other kinds of surface-wetting principles (e.g. electrowetting, and optoelectrowetting, as well as chemically, thermally, structurally and radioactively induced surface-tension gradients); gravity; surface tension (e.g., capillary action); electrostatic forces (e.g., electroosmotic flow); centrifugal flow (substrate disposed on a compact disc and rotated); magnetic forces (e.g., oscillating ions causes flow); magnetohydrodynamic forces; and vacuum or pressure differential. In certain embodiments, combinations of two or more of the foregoing techniques may be employed to conduct a droplet operation in a droplet actuator of the invention. Similarly, one or more of the foregoing may be used to deliver liquid into a droplet operations gap, e.g., from a reservoir in another device or from an external reservoir of the droplet actuator (e.g., a reservoir associated with a droplet actuator substrate and a flow path from the reservoir into the droplet operations gap). Droplet operations surfaces of certain droplet actuators of the invention may be made from hydrophobic materials or may be coated or treated to make them hydrophobic. For example, in some cases some portion or all of the droplet operations surfaces may be derivatized with low surface-energy materials or chemistries, e.g., by deposition or using in situ synthesis using compounds such as poly- or per-fluorinated compounds in solution or polymerizable monomers. Examples include TEFLON® AF (available from DuPont, Wilmington, Del.), members of the cytop family of materials, coatings in the FLUOROPEL® family of hydrophobic and superhydrophobic coatings (available from Cytonix Corporation, Beltsville, Md.), silane coatings, fluorosilane coatings, hydrophobic phosphonate derivatives (e.g., those sold by Aculon, Inc), and NOVEC™ electronic coatings (available from 3M Company, St. Paul, Minn.), and other fluorinated monomers for plasma-enhanced chemical vapor deposition (PECVD). In some cases, the droplet operations surface may include a hydrophobic coating having a thickness ranging from about 10 nm to about 1,000 nm. Moreover, in some embodiments, the top substrate of the droplet actuator includes an electrically conducting organic polymer, which is then coated with a hydrophobic coating or otherwise treated to make the droplet operations surface hydrophobic. For example, the electrically conducting organic polymer that is deposited onto a plastic substrate may be poly(3,4-ethylenedioxythiophene) poly(styrenesulfonate) (PEDOT:PSS). Other examples of electrically conducting organic polymers and alternative conductive layers are described in Pollack et al., International Patent Application No. PCT/US2010/040705, entitled “Droplet Actuator Devices and Methods,” the entire disclosure of which is incorporated herein by reference. One or both substrates may be fabricated using a printed circuit board (PCB), glass, indium tin oxide (ITO)-coated glass, and/or semiconductor materials as the substrate. When the substrate is ITO-coated glass, the ITO coating is preferably a thickness in the range of about 20 to about 200 nm, preferably about 50 to about 150 nm, or about 75 to about 125 nm, or about 100 nm. In some cases, the top and/or bottom substrate includes a PCB substrate that is coated with a dielectric, such as a polyimide dielectric, which may in some cases also be coated or otherwise treated to make the droplet operations surface hydrophobic. When the substrate includes a PCB, the following materials are examples of suitable materials: MITSUI™ BN-300 (available from MITSUI Chemicals America, Inc., San Jose Calif.); ARLON™ 11N (available from Arlon, Inc, Santa Ana, Calif.).; NELCO® N4000-6 and N5000-30/32 (available from Park Electrochemical Corp., Melville, N.Y.); ISOLA™ FR406 (available from Isola Group, Chandler, Ariz.), especially IS620; fluoropolymer family (suitable for fluorescence detection since it has low background fluorescence); polyimide family; polyester; polyethylene naphthalate; polycarbonate; polyetheretherketone; liquid crystal polymer; cyclo-olefin copolymer (COC); cyclo-olefin polymer (COP); aramid; THERMOUNT® nonwoven aramid reinforcement (available from DuPont, Wilmington, Del.); NOMEX® brand fiber (available from DuPont, Wilmington, Del.); and paper. Various materials are also suitable for use as the dielectric component of the substrate. Examples include: vapor deposited dielectric, such as PARYLENE™ C (especially on glass) and PARYLENE™ N (available from Parylene Coating Services, Inc., Katy, Tex.); TEFLON® AF coatings; cytop; soldermasks, such as liquid photoimageable soldermasks (e.g., on PCB) like TAIYO™ PSR4000 series, TAIYO™ PSR and AUS series (available from Taiyo America, Inc. Carson City, Nev.) (good thermal characteristics for applications involving thermal control), and PROBIMER™ 8165 (good thermal characteristics for applications involving thermal control (available from Huntsman Advanced Materials Americas Inc., Los Angeles, Calif.); dry film soldermask, such as those in the VACREL® dry film soldermask line (available from DuPont, Wilmington, Del.); film dielectrics, such as polyimide film (e.g., KAPTON® polyimide film, available from DuPont, Wilmington, Del.), polyethylene, and fluoropolymers (e.g., FEP), polytetrafluoroethylene; polyester; polyethylene naphthalate; cyclo-olefin copolymer (COC); cyclo-olefin polymer (COP); any other PCB substrate material listed above; black matrix resin; and polypropylene. Droplet transport voltage and frequency may be selected for performance with reagents used in specific assay protocols. Design parameters may be varied, e.g., number and placement of on-actuator reservoirs, number of independent electrode connections, size (volume) of different reservoirs, placement of magnets/bead washing zones, electrode size, inter-electrode pitch, and gap height (between top and bottom substrates) may be varied for use with specific reagents, protocols, droplet volumes, etc. In some cases, a substrate of the invention may derivatized with low surface-energy materials or chemistries, e.g., using deposition or in situ synthesis using poly- or per-fluorinated compounds in solution or polymerizable monomers. Examples include TEFLON® AF coatings and FLUOROPEL® coatings for dip or spray coating, and other fluorinated monomers for plasma-enhanced chemical vapor deposition (PECVD). Additionally, in some cases, some portion or all of the droplet operations surface may be coated with a substance for reducing background noise, such as background fluorescence from a PCB substrate. For example, the noise-reducing coating may include a black matrix resin, such as the black matrix resins available from Toray industries, Inc., Japan. Electrodes of a droplet actuator are typically controlled by a controller or a processor, which is itself provided as part of a system, which may include processing functions as well as data and software storage and input and output capabilities. Reagents may be provided on the droplet actuator in the droplet operations gap or in a reservoir fluidly coupled to the droplet operations gap. The reagents may be in liquid form, e.g., droplets, or they may be provided in a reconstitutable form in the droplet operations gap or in a reservoir fluidly coupled to the droplet operations gap. Reconstitutable reagents may typically be combined with liquids for reconstitution. An example of reconstitutable reagents suitable for use with the invention includes those described in Meathrel, et al., U.S. Pat. No. 7,727,466, entitled “Disintegratable films for diagnostic devices,” granted on Jun. 1, 2010.

“Droplet operation” means any manipulation of a droplet on a droplet actuator. A droplet operation may, for example, include: loading a droplet into the droplet actuator; dispensing one or more droplets from a source droplet; splitting, separating or dividing a droplet into two or more droplets; transporting a droplet from one location to another in any direction; merging or combining two or more droplets into a single droplet; diluting a droplet; mixing a droplet; agitating a droplet; deforming a droplet; retaining a droplet in position; incubating a droplet; heating a droplet; vaporizing a droplet; cooling a droplet; disposing of a droplet; transporting a droplet out of a droplet actuator; other droplet operations described herein; and/or any combination of the foregoing. The terms “merge,” “merging,” “combine,” “combining” and the like are used to describe the creation of one droplet from two or more droplets. It should be understood that when such a term is used in reference to two or more droplets, any combination of droplet operations that are sufficient to result in the combination of the two or more droplets into one droplet may be used. For example, “merging droplet A with droplet B,” can be achieved by transporting droplet A into contact with a stationary droplet B, transporting droplet B into contact with a stationary droplet A, or transporting droplets A and B into contact with each other. The terms “splitting,” “separating” and “dividing” are not intended to imply any particular outcome with respect to volume of the resulting droplets (i.e., the volume of the resulting droplets can be the same or different) or number of resulting droplets (the number of resulting droplets may be 2, 3, 4, 5 or more). The term “mixing” refers to droplet operations which result in more homogenous distribution of one or more components within a droplet. Examples of “loading” droplet operations include microdialysis loading, pressure assisted loading, robotic loading, passive loading, and pipette loading. Droplet operations may be electrode-mediated. In some cases, droplet operations are further facilitated by the use of hydrophilic and/or hydrophobic regions on surfaces and/or by physical obstacles. For examples of droplet operations, see the patents and patent applications cited above under the definition of “droplet actuator.” Impedance or capacitance sensing or imaging techniques may sometimes be used to determine or confirm the outcome of a droplet operation. Examples of such techniques are described in Sturmer et al., International Patent Pub. No. WO/2008/101194, entitled “Capacitance Detection in a Droplet Actuator,” published on Aug. 21, 2008, the entire disclosure of which is incorporated herein by reference. Generally speaking, the sensing or imaging techniques may be used to confirm the presence or absence of a droplet at a specific electrode. For example, the presence of a dispensed droplet at the destination electrode following a droplet dispensing operation confirms that the droplet dispensing operation was effective. Similarly, the presence of a droplet at a detection spot at an appropriate step in an assay protocol may confirm that a previous set of droplet operations has successfully produced a droplet for detection. Droplet transport time can be quite fast. For example, in various embodiments, transport of a droplet from one electrode to the next may exceed about 1 sec, or about 0.1 sec, or about 0.01 sec, or about 0.001 sec. In one embodiment, the electrode is operated in AC mode but is switched to DC mode for imaging. It is helpful for conducting droplet operations for the footprint area of droplet to be similar to electrowetting area; in other words, 1x-, 2x- 3x-droplets are usefully controlled operated using 1, 2, and 3 electrodes, respectively. If the droplet footprint is greater than the number of electrodes available for conducting a droplet operation at a given time, the difference between the droplet size and the number of electrodes should typically not be greater than 1; in other words, a 2x droplet is usefully controlled using 1 electrode and a 3x droplet is usefully controlled using 2 electrodes. When droplets include beads, it is useful for droplet size to be equal to the number of electrodes controlling the droplet, e.g., transporting the droplet.

“Filler fluid” means a fluid associated with a droplet operations substrate of a droplet actuator, which fluid is sufficiently immiscible with a droplet phase to render the droplet phase subject to electrode-mediated droplet operations. For example, the droplet operations gap of a droplet actuator is typically filled with a filler fluid. The filler fluid may, for example, be a low-viscosity oil, such as silicone oil or hexadecane filler fluid. The filler fluid may fill the entire gap of the droplet actuator or may coat one or more surfaces of the droplet actuator. Filler fluids may be conductive or non-conductive. Filler fluids may, for example, be doped with surfactants or other additives. For example, additives may be selected to improve droplet operations and/or reduce loss of reagent or target substances from droplets, formation of microdroplets, cross contamination between droplets, contamination of droplet actuator surfaces, degradation of droplet actuator materials, etc. Composition of the filler fluid, including surfactant doping, may be selected for performance with reagents used in the specific assay protocols and effective interaction or non-interaction with droplet actuator materials. Examples of filler fluids and filler fluid formulations suitable for use with the invention are provided in Srinivasan et al, International Patent Pub. Nos. WO/2010/027894, entitled “Droplet Actuators, Modified Fluids and Methods,” published on Mar. 11, 2010, and WO/2009/021173, entitled “Use of Additives for Enhancing Droplet Operations,” published on Feb. 12, 2009; Sista et al., International Patent Pub. No. WO/2008/098236, entitled “Droplet Actuator Devices and Methods Employing Magnetic Beads,” published on Aug. 14, 2008; and Monroe et al., U.S. Patent Publication No. 20080283414, entitled “Electrowetting Devices,” filed on May 17, 2007; the entire disclosures of which are incorporated herein by reference, as well as the other patents and patent applications cited herein.

“Immobilize” with respect to magnetically responsive beads, means that the beads are substantially restrained in position in a droplet or in filler fluid on a droplet actuator. For example, in one embodiment, immobilized beads are sufficiently restrained in position in a droplet to permit execution of a droplet splitting operation, yielding one droplet with substantially all of the beads and one droplet substantially lacking in the beads.

“Magnetically responsive” means responsive to a magnetic field. “Magnetically responsive beads” include or are composed of magnetically responsive materials. Examples of magnetically responsive materials include paramagnetic materials, ferromagnetic materials, ferrimagnetic materials, and metamagnetic materials. Examples of suitable paramagnetic materials include iron, nickel, and cobalt, as well as metal oxides, such as Fe3O4, BaFe12O19, CoO, NiO, Mn2O3, Cr2O3, and CoMnP.

“Reservoir” means an enclosure or partial enclosure configured for holding, storing, or supplying liquid. A droplet actuator system of the invention may include on-cartridge reservoirs and/or off-cartridge reservoirs. On-cartridge reservoirs may be (1) on-actuator reservoirs, which are reservoirs in the droplet operations gap or on the droplet operations surface; (2) off-actuator reservoirs, which are reservoirs on the droplet actuator cartridge, but outside the droplet operations gap, and not in contact with the droplet operations surface; or (3) hybrid reservoirs which have on-actuator regions and off-actuator regions. An example of an off-actuator reservoir is a reservoir in the top substrate. An off-actuator reservoir is typically in fluid communication with an opening or flow path arranged for flowing liquid from the off-actuator reservoir into the droplet operations gap, such as into an on-actuator reservoir. An off-cartridge reservoir may be a reservoir that is not part of the droplet actuator cartridge at all, but which flows liquid to some portion of the droplet actuator cartridge. For example, an off-cartridge reservoir may be part of a system or docking station to which the droplet actuator cartridge is coupled during operation. Similarly, an off-cartridge reservoir may be a reagent storage container or syringe which is used to force fluid into an on-cartridge reservoir or into a droplet operations gap. A system using an off-cartridge reservoir will typically include a fluid passage means whereby liquid may be transferred from the off-cartridge reservoir into an on-cartridge reservoir or into a droplet operations gap.

“Transporting into the magnetic field of a magnet,” “transporting towards a magnet,” and the like, as used herein to refer to droplets and/or magnetically responsive beads within droplets, is intended to refer to transporting into a region of a magnetic field capable of substantially attracting magnetically responsive beads in the droplet. Similarly, “transporting away from a magnet or magnetic field,” “transporting out of the magnetic field of a magnet,” and the like, as used herein to refer to droplets and/or magnetically responsive beads within droplets, is intended to refer to transporting away from a region of a magnetic field capable of substantially attracting magnetically responsive beads in the droplet, whether or not the droplet or magnetically responsive beads is completely removed from the magnetic field. It will be appreciated that in any of such cases described herein, the droplet may be transported towards or away from the desired region of the magnetic field, and/or the desired region of the magnetic field may be moved towards or away from the droplet. Reference to an electrode, a droplet, or magnetically responsive beads being “within” or “in” a magnetic field, or the like, is intended to describe a situation in which the electrode is situated in a manner which permits the electrode to transport a droplet into and/or away from a desired region of a magnetic field, or the droplet or magnetically responsive beads is/are situated in a desired region of the magnetic field, in each case where the magnetic field in the desired region is capable of substantially attracting any magnetically responsive beads in the droplet. Similarly, reference to an electrode, a droplet, or magnetically responsive beads being “outside of” or “away from” a magnetic field, and the like, is intended to describe a situation in which the electrode is situated in a manner which permits the electrode to transport a droplet away from a certain region of a magnetic field, or the droplet or magnetically responsive beads is/are situated away from a certain region of the magnetic field, in each case where the magnetic field in such region is not capable of substantially attracting any magnetically responsive beads in the droplet or in which any remaining attraction does not eliminate the effectiveness of droplet operations conducted in the region. In various aspects of the invention, a system, a droplet actuator, or another component of a system may include a magnet, such as one or more permanent magnets (e.g., a single cylindrical or bar magnet or an array of such magnets, such as a Halbach array) or an electromagnet or array of electromagnets, to form a magnetic field for interacting with magnetically responsive beads or other components on chip. Such interactions may, for example, include substantially immobilizing or restraining movement or flow of magnetically responsive beads during storage or in a droplet during a droplet operation or pulling magnetically responsive beads out of a droplet.

“Washing” with respect to washing a bead means reducing the amount and/or concentration of one or more substances in contact with the bead or exposed to the bead from a droplet in contact with the bead. The reduction in the amount and/or concentration of the substance may be partial, substantially complete, or even complete. The substance may be any of a wide variety of substances; examples include target substances for further analysis, and unwanted substances, such as components of a sample, contaminants, and/or excess reagent. In some embodiments, a washing operation begins with a starting droplet in contact with a magnetically responsive bead, where the droplet includes an initial amount and initial concentration of a substance. The washing operation may proceed using a variety of droplet operations. The washing operation may yield a droplet including the magnetically responsive bead, where the droplet has a total amount and/or concentration of the substance which is less than the initial amount and/or concentration of the substance. Examples of suitable washing techniques are described in Pamula et al., U.S. Pat. No. 7,439,014, entitled “Droplet-Based Surface Modification and Washing,” granted on Oct. 21, 2008, the entire disclosure of which is incorporated herein by reference.

The terms “top,” “bottom,” “over,” “under,” and “on” are used throughout the description with reference to the relative positions of components of the droplet actuator, such as relative positions of top and bottom substrates of the droplet actuator. It will be appreciated that the droplet actuator is functional regardless of its orientation in space.

When a liquid in any form (e.g., a droplet or a continuous body, whether moving or stationary) is described as being “on”, “at”, or “over” an electrode, array, matrix or surface, such liquid could be either in direct contact with the electrode/array/matrix/surface, or could be in contact with one or more layers or films that are interposed between the liquid and the electrode/array/matrix/surface.

When a droplet is described as being “on” or “loaded on” a droplet actuator, it should be understood that the droplet is arranged on the droplet actuator in a manner which facilitates using the droplet actuator to conduct one or more droplet operations on the droplet, the droplet is arranged on the droplet actuator in a manner which facilitates sensing of a property of or a signal from the droplet, and/or the droplet has been subjected to a droplet operation on the droplet actuator.

### 6 BRIEF DESCRIPTION OF THE DRAWINGS

FIGS. 1A and 1B illustrate cross-sectional side views of an example of a droplet actuator;

FIGS. 2A and 2B illustrate cross-sectional side views of another example of a droplet actuator;

FIGS. 3A and 3B illustrate a top view and a side view, respectively, of a droplet actuator that uses cantilever springs to provide spring forces for forcing a bottom substrate against gap-setting features of a top substrate;

FIGS. 4A and 4B illustrate cross-sectional side views of a portion of an example of a droplet actuator that uses z-axis connectors between the bottom and top substrates;

FIG. 4C illustrates top and side views of an example of a z-axis connector;

FIGS. 5A and 5B illustrate cross-sectional side views of a portion of a droplet actuator;

FIGS. 6A and 6B illustrate cross-sectional side views of a process of using a reservoir assembly of the droplet actuator of FIGS. 5A and 5B;

FIG. 7 illustrates a top view of an example of a substrate of a droplet actuator that includes simple mechanisms for performing a quality control check on the control channels thereof;

FIGS. 8A through 8I illustrate top views of an example of an electrode arrangement and a process of impedance detection for determining droplet volumes;

FIG. 9 illustrates a flow diagram of an example of a method of reversing the surface charge effect in a droplet actuator;

FIG. 10 illustrates a flow diagram of an example of a method of using the surface charge effect to retain droplets in position within the droplet operations gap during handling the droplet actuator;

FIG. 11 illustrates a flow diagram of an example of a method of using impedance detection to quantify the rate of surface charging in a droplet actuator;

FIG. 12 illustrates a flow diagram of an example of a method of using droplet pinning due to surface charge effect as an indicator of temperature in a droplet actuator;

FIGS. 13A and 13B illustrate a cross-sectional side view and top view, respectively, of a portion of an example of a droplet actuator that includes dedicated high voltage channels to assist loading;

FIG. 14 illustrates a top view of an example of a substrate, such as a PCB, of a droplet actuator (not shown) that includes booster converters for individual control of the channels of a droplet actuator;

FIG. 15A illustrates a schematic diagram of an example of a voltage biasing circuit 1500 for an impedance spectrometer for use with a droplet actuator;

FIG. 15B illustrates an example of a plot 1550 that shows a plot of V-HIGH vs. V-BIAS of voltage biasing circuit 1500 of FIG. 15A;

FIG. 16 illustrates a schematic diagram of an example of a selectively regulated power supply 1600 for low-power droplet operations a droplet actuator;

FIG. 17 illustrates a top view of an example of a substrate of a droplet actuator that includes a mechanism for automatically indicating the presence a droplet actuator in an instrument;

FIGS. 18A through 18D illustrate a top view of an example of an electrode arrangement and show a process of validating a droplet merge operation in which the merge operation is successful;

FIGS. 19A through 19D illustrate the process of validating a droplet merge operation of FIGS. 18A through 18D, but when the merge operation is not successful;

FIG. 20 illustrates a flow diagram of an example of a method of correlating impedance measurements with respect to the DNA melting process to determine the temperature in a droplet actuator;

FIGS. 21A and 21B illustrate cross-sectional side views of an example of a droplet actuator and a process of using phase transitions to characterize, monitor, and/or calibrate droplet temperature;

FIG. 22 illustrates a schematic diagram of an example of a heater drive circuit for supplying heat directly to an electrode of a droplet actuator;

FIG. 23 illustrates a cross-sectional side view of a portion of droplet actuator and shows an example of using a laser as a heat source and/or for promoting cell lysis;

FIGS. 24A and 24B illustrate a top view and a cross-sectional side view, respectively, of an example of a droplet actuator that includes a hydrophilic reservoir for use in droplet imaging operations;

FIG. 25 illustrates a cross-sectional side view of an example of a droplet actuator and a process of measuring the gap height;

FIG. 26 illustrates an example of pseudo code for implementing an algorithm for locating short tandem repeats in large sequences of assay protocols;

FIG. 27 shows an example of a digital image from which droplet actuator description files may be automatically generated using an algorithm of the invention;

FIG. 28 illustrates a flow diagram of an example of a method of handling instrument/computer communication interruptions in a microfluidics system;

FIG. 29 illustrates a flow diagram of an example of a method of executing conditional droplet operations actions in a microfluidics system based on inputs at run-time;

FIG. 30 illustrates a top view of an example of a substrate of a droplet actuator that includes a mechanism for indicating a droplet actuator end-of-life condition; and

FIG. 31 illustrates a functional block diagram of an example of a microfluidics system that includes a droplet actuator.

### 7 DETAILED DESCRIPTION OF THE INVENTION

The invention provides droplet actuator systems, devices, and methods. Embodiments of the invention provide droplet actuators that use spring forces for maintaining uniform gap height in a droplet actuator. The invention also provides various techniques for coupling substrates of a droplet actuator. Further, the invention provides techniques for simple and inexpensive droplet actuator testing. The invention also provides novel electrode arrangements for volumetric metering using impedance. This technique enables droplets to be transported to a special metering area, measured, and then reliably removed. In yet other embodiments, the invention provides valves designed for use in droplet actuators. These valves are useful for preventing waste from flowing back into the droplet actuator after being transported into a waste reservoir. Examples include reversible mobile valves and soluble valves for providing a reversible blockage to reagent reservoirs. In yet other embodiments, the invention provides novel techniques for reversing surfaces in droplet actuators and/or using to charged surfaces to advantage in droplet actuators. For example, such techniques are useful for reversing the surface charge effect in a droplet actuator. Other techniques make use of the surface charge effect in a droplet actuator for off-loading liquid from an instrument in an automated fashion. Still others, make use of impedance detection to quantify the rate of surface charging in a droplet actuator. And others make use of droplet pinning due to surface charge effect as an indicator of temperature in a droplet actuator. The invention also provides novel techniques for controlling droplet actuators. The invention provides a droplet actuator that includes dedicated high voltage channels to assist loading; an electrode arrangement for optimized use of an n-phase control bus in a droplet actuator; a bottom substrate that includes booster converters for individual control of the channels of a droplet actuator; a voltage biasing circuit for droplet actuator impedance spectroscopy; and a selectively regulated power supply for low-power droplet operations a droplet actuator. In yet other embodiments, the invention provides novel detection methods for use in droplet actuators. In one embodiment, the invention provides for automatic detection of the insertion of a droplet actuator into an instrument. The invention provides for automatic detection of protocol initiation. The invention provides for the use of impedance detection to reliably validate droplet merge operations. The invention provides for droplet-based chemistry techniques in which the reduction of surfactant concentration in a droplet is detected using impedance. The invention provides for a method of temperature control in a droplet in a droplet actuator that relies on direct observation of the DNA melting process. The invention provides for the use of phase transitions of droplets in combination with impedance spectroscopy to characterize, monitor, and/or calibrate droplet temperature. In other embodiments, the invention provides local heating mechanisms in droplet actuators. For example, the invention provides a method of supplying heat directly to one or more electrodes in a droplet actuator. The invention provides a droplet actuator that uses a laser as a heat source and/or for promoting cell lysis. In other embodiments, the invention provides techniques imaging a droplet in a droplet actuator using a hydrophilic reservoir in the droplet actuator. In yet other embodiments, the invention provides processes for measuring the gap height during droplet actuator assembly. The invention also provides algorithms for locating short tandem repeats in lengthy nucleic acid sequences. The invention provides algorithms for generating droplet actuator description files by analyzing digital images. The invention provides methods of handling instrument/computer communication interruptions were droplet actuators. The invention provides methods of executing conditional droplet operations actions in a microfluidics system based on inputs at run-time. The invention provides methods of indicating droplet actuator end-of-life conditions that are easily detectable and substantially irreversible.

### 7.1 Droplet Actuators and Methods of Assembly

Providing a uniform gap height in a droplet actuator improves droplet operations performed in the droplet operations gap. However, using less expensive materials for manufacturing the top and/or bottom substrate can result in non-planar components, leading to a non-uniform gap height. For example, PCB's and plastic substrates may warp, leading to non-uniform gap height. The invention provides droplet actuator designs that force non-planar components into a more planar conformation and thereby improve uniformity of the gap height.

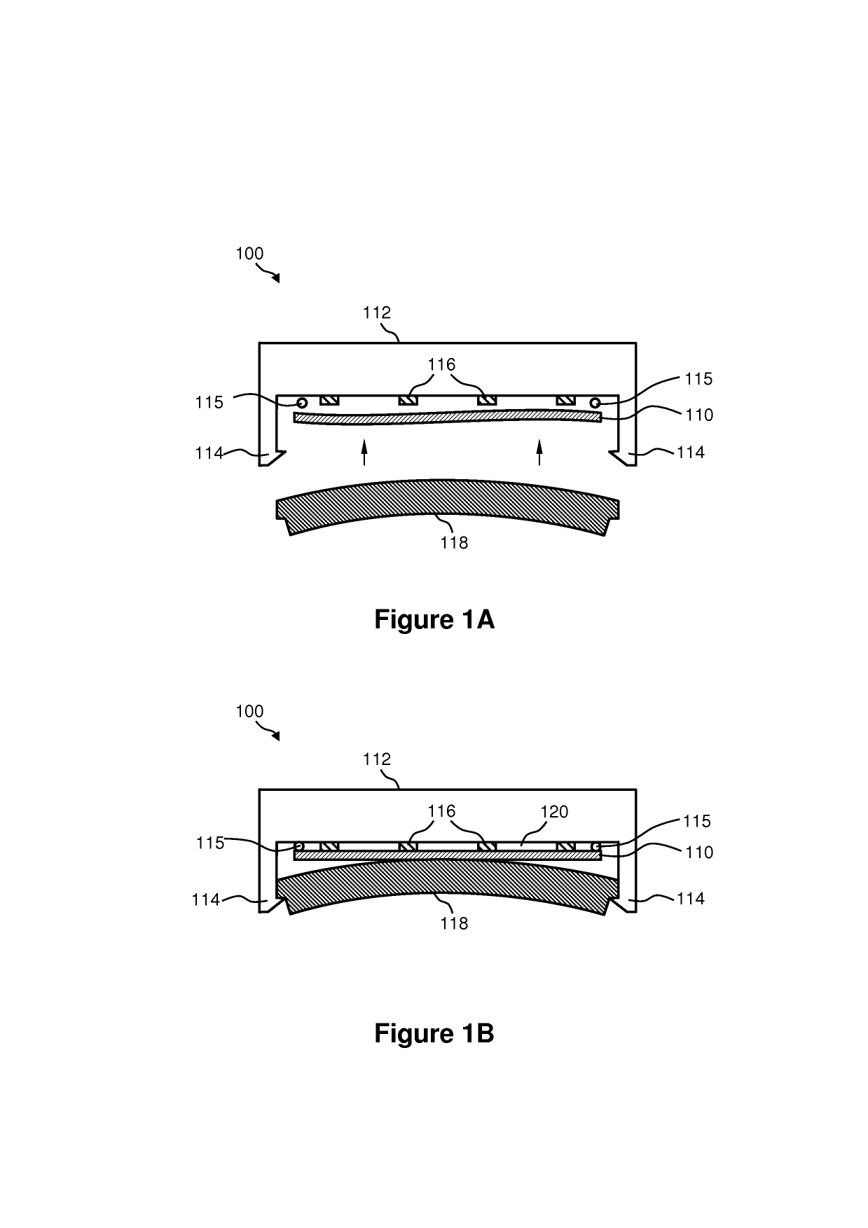

FIGS. 1A and 1B illustrate cross-sectional side views of an example of a droplet actuator 100. FIG. 1A shows droplet actuator 100 when not assembled, while FIG. 1B shows droplet actuator 100 when assembled. Droplet actuator 100 includes top substrate 112 comprising gap-setting features 116. Droplet actuator 100 includes a non-planar bottom substrate 110. Bottom substrate 110 may be forced against the gap-setting features 116. A spring 118 is provided to force bottom substrate 110 against gap-setting features 116. Bottom substrate 110 may be a substantially flexible and non-planar substrate. In one example, bottom substrate 110 may be formed of printed circuit board (PCB) material or other plastic material. As illustrated, bottom substrate 110 is substantially non-planar. However, it will be appreciated that the configuration shown may also be used to couple a planar bottom substrate to a top substrate. Top substrate 112 may be a substantially rigid and planar substrate. In one example, top substrate 112 may be formed of injection molded plastic that is suitably thick or otherwise supported to provide a predetermined rigidity and planarity. Clip members 114 may be integrated into or coupled to top substrate 112. For example, clip members 114 may be integrated into or couple to at least two sides of top substrate 112. Gap-setting features 116 are arranged to project into the droplet operations gap and abut bottom substrate 110 when it is in assembled position, thereby providing a uniform gap height. Gap-setting features 116 are shown as part of the top substrate; however, it will be appreciated that gap-setting features may be part of the top substrate, part of the bottom substrate, a separate component provided between the top substrate and the bottom substrate (e.g., a gasket) or combinations of any of the foregoing arrangements. In the embodiment illustrated, the rigid and planar top substrate 112 along with the gap-setting features 116 defines the planarity of the assembly and the uniformity of the gap height. A sealing member 115, which may for example be a gasket, adhesive, or other sealing substance may be situated around a perimeter of the droplet operations gap in order to seal the gap.

Top substrate 112 is sized such that bottom substrate 110 may be fitted between the clip members 114 and forced against gap-setting features 116. As shown in FIGS. 1A and 1B, a back plate 118, which is a leaf-spring type of back plate, is fitted against the outer surface of bottom substrate 110. The ends of back plate 118 are snapped into clip members 114 of top substrate 112. In this manner, spring force is applied to bottom substrate 110 forcing it against the gap-setting features 116 of top substrate 112, as shown in FIG. 1B. Due to the flexibility of bottom substrate 110 (e.g., a PCB) the topology of the droplet operations surface of bottom substrate 110 is forced into conformity with the topology of the gap-setting features 116, which is substantially planar. In this manner, a uniform gap height may be achieved even when bottom substrate 110 is not planar. FIG. 1B shows a substantially uniform droplet operations gap 120 between bottom substrate 110 and top substrate 112. Sealing member 115, which is situated around a perimeter of the droplet operations gap, seals the gap. The sealed gap may include a filler fluid, e.g., the sealed gap may be partially or completely filled with a filler fluid. One or more openings (not shown) may be included in the top and/or bottom substrates for adding fluid (liquid or gas) into or removing fluid (liquid or gas) from the droplet operations gap 120.

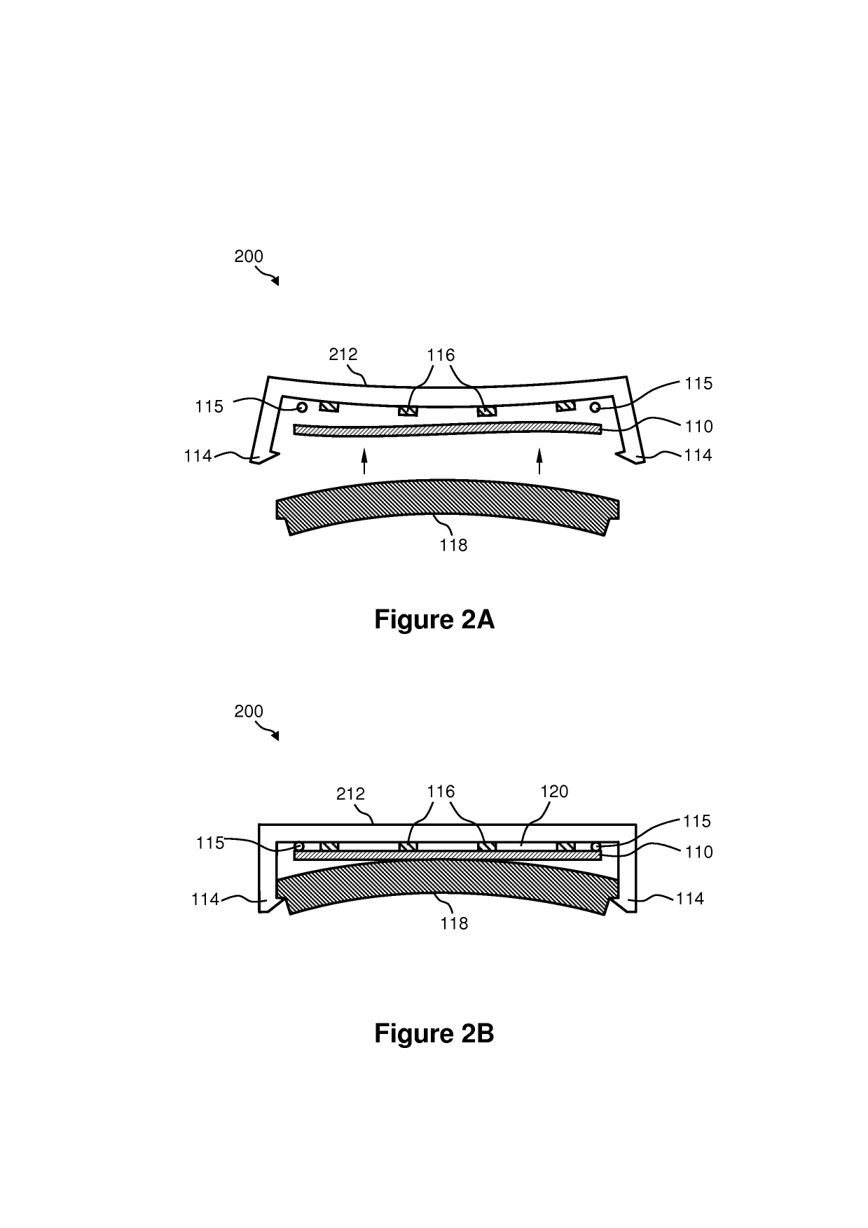

FIGS. 2A and 2B illustrate cross-sectional side views of a droplet actuator 200. In droplet actuator 200, top substrate 212 is also non-planar. FIG. 2A shows droplet actuator 200 when not assembled; FIG. 2B shows droplet actuator 200 when assembled. Droplet actuator 200 is substantially the same as droplet actuator 100 of FIGS. 1A and 1B except that top substrate 112, which is rigid, is replaced with a top substrate 212, which is flexible. Thus, top substrate 212 also operates as a spring. Top substrate 212 may be formed of a flexible material, such as injection molded plastic. Top substrate 212 includes clip members 114 and gap-setting features 116 as described with reference to FIGS. 1A and 1B. Sealing member 115, as described in FIGS. 1A and 1B, may be situated around a perimeter of the droplet operations gap in order to seal the gap, which may be filled with a filler fluid.

The ends of back plate 118 are snapped into clip members 114 of top substrate 212. In this manner, spring force is applied to bottom substrate 110 forcing it against the gap-setting features 116 of top substrate 212, as shown in FIG. 2B. The flexibility of bottom substrate 110 (e.g., a PCB) and of top substrate 212 are selected such that when gap-setting features 116 abut bottom substrate 114 the result is a substantially uniform gap height. It should be noted, that in some embodiments, the gap height may be substantially uniform, while the top and bottom substrates are not substantially planar. In other embodiments the materials are selected and arranged such that coupling back plate 118 two top plate 116 results in a substantially uniform gap height and substantially planar top and/or bottom substrates. Generally speaking, the topology of the droplet operations surface of bottom substrate 110 follows the topology of the gap-setting features 116, resulting in a substantially uniform gap height. FIG. 2B shows a substantially uniform gap 120 between bottom substrate 110 and top substrate 212. One or more openings (not shown) may be included in the top and/or bottom substrates for adding fluid (liquid or gas) into or removing fluid (liquid or gas) from the droplet operations gap 120.

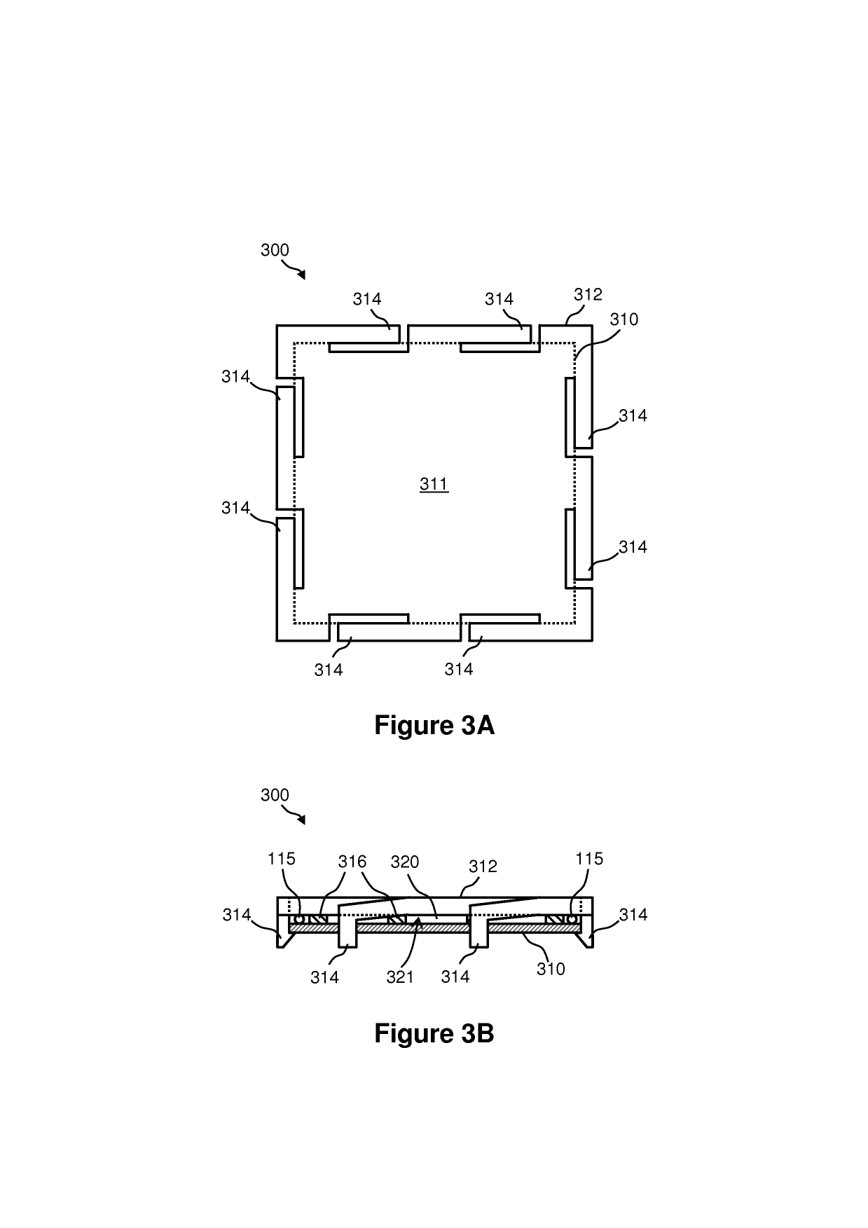

FIGS. 3A and 3B illustrate a top view and a side view, respectively, of a droplet actuator 300 that uses cantilever springs to provide spring forces for forcing a bottom substrate against gap-setting features of a top substrate. (As already noted, in this and other examples, the gap height setting features may be provided on the bottom substrate or on both substrates.) As illustrated here, droplet actuator 300 includes a bottom substrate 310 that may be forced against gap-setting features of a top substrate 312 via spring forces. In one example, bottom substrate 310 may be a PCB or other plastic material that may or may not be planar. In one example, top substrate 312 may be a substantially rigid and planar substrate having a substrate body 311 and a set of cantilever spring clip members 314 formed or coupled thereto around its perimeter. In one example, substrate body 311 is formed of injection molded plastic and has a thickness or other features rendering it rigid and substantially planar. Multiple clip members 314 are provided around the periphery of top substrate 312 so that bottom substrate 310 can be secured on all sides. Additionally, gap-setting features 316, such as spacers, are formed on droplet operations surface 321 of top substrate 312. Top substrate 312 is sized such that bottom substrate 310 may be fitted within the arrangement of clip members 314 and forced against gap-setting features 316 by clip members 314. In this embodiment, no back plate is required. Clip members 314 are designed to function as cantilever springs such that when clipped to the edges of bottom substrate 310, the cantilever springs force bottom substrate 310 into contact with gap height setting features 316. Again, sealing member 115, as described in FIGS. 1A and 1B, may be situated around a perimeter of the droplet operations gap in order to seal the gap, which may be filled with a filler fluid.

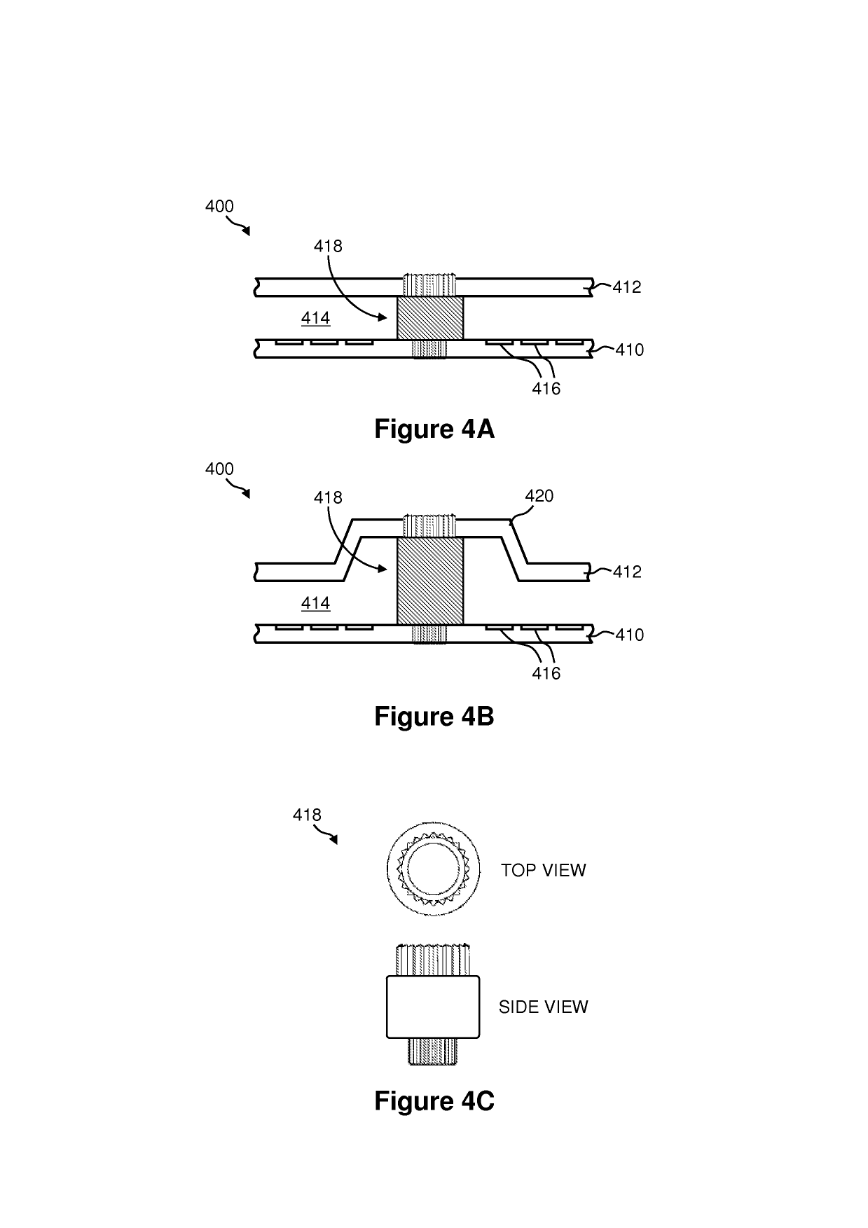

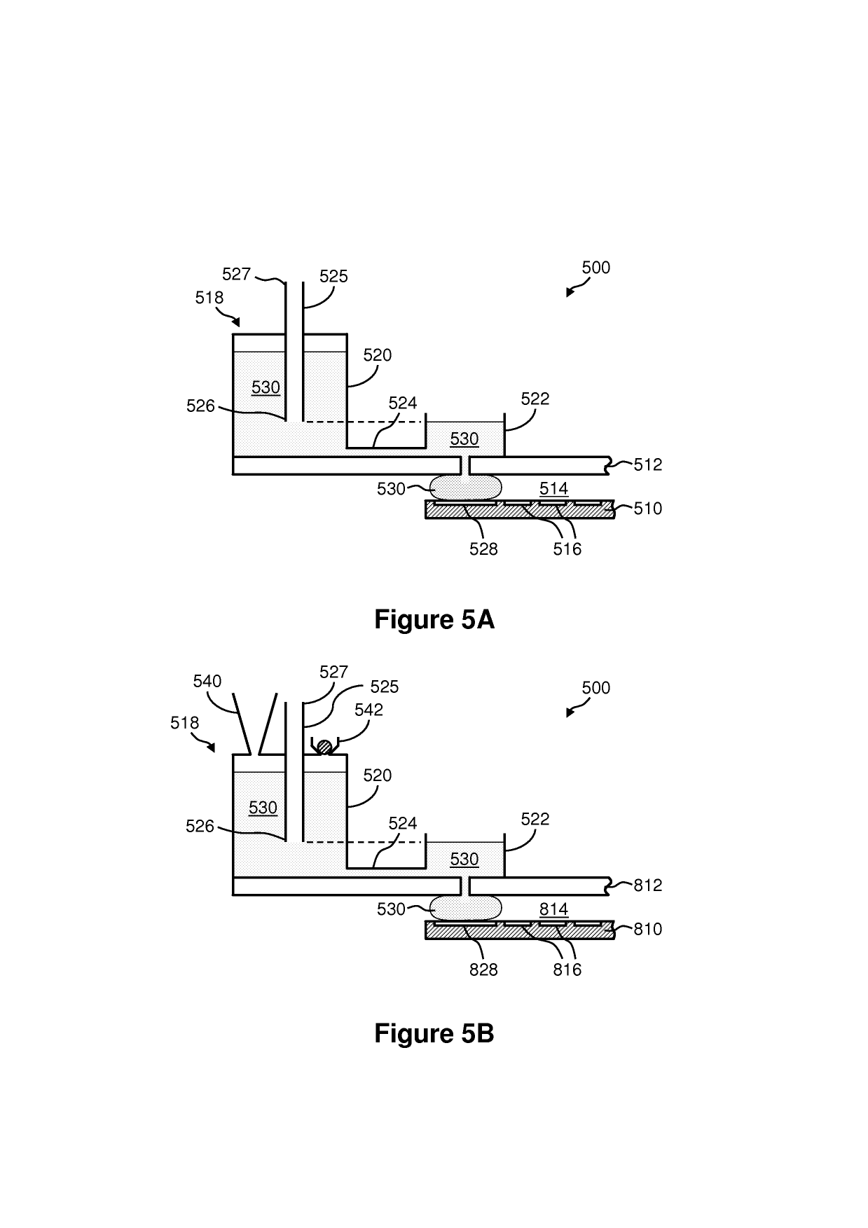

FIGS. 4A and 4B illustrate cross-sectional side views of a portion of an example of a droplet actuator 400 that uses z-axis connectors between the bottom and top substrates. FIG. 4C illustrates top and side views of an example of a z-axis connector. Droplet actuator 400 may include a bottom substrate 410 and a top substrate 412 that are separated by droplet operations gap 414. Droplet actuator 400 may include an arrangement of droplet operations electrodes 416 (e.g., electrowetting electrodes) that may be associated with bottom substrate 410, top substrate 412, or both substrates. Droplet operations are conducted atop droplet operations electrodes 416 in droplet operations gap 414.

Multiple z-axis connectors 418 may be placed between bottom substrate 410 and top substrate 412 at designated locations for setting the droplet operations gap 414 of droplet actuator 400. A step, such as a step 420, may be provided in the profile of top substrate 412 to accommodate the height of each z-axis connector 418. The z-axis connectors 418 may be implemented as any type of commercially available (or custom made) “board-to-board” connectors, such as broach style fasteners, pin connectors, and the like.

In the example shown in FIGS. 4A and 4B, z-axis connector 418 is implemented by a broach style fastener (available from Mill-Max Mfg. Corp, Oyster Bay, N.Y. and PennEngineering, Danboro, Pa.). More details of a broach style fastener are shown in FIG. 4C. In this example, openings are provided in bottom substrate 410 and top substrate 412 into which the pins of the broach style fastener are fitted (e.g., press fitted). The body of the broach style fastener provides a spacer between bottom substrate 410 and top substrate 412. In this manner, multiple broach style fasteners may be used as the gap-setting components of droplet actuator 400. Referring to FIG. 4B, in some instances, a step, such as a step 420 or recessed region may be provided in the profile of top substrate 412 to accommodate the height of the body of the broach style fastener.

Referring to FIGS. 1A through 4C, any combinations of the mechanisms for assembling and/or spacing the bottom and top substrates of a droplet actuator may be used.

### 7.2 Droplet Actuators and Methods of Use

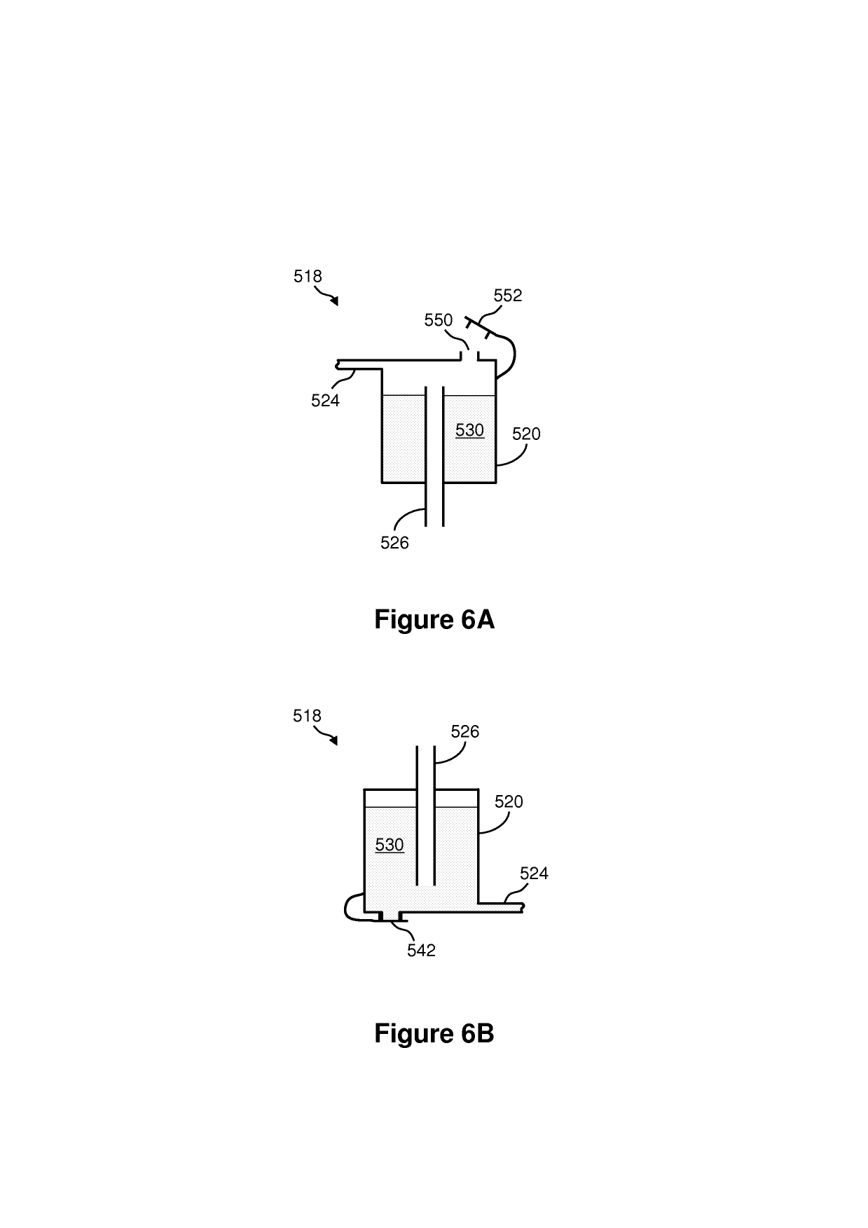

FIGS. 5A and 5B illustrate cross-sectional side views of a portion of a droplet actuator 500. Droplet actuator 500 may include a bottom substrate 510 and a top substrate 512 that are separated by a droplet operations gap 514. Droplet actuator 500 may include an arrangement of droplet operations electrodes 516 (e.g., electrowetting electrodes) that may be associated with bottom substrate 510, top substrate 512, or both substrates. Droplet operations electrodes 516 are arranged to conduct droplet operations. Droplet operations are conducted in droplet operations gap 514. Referring to FIG. 5A, a reservoir assembly 518 is coupled to or formed together with top substrate 512. Reservoir assembly 518 includes a large capacity reservoir 520 that is coupled via a flow path 524 to a small capacity reservoir 522. Large capacity reservoir 520 is fully enclosed and sealed, except for a vent tube 525 provided through the cover of large capacity reservoir 520. That is, a first end 526 of vent tube 525 is inside the large capacity reservoir 520 while a second end 527 of vent tube 525 is outside of large capacity reservoir 520 and in the surrounding atmosphere. The small capacity reservoir 522 is substantially aligned with a reservoir electrode 528 atop bottom substrate 510. Large capacity reservoir 520 and small capacity reservoir 522 may contain an amount of liquid 530 that may be dispensed into droplet actuator 500 via reservoir electrode 528. The level of liquid 530 in small capacity reservoir 522 substantially aligns with the height of end 526 of vent tube 525 in large capacity reservoir 520.

For example, reservoir assembly 518 of this invention provides a large capacity reservoir and at the same time provides low pressure volume of liquid in a small capacity reservoir that does not overcome the electrowetting forces of the droplet actuator and, therefore, avoids flooding the droplet actuator. The low pressure is due to the presence of vent tube 525 which is submerged in liquid 530, thereby enabling liquid 530 to flow from large capacity reservoir 520 through flow path 524 into small capacity reservoir 522, while restricting that flow in preventing the overflow of small capacity reservoir 522.

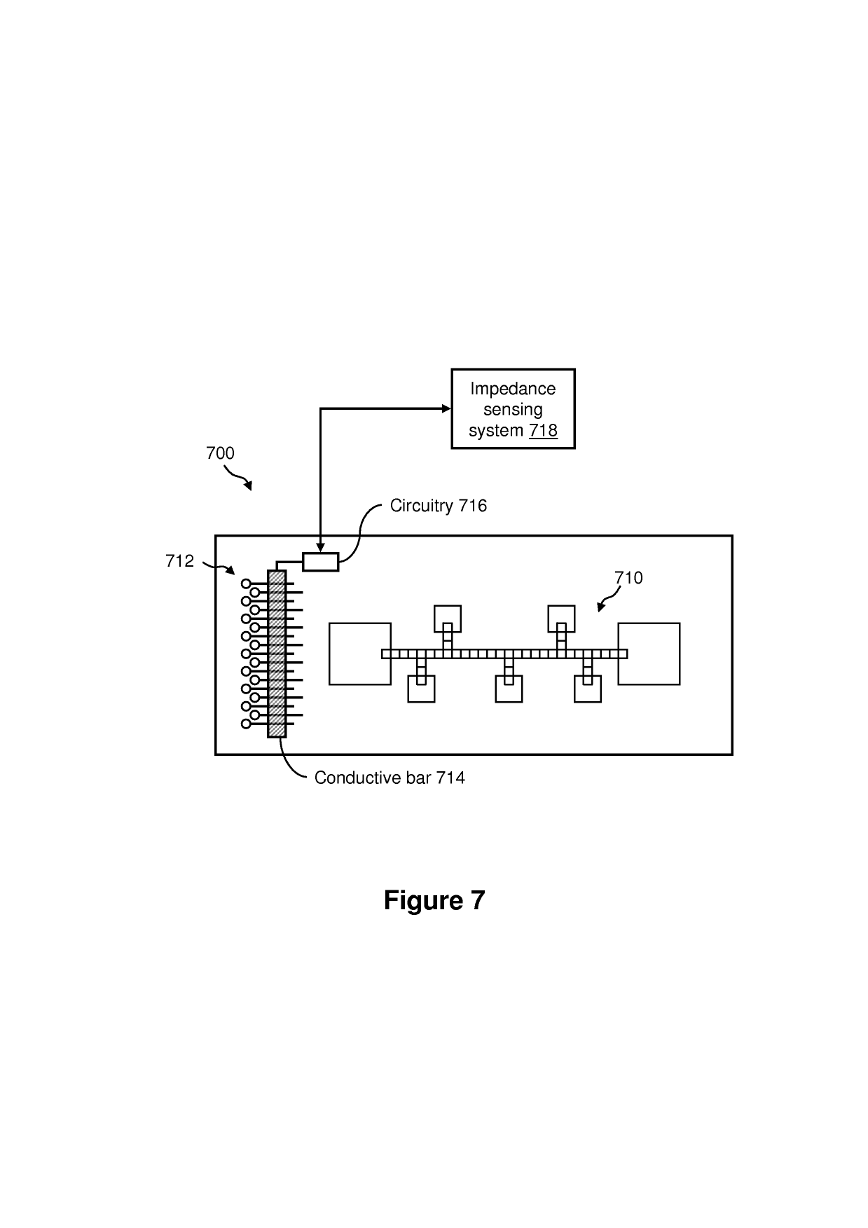

Referring to FIG. 5B, in another example a filler inlet 540 and a valve, such as a ball valve 542, are provided atop the large capacity reservoir 520 portion of reservoir assembly 518. The valve permits an additional level of control of the flow of liquid from large capacity reservoir 520 into small capacity reservoir 522. More details of a method of using reservoir assembly 518 are described with reference to FIGS. 6A and 6B.

FIGS. 6A and 6B illustrate cross-sectional side views of a process of using reservoir assembly 518 of FIGS. 5A and 5B. Reservoir assembly 518 may be designed to be detachable from the droplet actuator. For example, FIG. 6A shows reservoir assembly 518 detached from droplet actuator 500 and in an inverted position for filling. In this example, the large capacity reservoir 520 portion of reservoir assembly 518 further includes a filler port 550 that may be capped via a cap 552 that is accessible only when in the inverted position. FIG. 6A shows that filler port 550 may be opened and an amount of liquid 530 is poured into large capacity reservoir 520. In particular, large capacity reservoir 520 is filled to a level that is slightly below the end of vent tube 525 in this inverted position, as shown in FIG. 6A. Once filled, large capacity reservoir 520 is capped off via cap 552 and reservoir assembly 518 may be returned to the non-inverted position (see FIG. 6B) and provided atop droplet actuator 500 for use.

Referring to FIGS. 5A, 5B, 6A, and 6B, reservoir assembly 518 is easy to load and allows a large volume of liquid to be stored above the droplet actuator while reducing, preferably entirely eliminating, the risk of flooding the droplet actuator.

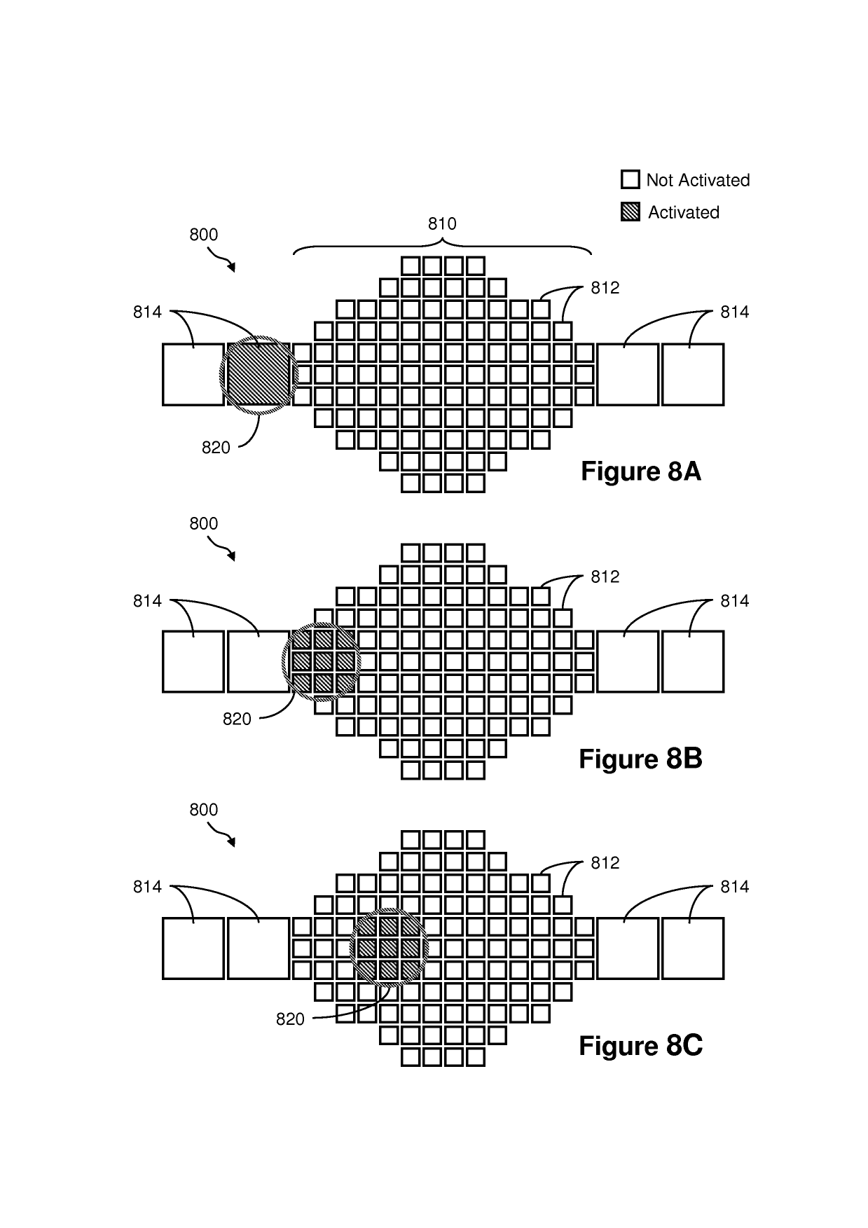

FIG. 7 illustrates a top view of an example of a substrate 700, such as a PCB, of a droplet actuator (not shown) that includes simple mechanisms for performing a quality control check on the control channels thereof. In this example, substrate 700 is a PCB that includes an electrode arrangement 710 and control channels 712. Control channels 712 are used for controlling the electrode arrangement 710, such as for applying electrowetting voltages.

Currently, the process of manufacturing droplet actuators may involve costly and highly complex comprehensive testing processes. Accordingly, an aspect of this invention is that is provides a configuration that facilitates a less comprehensive testing process, that is simple and inexpensive to implement, and yet provides enough information to achieve a high degree of confidence about the operation of droplet actuators.

Substrate 700 is associated with a conductive bar 714 situated across the area of control channels 712. Conductive bar 714 may be external to the substrate or within the substrate on a different level, such as a different wiring layer of a PCB or semiconductor layout. Conductive bar 714 may be formed of any electrically conductive material. In one example, conductive bar 714 is a copper bar. Circuitry 716 is also provided on substrate 700. Circuitry 716 connects to conductive bar 714 and also interfaces with an external impedance sensing system 718. Circuitry 716 is used to selectively connect conductive bar 714 to an impedance sensing system 718, e.g., an impedance spectrometer. By turning on individual control channels 712 during impedance sensing, an impedance measurement between each individual control channel 712 and the conductive bar 714 may be used to confirm activation of control channels 712 and to determine when activation of any of the control channels 712 is not effective. Optionally, to discriminate which control channel 712 is turned on, a resistor ladder may be present that is connected to pads under each control channel 712. This configuration permits a control check that provides a high degree of confidence that the control channels are being asserted correctly. In one example, the test may be run every time the droplet actuator is powered up to confirm readiness for operation before running assays.

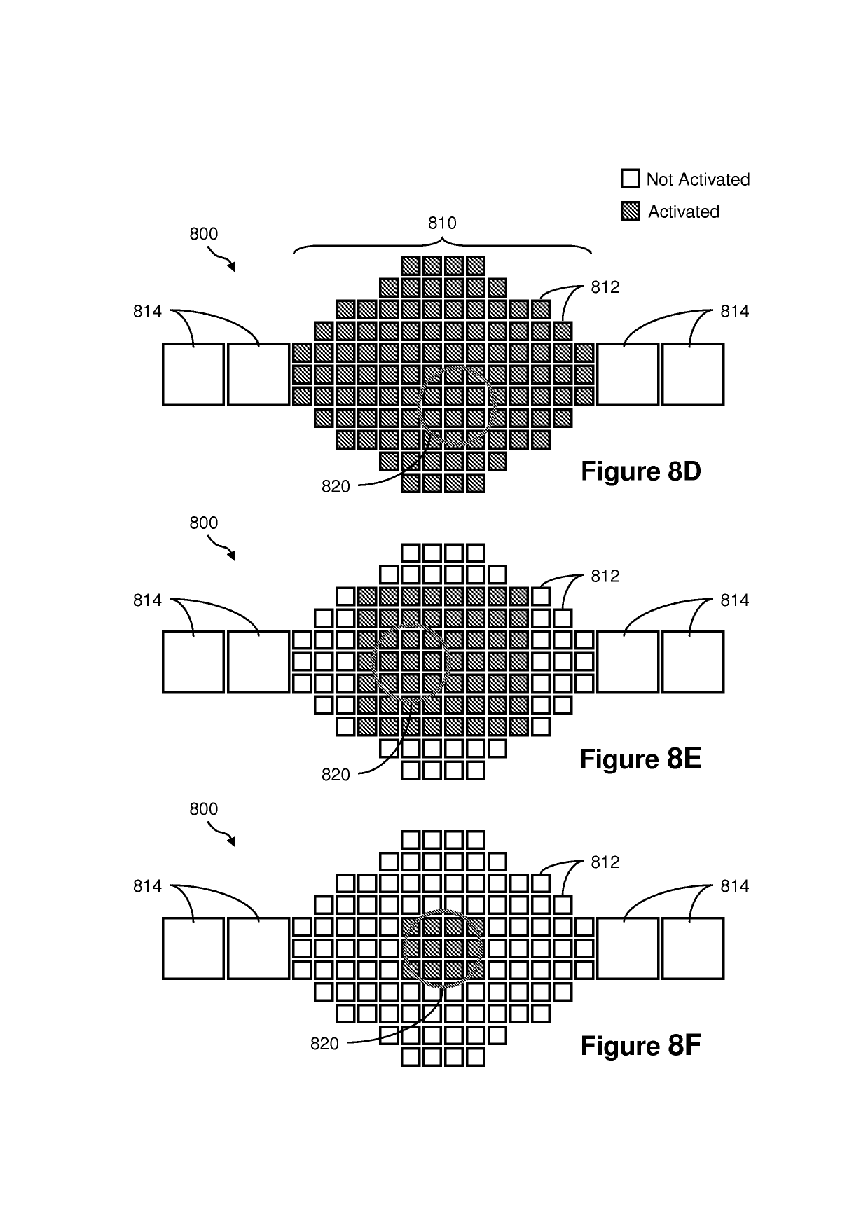

FIGS. 8A through 8I illustrate top views of an example of an electrode arrangement 800 and a process of impedance detection for determining droplet volumes. The invention provides a novel electrode arrangement for volumetric metering using impedance that allows for a droplet to be brought to a special metering area, measured, and then reliably removed. Electrode arrangement 800 may be patterned on a substrate of a droplet actuator (not shown). Electrode arrangement 800 includes an impedance detection region 810 that is formed of an array or pattern of impedance measuring electrodes 812. Leading into and out of the pattern of impedance measuring electrodes 812 that form impedance detection region 810 is an arrangement of droplet operations electrodes 814.

The size (in area) of each individual impedance measuring electrode 812 is some fraction smaller than the size (in area) of each individual droplet operations electrodes 814. In one example, a 3×3 array of impedance measuring electrodes 812 is about the same area as a single droplet operations electrode 814. That is, each impedance measuring electrode 812 is less than about one ninth the size of each droplet operations electrode 814. Associated with electrode arrangement 800, but not shown, is an impedance sensing system, such as an impedance spectrometer. In one example, electrode arrangement 800 may be patterned on the bottom substrate of a droplet actuator, where the droplet actuator includes the bottom substrate and a top substrate that are separated by a droplet operations gap. Using the impedance sensing system, impedance may be measured at each of the impedance measuring electrodes 812 across the droplet operations gap between the bottom substrate and the top substrate. Impedance measuring electrodes 812 may be individually scanned, scanned in various combinations, or impedance may be measured simultaneously.

The footprint of a droplet situated on impedance measuring electrodes 812 may be measured by determining the impedance at each of the electrodes. The volume of the droplet may be determined based on the area of the footprint. The impedance measuring electrodes 812 may be operated as a single electrowetting electrode in order to transport the droplet from an array of electrowetting electrodes onto the impedance measuring electrodes 812. Following measurement of droplet volume, subsets of the impedance measuring electrodes 812 may be activated in order to transport the droplet across the impedance measuring electrodes 812 and back onto the array of electrowetting electrodes. The impedance measuring electrodes 812 may also be used to conduct other droplet operations, such as dispensing sub droplets off of the primary droplet in order to reduce its volume; splitting the droplet; merging the droplet with other droplets in order to increase droplet volume. In this manner, a droplet may be prepared with a predetermined volume.

Referring to FIG. 8A, a droplet 820, which may be a droplet is transported via droplet operations along droplet operations electrodes 814 and to a position which is adjacent to impedance measuring electrodes 812 of impedance detection region 810.

Referring to FIG. 8B, droplet 820 is transported via droplet operations into impedance detection region 810 by activating (but not all) impedance measuring electrodes 812.

Referring to FIG. 8C, droplet 820 is transported via droplet operations into a central region of impedance detection region 810 by activating other (but not all) impedance measuring electrodes 812.

Referring to FIG. 8D, impedance is measured at the collective set of impedance measuring electrodes 812 in impedance detection region 810. In some embodiments, the footprints of the droplet may be determined and the volume of the droplet may be calculated at this step.

FIGS. 8E and 8F illustrate a further refinement in which the impedance measuring electrodes in impedance detection region 810 are deactivated in stages from the outside in, in order to “coral” droplet 820. At each step of the corralling process, an impedance measurement is taken. The volume of droplet 820 may be calculated when the droplet is at its smallest possible size (FIG. 8F). The corralling process also has the further advantage that it permits a set of electrodes which is smaller than the footprint of the droplet to retain the droplet in place by electrowetting, so that the shape of the footprint of the droplet is not distorted by the electrowetting effect during the impedance measurement which determines the footprint that serves as the basis for calculation of the volume of the droplet.

Referring to FIGS. 8G, 8H, and 8I, once the impedance measurement is completed, droplet 820 is transported via droplet operations out of impedance detection region 810 and back onto droplet operations electrodes 814.

Referring to FIGS. 8A through 8I, this invention provides higher accuracy and more volume flexibility than current methods. The invention may also be used in 2-stage dispensers, as it is well-suited for measuring large volumes.

### 7.2.1 Charged Surfaces in Droplet Actuators and Associated Methods

Currently, for operations (e.g., impedance detection, capacitance detection, and noise sensitive applications like fluorescence detection) the alternating current (AC) mode is temporarily quieted and the droplet actuator is put into a direct current (DC) mode while sensitive measurements are taken. However, it has been found that when droplet actuators are run in DC mode for a long period of time, the droplets become sluggish and stop moving. The droplets seem to get stuck or “pinned” on the electrode at which they were subjected to the DC mode for a long period of time. This is because over time the surfaces (e.g., dielectric surfaces) in droplet actuators become charged. Further, a problem exists in that returning to AC mode does not reverse the effect, the surface remains charged and, thus, the droplet remains pinned.

Accordingly, some embodiments of the invention provide methods of reversing the surface charge effect in a droplet actuator. Other embodiments of the invention provide methods of using charged surfaces to advantage in a droplet actuator. Another embodiment of the invention provides a method of quantifying the rate of surface charging or discharging in a droplet actuator.

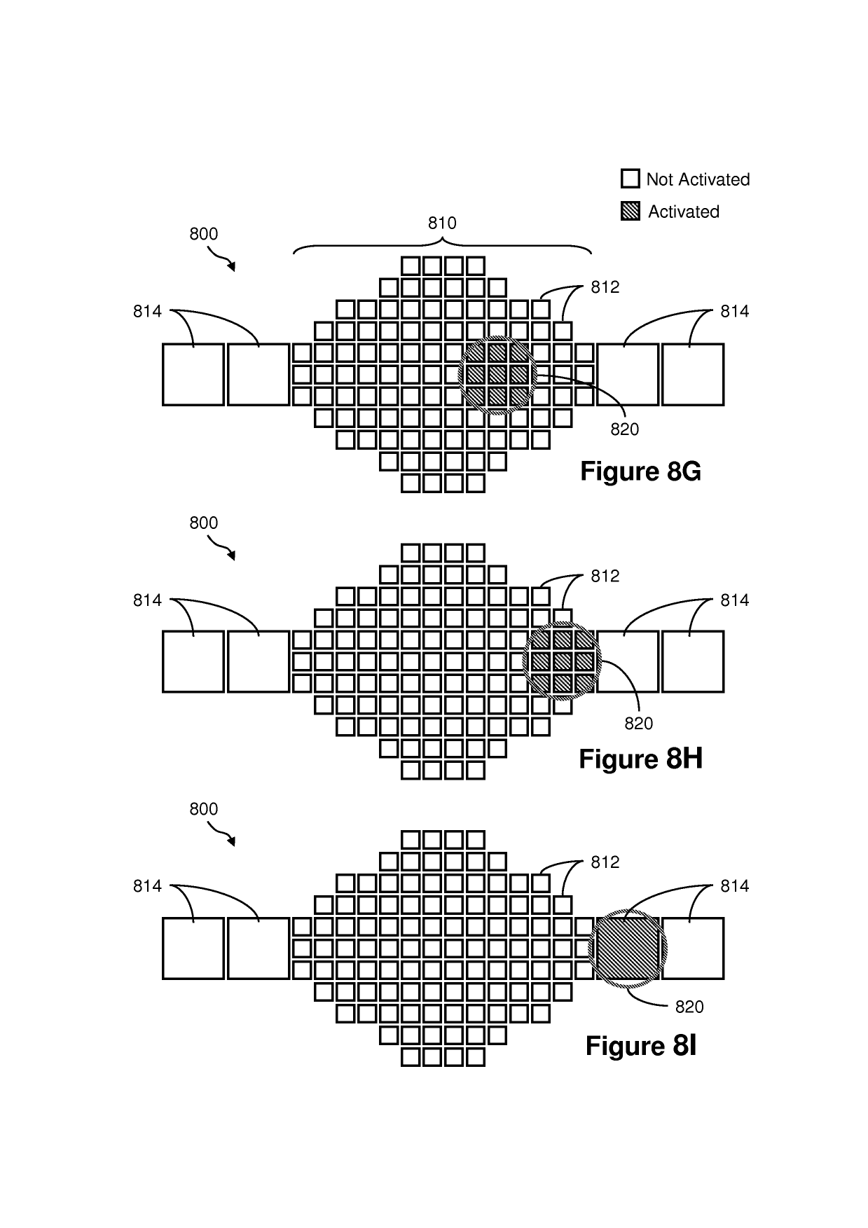

FIG. 9 illustrates a flow diagram of an example of a method 900 of reversing the surface charge effect in a droplet actuator. Method 900 may include, but is not limited to, the following steps.

At step 910, droplet operations are performed in DC mode of operation according to an assay protocol. Examples of operations that are performed in DC mode include, but are not limited to, impedance detection, capacitance detection, and noise sensitive operations like fluorescence detection, absorbance detection, and other methods of optical detection. While in DC mode, the DC voltage value that is applied to one or more electrodes is recorded and the amount of time spent in DC mode is recorded. In one example, +300 volts DC is applied for about 100 milliseconds (ms). Therefore, +300 volts DC and 100 ms is recorded. In other embodiments, the DC voltage value and the amount of time spent in DC mode are predetermined and controlled. In this case, no recording is necessary.

At step 912, a DC charge that is opposite in polarity from that which was recorded in step 910 (or from that which was predetermined charge) is applied for the same amount of time that was recorded in step 910 (or the same amount of time that was predetermined). Continuing the example, if +300 volts DC and 100 ms is recorded at step 912, then at this step −300 volts DC is applied for about 100 ms. By applying the opposite DC charge for the same amount of time, the surface charge effect in a droplet actuator may be substantially reversed. In other embodiments, instead of applying the opposite charge for a period of time that is the same as the charge in step 910, it may be possible to vary the characteristics of the opposite charge. Therefore, the discharging of the surface may be performed in an amount of time that is different from the time that the first charge was applied.

At step 914, the droplet actuator is returned to the AC mode of operation for continuing the assay protocol, i.e., additional droplet operations may be performed in AC mode.

In summary, when in DC mode, by spending a substantially equal amount of time in each of the positive and negative states, the surface charge effect in a droplet actuator may be substantially reversed. While method 900 may be performed in real time for each individual electrode, in another embodiment, the DC voltage values and the amount of time spent in DC mode for multiple electrodes may be stored in a lookup table. Then, when it is convenient to the protocol, method 900 may be executed on the multiple electrodes for reversing the surface charge effects thereon. In this manner, the interference of surface charge with droplet operations that is typically encountered with the use of DC voltage may be avoided.

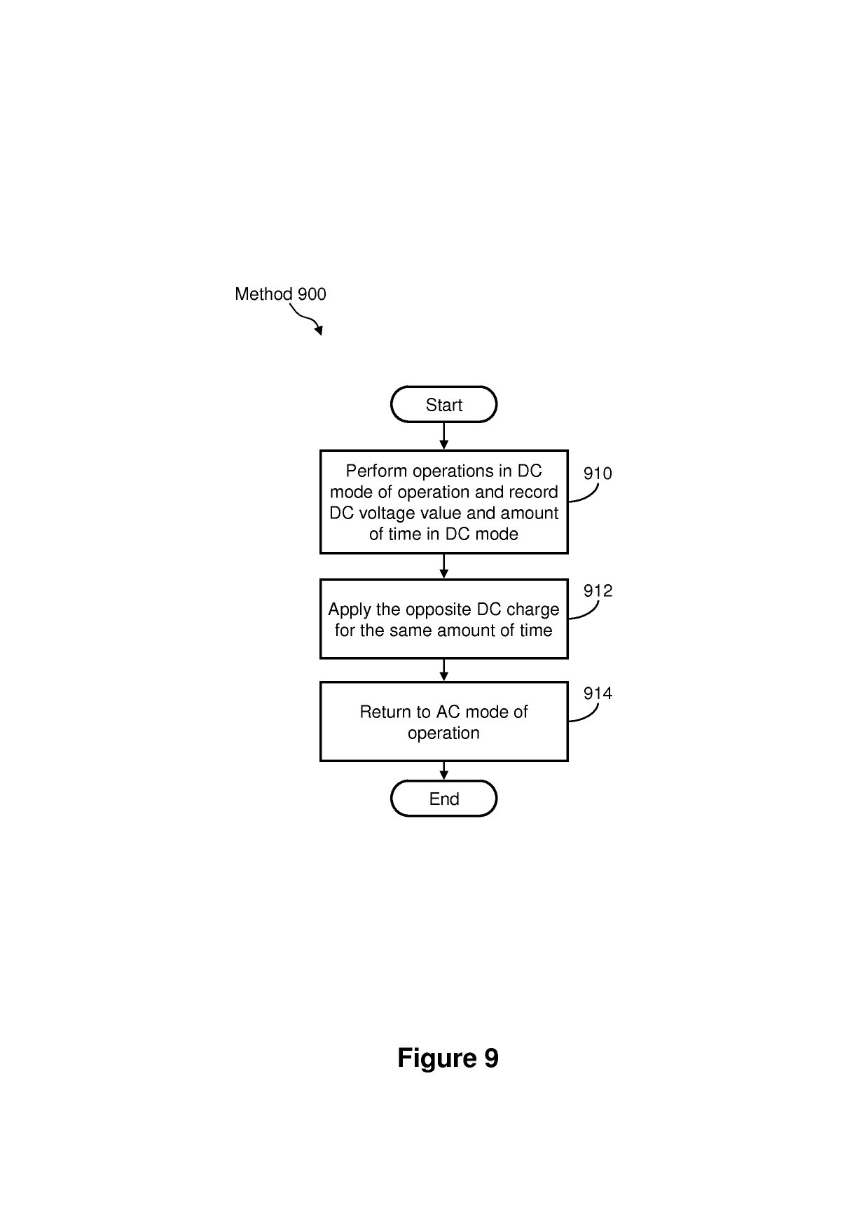

FIG. 10 illustrates a flow diagram of an example of a method 1000 of using the surface charge effect to retain droplets in position within the droplet operations gap during handling the droplet actuator. Droplets are subject to dislocation when they are removed from a droplet actuator and handled robotically or manually. The invention provides methods of using the surface charge effect to advantage for retaining droplets in position when handling a droplet actuator cartridge. Method 1000 may include, but is not limited to, the following steps.

At step 1010, droplet operations are conducted in the droplet operations gap of the droplet actuator, which results in droplets being distributed atop certain electrodes of the droplet actuator.

At step 1012, DC voltage is applied to charge the certain electrodes in order to retain the droplets in position within the droplet operations gap of the droplet actuator for handling the droplet actuator.

At step 1014, the droplet actuator is manually or robotically removed from the instrument deck.

At step 1016, subsequent steps are conducted, such as placing the droplet actuator on a rack, placing the droplet actuator in an incubator, placing the droplet actuator in a reading device, placing the droplet actuator on another electrowetting system for subsequent electrowetting steps, or returning the droplet actuator to the same electrowetting system for subsequent electrowetting steps.

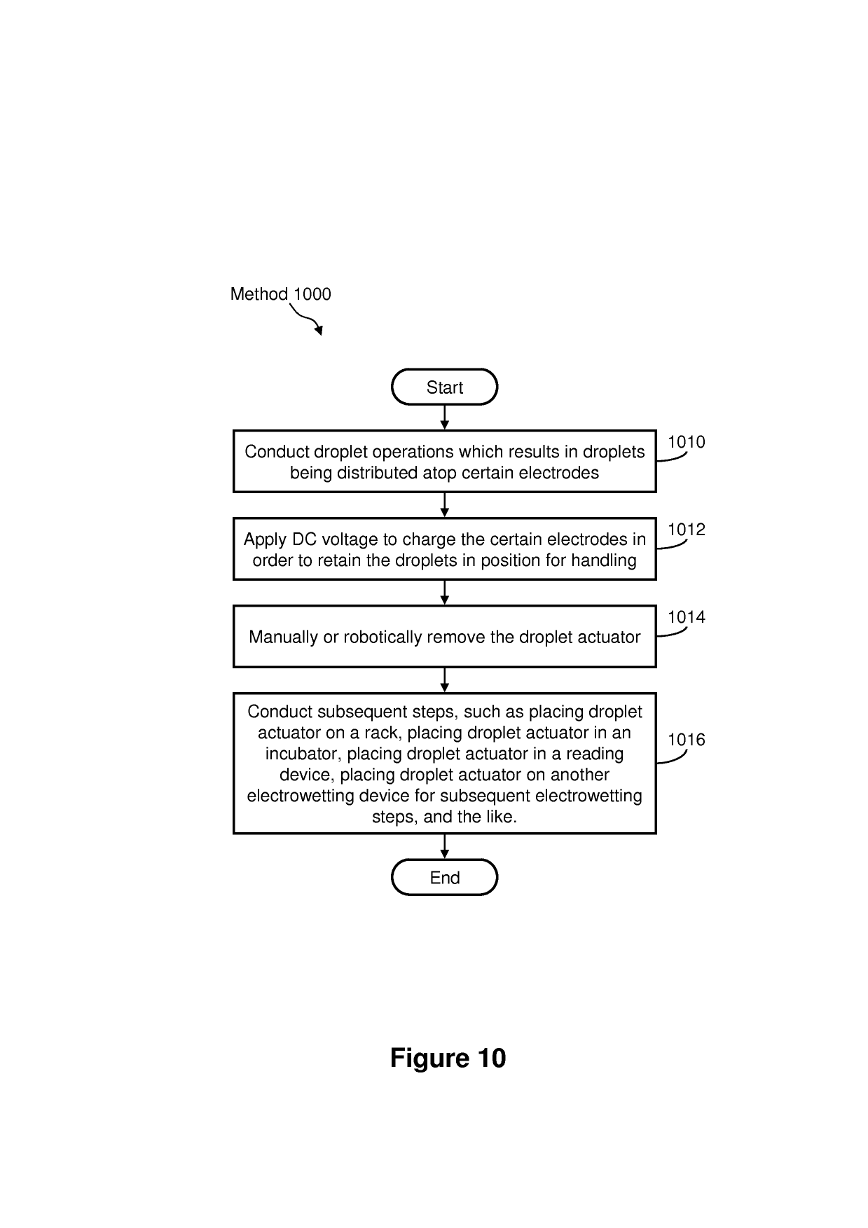

FIG. 11 illustrates a flow diagram of an example of a method 1100 of using impedance detection to quantify the rate of surface charging in a droplet actuator. Currently, it is difficult to determine the degree of surface charge effect that may be occurring and/or present in a droplet actuator. Accordingly, the invention provides a method of using impedance detection to quantify the rate of surface charging in a droplet actuator. Method 1100 may include, but is not limited to, the following steps.

At step 1110, with the controller in AC mode, a droplet is dispensed and then transported using droplet operations to an electrode and then “parked” at that electrode.

At step 1112, with the controller in DC mode, the electrode is exposed selectively to a DC field. That is, the electrode is turned on and a DC voltage is applied.

At step 1114, with the controller in AC mode, attempts are made to transport the droplet away from the electrode on which it is parked. The charging effect is exhibited in the “pinning” of the droplet to the electrode on which it is parked. The strength of the droplet “pinning” effect is directly proportional to the amount of accumulated surface charge. Beyond a charge threshold, some amount of the droplet material may be left behind on the charged electrode.

At step 1116, impedance detection is used to determine how much time it takes to actually move the droplet away from the electrode to which it is pinned, then correlate this time to the amount of surface charging. The greater the surface charge, the slower the droplet will be to move away from that electrode. Accordingly, impedance detection is used to indicate the timing of the transport of the droplet. The timing of droplet transport is correlated with the amount of surface charging. An alternative approach may be to gradually ramp up the voltage applied to the adjacent electrode, and identify the voltage at which the droplet actually moves away from the surface charged surface. That voltage would correlate with the amount of surface charge.

At step 1118, the droplet is shuttled back and forth between the electrode of interest and an adjacent electrode, while at the same time the electrode of interest is exposed to a DC field for longer and longer time periods. A total accumulated charge and charge accumulation time constant (as well as other potentially useful parameters) can be gleaned automatically by harvesting impedance data (i.e., based on droplet coverage), which indicates the total amount of droplet material that is left on the electrode.

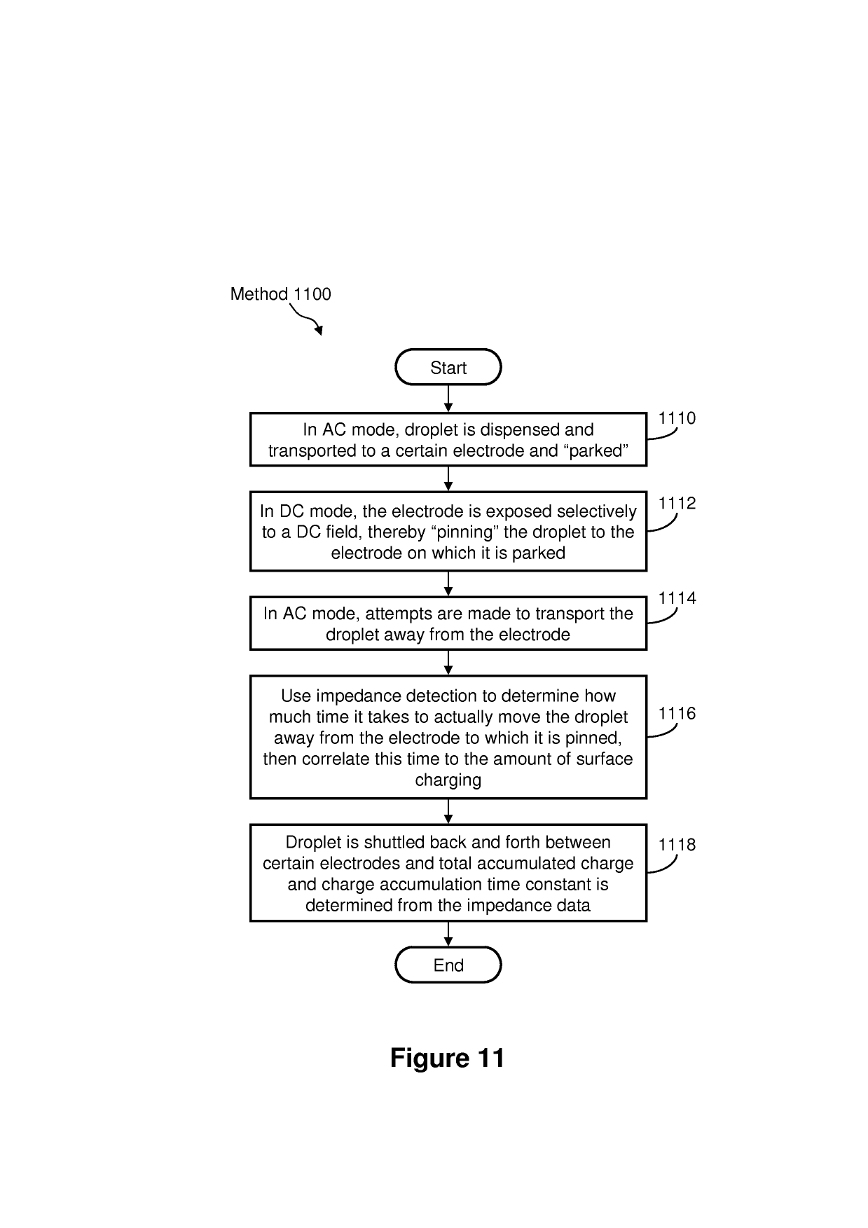

FIG. 12 illustrates a flow diagram of an example of a method 1200 of using droplet pinning due to surface charge effect as an indicator of temperature in a droplet actuator. Literature about spatial charging in dielectric films, such as polyimide film (e.g., KAPTON® polyimide film), suggests that discharge rates may be altered by changes in temperature. For example, higher temperatures tend to correspond to faster discharge rates. Consequently, the droplet pinning effect is stronger or weaker depending on temperature. Therefore, changes in temperature may be observed by monitoring changes in the degree of droplet pinning. Accordingly, the invention provides a method of using droplet pinning due to surface charge effect as an indicator of temperature in a droplet actuator. The method of the invention may be used as a temperature feedback mechanism. For example, the method of the invention may be used to ensure that a heating mechanism of the droplet actuator is operating properly. Method 1200 may include, but is not limited to, the following steps.

At step 1210, with the controller in AC mode and the heater turned OFF, a droplet is dispensed and then transported using droplet operations to a electrode and then “parked” at that electrode.

At step 1212, with the controller in DC mode and the heater turned OFF, apply a DC voltage for a long enough time to cause the surface charge effect to occur at the electrode on which the droplet is parked, thereby causing the droplet to be pinned.

At step 1214, with the controller in AC mode and the heater turned ON, attempt to transport the droplet away from the electrode on which it is parked and monitor (e.g., using impedance detection) whether and/or when the droplet is released.

At step 1216, correlate droplet response of step 1214 to a temperature being present in the droplet actuator. For example, because higher temperatures tend to correspond to faster discharge rates, the time of the droplet's release may serve as an indicator of reaching a temperature, or may provide a simple feedback mechanism that the heater is working at all.

### 7.2.2 Droplet Actuator Controls

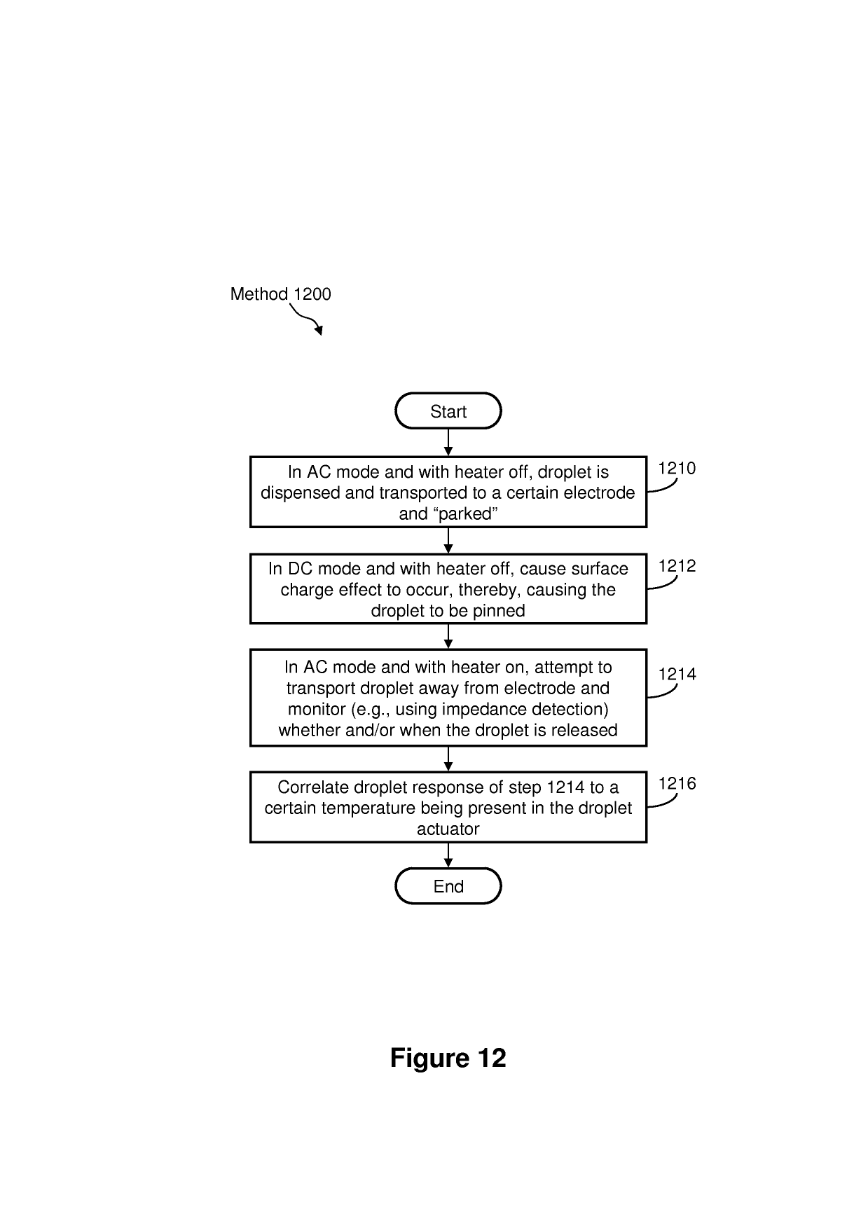

FIGS. 13A and 13B illustrate a cross-sectional side view and top view, respectively, of a portion of an example of a droplet actuator 1300 that includes dedicated high voltage channels to assist loading. High voltages seem to work better in the loading process of droplet actuators, which is a process of moving liquid from off-chip reservoirs to on-chip reservoirs. High loading voltages (e.g., about 1 kilovolt (kV) to about 10 kV) and lower electrowetting voltages (e.g., about ≦300 volts) may be multiplexed on the control channels of droplet actuators, but this has the disadvantage that it adds complexity to droplet actuator designs. The invention provides a droplet actuator that has dedicated high voltage control channels to assist loading, thereby reducing, preferably entirely eliminating, the need for multiplexing different voltages on droplet actuator control channels. In this manner, droplet actuator designs may be simplified.

Droplet actuator 1300 may include a bottom substrate 1310 and a top substrate 1312 that are separated by a droplet operations gap 1314. Droplet actuator 1300 may include an arrangement of droplet operations electrodes 1316 (e.g., electrowetting electrodes) that may be associated with bottom substrate 1310, top substrate 1312, or both substrates. Droplet operations are conducted atop droplet operations electrodes 1316 in droplet operations gap 1314.

A reservoir 1318 is coupled to or formed together with top substrate 1312. A reservoir electrode 1320 on bottom substrate 1310 is substantially aligned with reservoir 1318. Reservoir 1318 may contain an amount of liquid 1322. Liquid 1322 may be loaded from reservoir 1318 into droplet operations gap 1314 of droplet actuator 1300 using reservoir electrode 1320. Droplets 1324 may be dispensed from reservoir electrode 1320 onto droplet operations electrodes 1316. Reservoir 1318 is an example of an off-chip reservoir. The quantity of liquid 1322 atop reservoir electrode 1320 in droplet operations gap 1314 of droplet actuator 1300 is an example of an on-chip reservoir.

Referring to FIG. 13B, droplet actuator 1300 further includes channels for controlling droplet operations and a separate and dedicated channel for controlling loading. For example, droplet actuator 1300 may include a set of electrowetting (EW) channels 1330 for controlling droplet operations electrodes 1316. Additionally, both a high voltage (HV) channel 1332 and an EW channel 1334 may be coupled to reservoir electrode 1320. HV channel 1332 may be used for initial loading of the liquid at reservoir electrode 1320, while EW channel 1334 may be used for retention of the liquid in place after loading.

During the loading process, a high voltage, such as about 1 kV to about 10 kV, may be applied to HV channel 1332 for loading liquid 1322 from reservoir 1318 (i.e., an off-chip reservoir) onto reservoir electrode 1320 (i.e., an on-chip reservoir). Once loading is complete, the EW channels 1330 may be used for applying a lower voltage, such as about ≦300 volts, for controlling droplet operations electrodes 1316 and executing droplet operations, such as a droplet dispensing operation whereby a series of electrodes 1316 is activated to extend an elongated droplet out of the droplet situated atop electrode 1320, after which an intermediate electrode is deactivated to yield a dispensed droplet. Because HV channel 1332 and EW channels 1330 are independent of one another and are dedicated for functions, voltage multiplexing is not required on the control channels of droplet actuator 1300. In this manner, droplet actuator 1300 of the invention provides a simplified design.

Because of the separate HV channel 1332 that is dedicated for loading operations, loading may be easier and more reliable. That is, the HV channel 1332 (e.g., about 1 kV to about 10 kV) is used to promote stronger ingress of liquid into droplet operations gap 1314 of droplet actuator 1300, while the EW channels 1330 (e.g., about ≦300 volts) are used to maintain the liquid once it is loaded into droplet actuator 1300. Droplet actuator 1300 of the invention is not limited to one HV channel only. Any number of independent HV channels may be present for controlling any number of off-chip reservoirs.

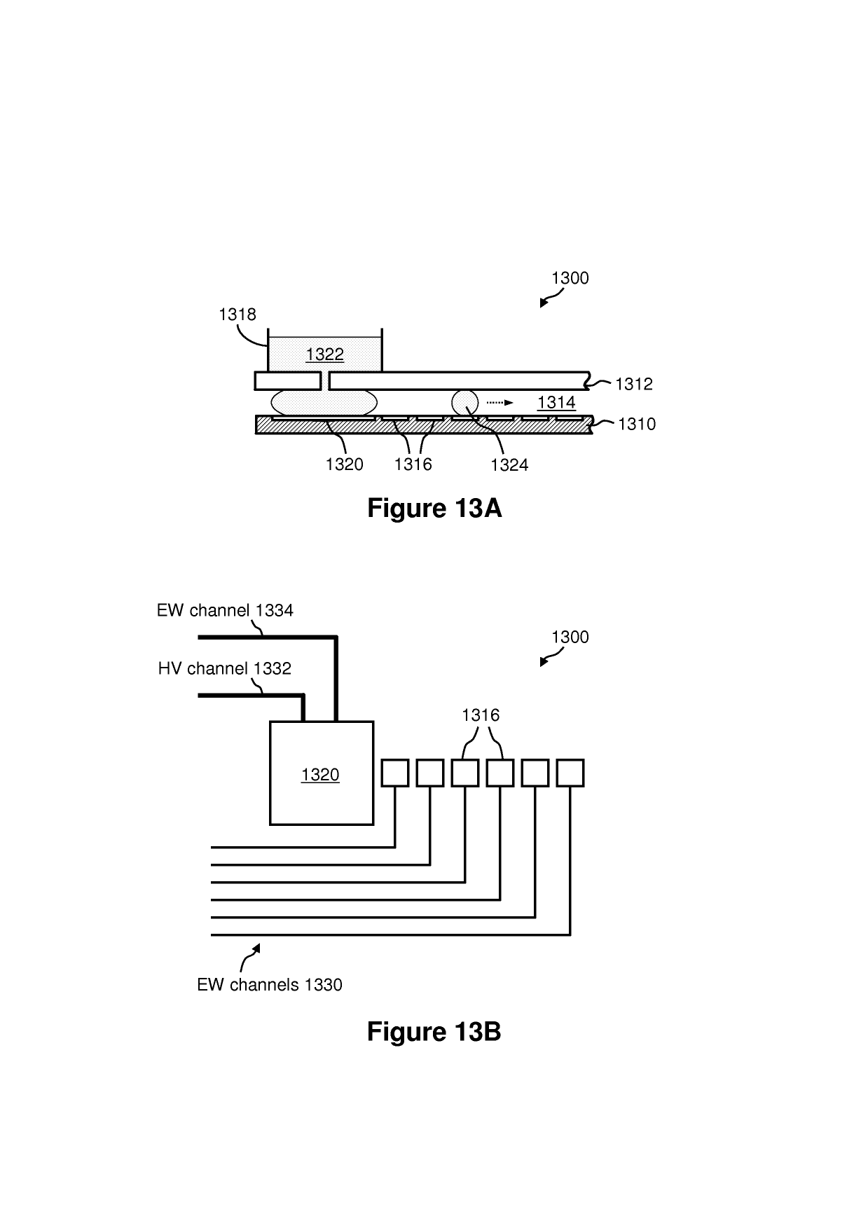

FIG. 14 illustrates a top view of an example of a substrate 1400, such as a PCB, of a droplet actuator (not shown) that includes booster converters for individual control of the channels of a droplet actuator. In this example, substrate 1400 is a PCB that includes an electrode arrangement 1410 and control channels 1412. Control channels 1412 are used for controlling the electrode arrangement 1410, such as for applying electrowetting voltages.

Currently, a global high-voltage power supply and complex switching logic is used to control the electrowetting voltages that are applied to the electrodes of a droplet actuator. This power supply arrangement is expensive and inflexible with respect to supplying multiple electrowetting voltages. Accordingly, a main aspect of this invention is that it provides a novel method of supplying multiple electrowetting voltages of a droplet actuator in a cost effective and flexible manner. The invention may also provide an improvement in operating efficiency.

For example, substrate 1400, which is a PCB, further includes multiple boost converters 1414 for controlling the voltage that is applied to control channels 1412. For example, there may be one boost converter 1414 for each control channel 1412. As is well known, a boost converter (or step-up converter) is a power converter that provides an output DC voltage that is greater than its input DC voltage. It is a class of switching-mode power supply (SMPS) containing at least two semiconductor switches (a diode and a transistor) and at least one energy storage element. Filter capacitors are normally added to the output of the converter to reduce output voltage ripple.

In operation, boost converters 1414 are used to provide individual control of the voltages at control channels 1412. For example, each boost converter 1414 may be driven by the output of a field programmable gate array (FPGA) (not shown), which may be used to individually modulate the frequency/duty cycle of the modulated waveform at each control channel 1412.

The power supply arrangement of the invention is inexpensive, not reliant on specialized application-specific integrated circuits (ASICs), achieves decentralization of high voltage generation, is potentially safer than the global power supply arrangement, is easy to construct, and is potentially more efficient than the global power supply arrangement.

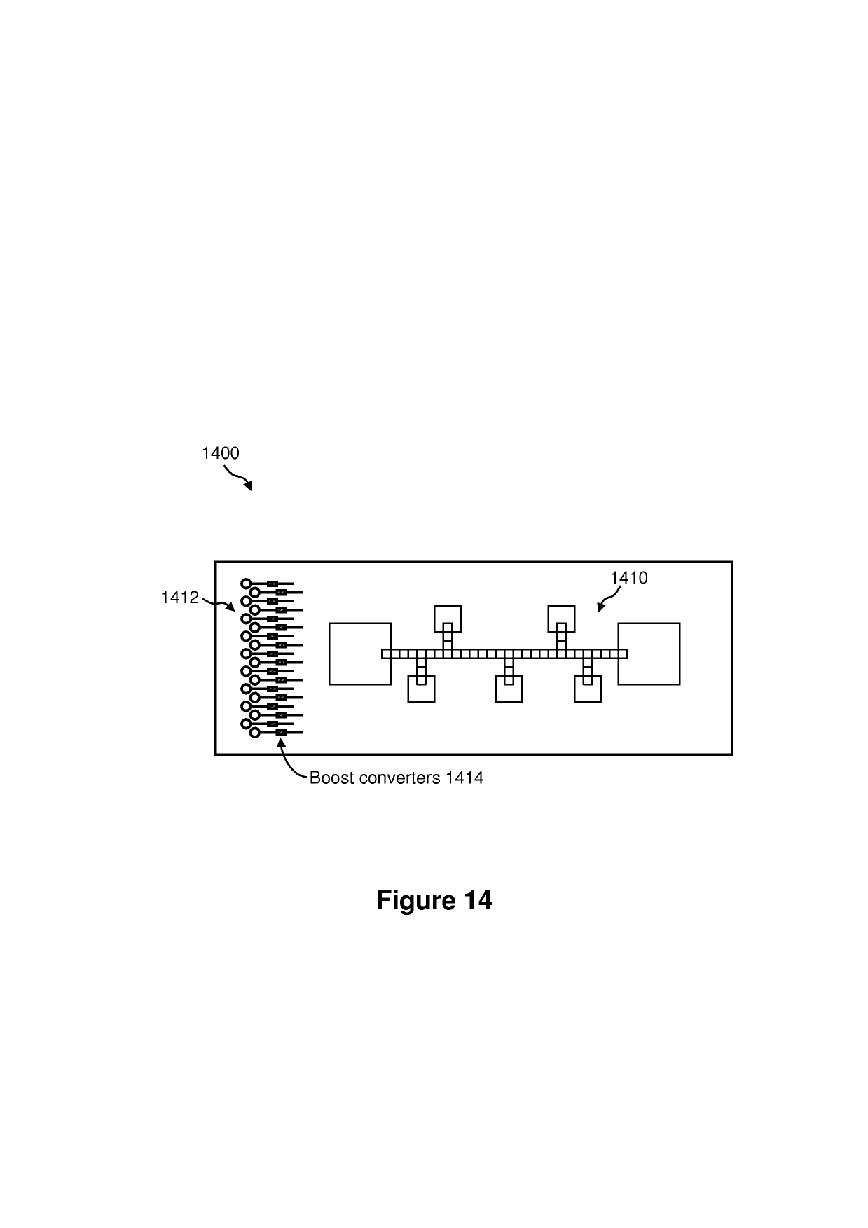

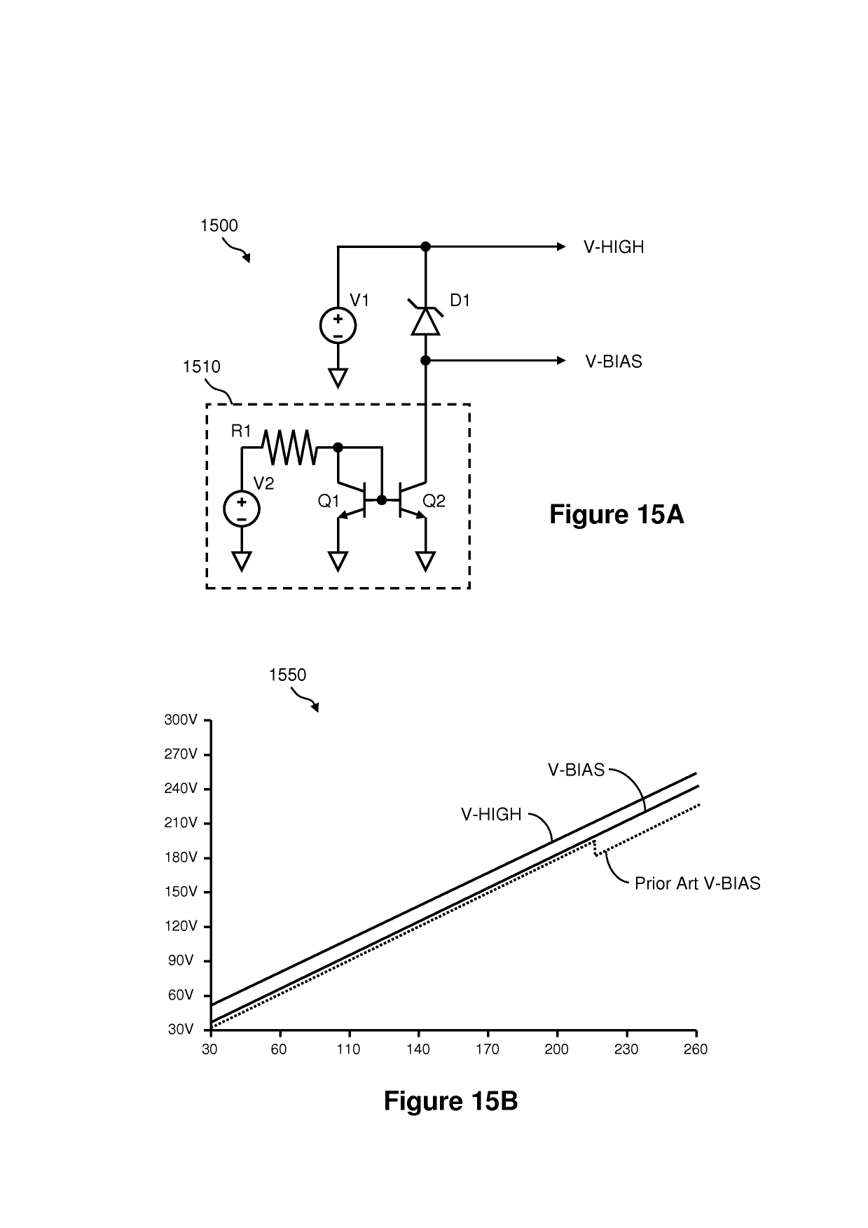

FIG. 15A illustrates a schematic diagram of an example of a voltage biasing circuit 1500 for an impedance spectrometer for use with a droplet actuator. Currently, impedance detection operations in a droplet actuator are performed using an impedance sensing system, such as an impedance spectrometer. A voltage bias circuit is associated with the modulator that drives the excitation waveform for the impedance spectrometer. However, a limitation of the current impedance spectrometer is its relative inaccuracy across different electrowetting bias voltages. An impedance measurement at one bias cannot be reliably compared to a measurement at another. This is because the modulator that drives the excitation waveform for the spectrometer behaves differently at different voltages. Accordingly, the invention provides a voltage biasing circuit 1500 that provides a reliable bias voltage for driving excitation waveform. As a result, the accuracy of the impedance measurements taken across different electrowetting bias voltages is improved. Voltage biasing circuit 1500 may reside in the instrument that controls the droplet actuator cartridge.

For example, voltage biasing circuit 1500 includes a voltage source V1 that supplies an electrowetting voltage node, V-HIGH. The modulator (not shown) that drives the excitation waveform for the impedance spectrometer (not shown) is biased by a zener diode D1 that is connected between a constant current circuit 1510 and the electrowetting voltage node, V-HIGH.

The constant current circuit 1510 includes, for example, a voltage source V2, a resistor R1, and a pair of bipolar transistors Q1 and Q2 that are arranged to provide a current mirror function. Bipolar transistors Q1 and Q2 can be used to achieve high tolerance to the high voltages involved, and the zener current can be set to a value that provides satisfactory results, while still maintaining an acceptably low power at all voltages. In this manner, a substantially constant current may be maintained at zener diode D1 and a reliable bias voltage V-BIAS may be generated. That is, the bias voltage V-BIAS tracks in a substantially linear fashion with respect to electrowetting voltage node, V-HIGH, as shown in FIG. 15B.

FIG. 15B illustrates an example of a plot 1550 that shows a plot of V-HIGH vs. V-BIAS of voltage biasing circuit 1500 of FIG. 15A. For comparison, plot 1550 also shows a plot of the V-BIAS of a prior art voltage biasing circuit, Prior Art V-BIAS. In this example, one can see that a step in the bias voltage occurs in Prior Art V-BIAS, which accounts for the inaccuracy of the impedance measurement. By contrast, no voltage step is present in V-BIAS of voltage biasing circuit 1500 of FIG. 15A across varying V-HIGH values. In this manner, the accuracy of the impedance measurement is maintained across the full range of V-HIGH values.

Referring to FIGS. 15A and 15B, the voltage biasing circuit of the invention is not limited to use in droplet actuator spectroscopy applications. The voltage biasing circuit of the invention may be used in any application in which it is beneficial to maintain a reliable bias voltage across a voltage range.

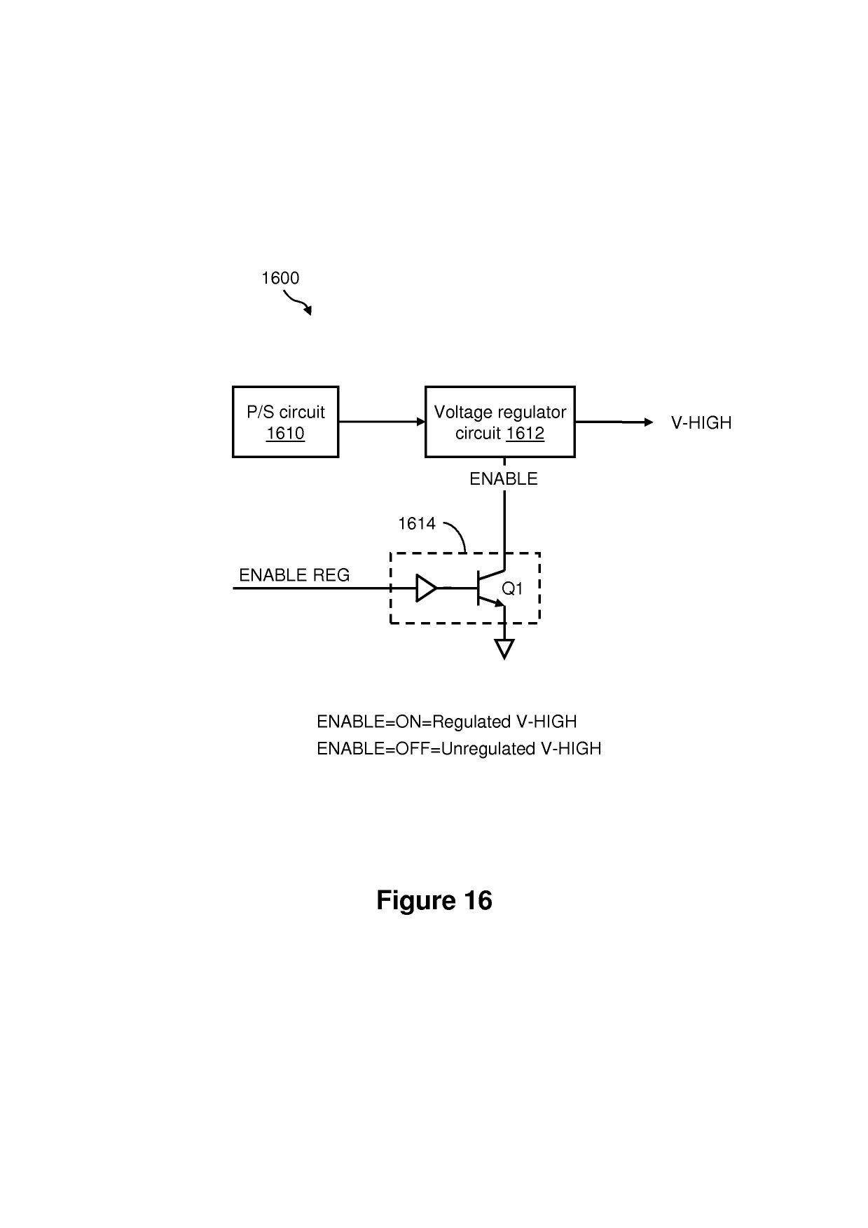

FIG. 16 illustrates a schematic diagram of an example of a selectively regulated power supply 1600 for low-power droplet operations a droplet actuator. Currently, one of the largest power drains in the controller of a droplet actuator is the voltage regulation of the high electrowetting voltage (e.g., 200-300 volts). The voltage regulation ensures a smooth DC electrowetting voltage, for a noise-free environment. However, this noise-free power supply is not necessary for droplet operations itself, but rather exists to support the impedance spectrometer, which requires a clean voltage bias to make accurate measurements. Because impedance measurements are taken only a very small percentage of the time, the voltage regulator for performing droplet operations can be replaced with the unregulated voltage, which is most of the time. Then, switch in the voltage regulator only when good noise performance is necessary. In this manner, the voltage regulator is in “shutdown” mode most of the time, saving a significant amount of power over the long term. Accordingly, the invention provides selectively regulated power supply 1600 for low-power droplet operations a droplet actuator. Selectively regulated power supply 1600 may reside in the instrument that controls the droplet actuator or on the droplet actuator itself.

For example, selectively regulated power supply 1600 may include a power supply (P/S) circuit 1610 whose output voltage may be regulated by a voltage regulator circuit 1612. P/S circuit 1610 may be any standard power supply circuit that is capable of providing the high electrowetting voltage (e.g., 200-300 volts), V-HIGH, at the desired current level. Voltage regulator circuit 1612 may be any standard voltage regulation circuit for reducing noise on the output of a high-voltage power supply, such as P/S circuit 1610.

Selectively regulated power supply 1600 further includes a gating function 1614. Gating function 1614 may include any standard gating components, such as one or more logic gates and/or transistors. Gating function 1614 is used to pass a gate signal, such as an ENABLE REG signal, to the ENABLE input of voltage regulator circuit 1612. For example, when ENABLE REG is active, voltage regulator circuit 1612 is enabled and the electrowetting voltage V-HIGH is a regulated voltage output. However, when ENABLE REG is not active, voltage regulator circuit 1612 is disabled and the electrowetting voltage V-HIGH is now an unregulated voltage output. That is, when voltage regulator circuit 1612 is disabled, the voltage output of P/S circuit 1610 passes unregulated through voltage regulator circuit 1612 to supply the electrowetting voltage, V-HIGH.

When voltage regulator circuit 1612 is enabled a certain amount of power consumption occurs. However, when voltage regulator circuit 1612 is disabled the power consumption is reduced. In one example, voltage regulator circuit 1612 is enabled only during noise-sensitive operations, such as during impedance measurements taken by the impedance spectrometer, which requires a clean voltage bias to make accurate measurements. Otherwise, voltage regulator circuit 1612 is disabled during operations that are not noise-sensitive, such as during droplet operations of the droplet actuator. When performing assay protocols on a droplet actuator, the amount of time spent performing non-noise-sensitive operations is large compared to the amount of time spent performing noise-sensitive operations. Therefore, voltage regulator circuit 1612 may be disabled most of the time, which provides significant power savings.

### 7.2.3 Detection Methods for Use in Droplet Actuators

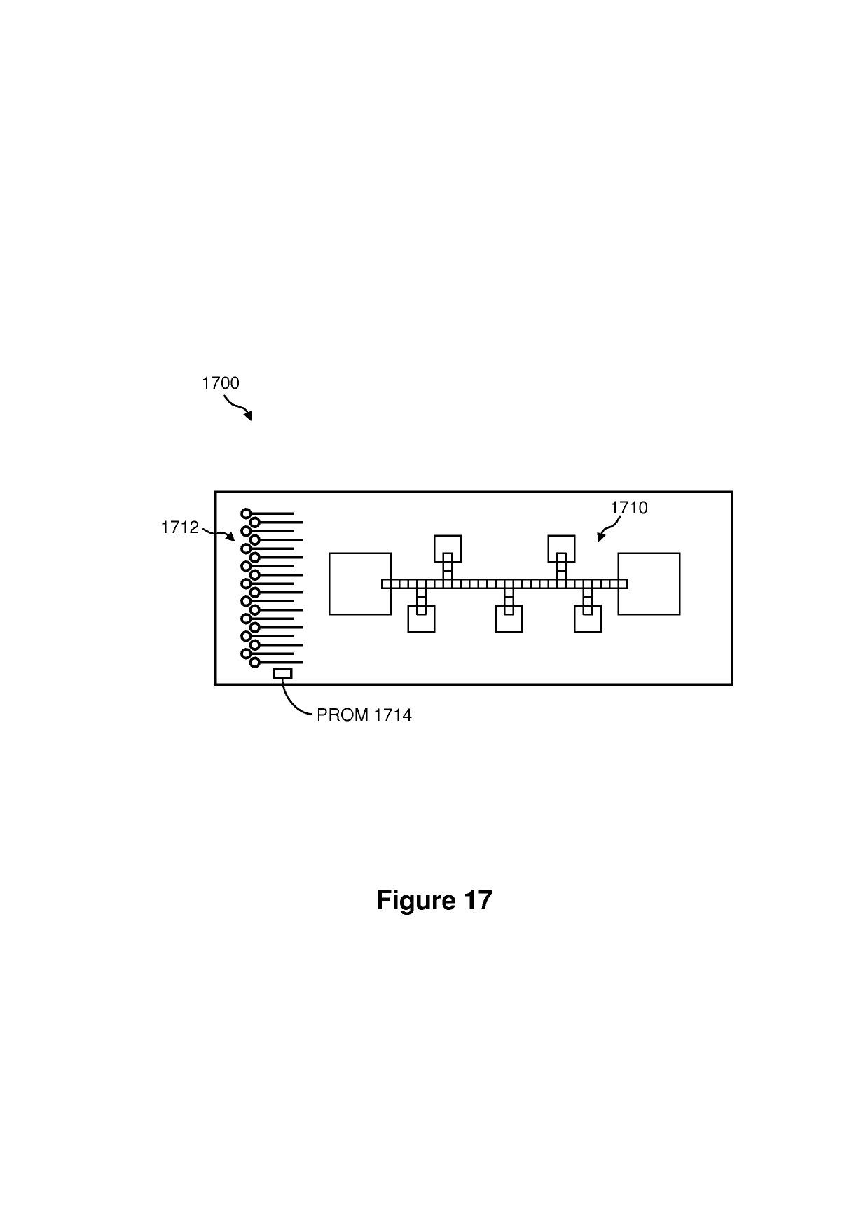

FIG. 17 illustrates a top view of an example of a substrate 1700 of a droplet actuator (not shown) that includes a mechanism for automatically indicating the presence a droplet actuator in an instrument. In this example, substrate 1700 is a PCB that includes an electrode arrangement 1710 and control channels 1712. Control channels 1712 are used for controlling the electrode arrangement 1710, such as for applying electrowetting voltages.

Currently, user action is required in the process of installing a droplet actuator in an instrument and initiating the protocol. This manual interaction is inefficient. Accordingly, the invention provides ways by which software may be used for automatically detecting the insertion of a droplet actuator into the instrument and beginning the protocol.

For example, substrate 1700 may include active and/or passive components for providing a computer-readable indication that a droplet actuator is provided in an instrument. In one example, FIG. 17 shows a programmable read-only memory (PROM) device 1714 that is provided on substrate 1700 (e.g., PCB). In one example, PROM device 1714 may be any standard electrically programmable read-only memory (EEPROM) device. PROM device 1714 may be encoded with, for example, but not limited to, droplet actuator device ID information. The software of the instrument may continuously monitor substrate 1700 for device ID information in PROM device 1714. The lack of device ID information (or any other information) being returned from substrate 1700 indicates that the droplet actuator is not provided in the instrument. However, information being returned from PROM device 1714 of substrate 1700 indicates that the droplet actuator is installed in the instrument and the protocol may be automatically initiated.

PROM device 1714 is one example of an active component for indicating the presence of a droplet actuator in an instrument. However, this is exemplary only. Other types of active components are possible, such as a logic gate that provides a computer-readable logic level only when the droplet actuator is provided and powered in the instrument. In other embodiments, passive components may be used for indicating the presence of a droplet actuator in an instrument. In one example, an arrangement of one or more pull-up resistors may provide a computer-readable logic level only when the droplet actuator is provided and powered in the instrument.

In yet other embodiments, a capacitance scan may be executed periodically (e.g., every few seconds) to determine whether or not a droplet actuator is provided in an instrument.

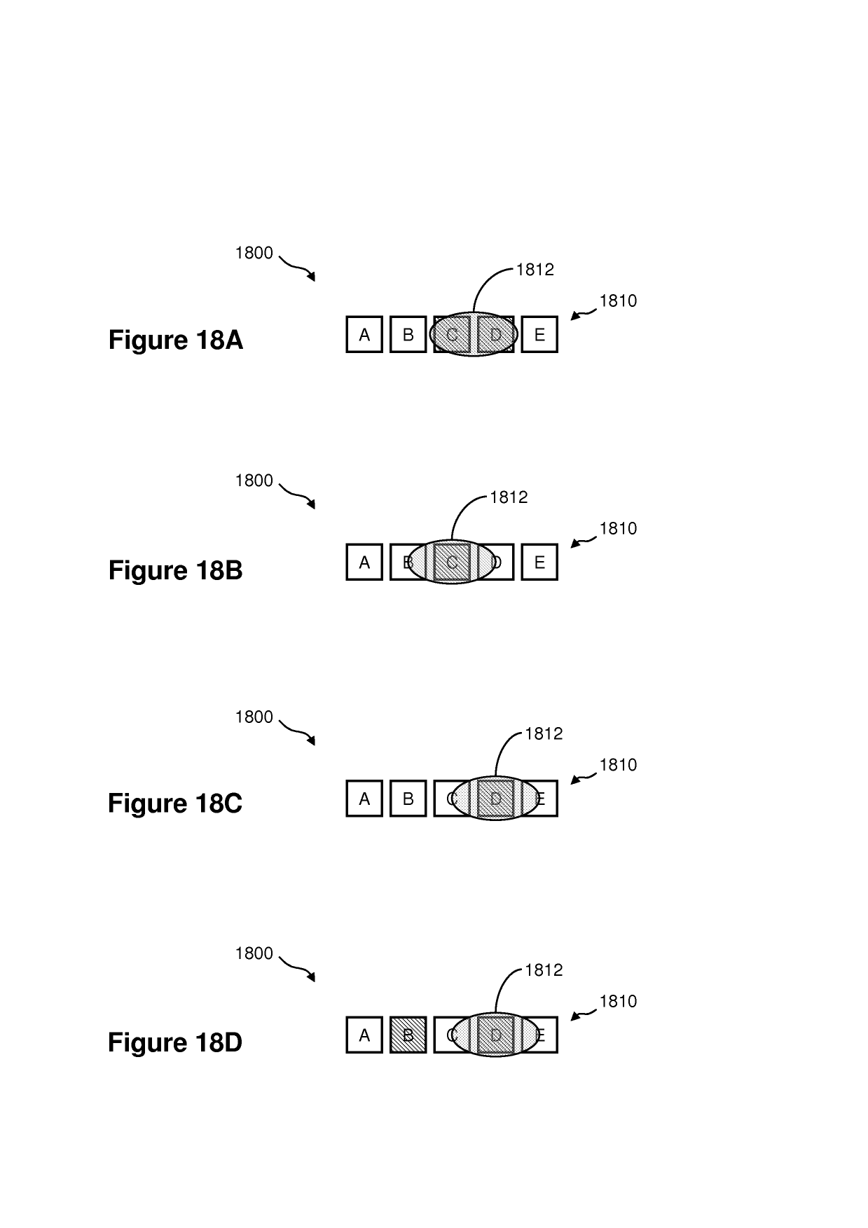

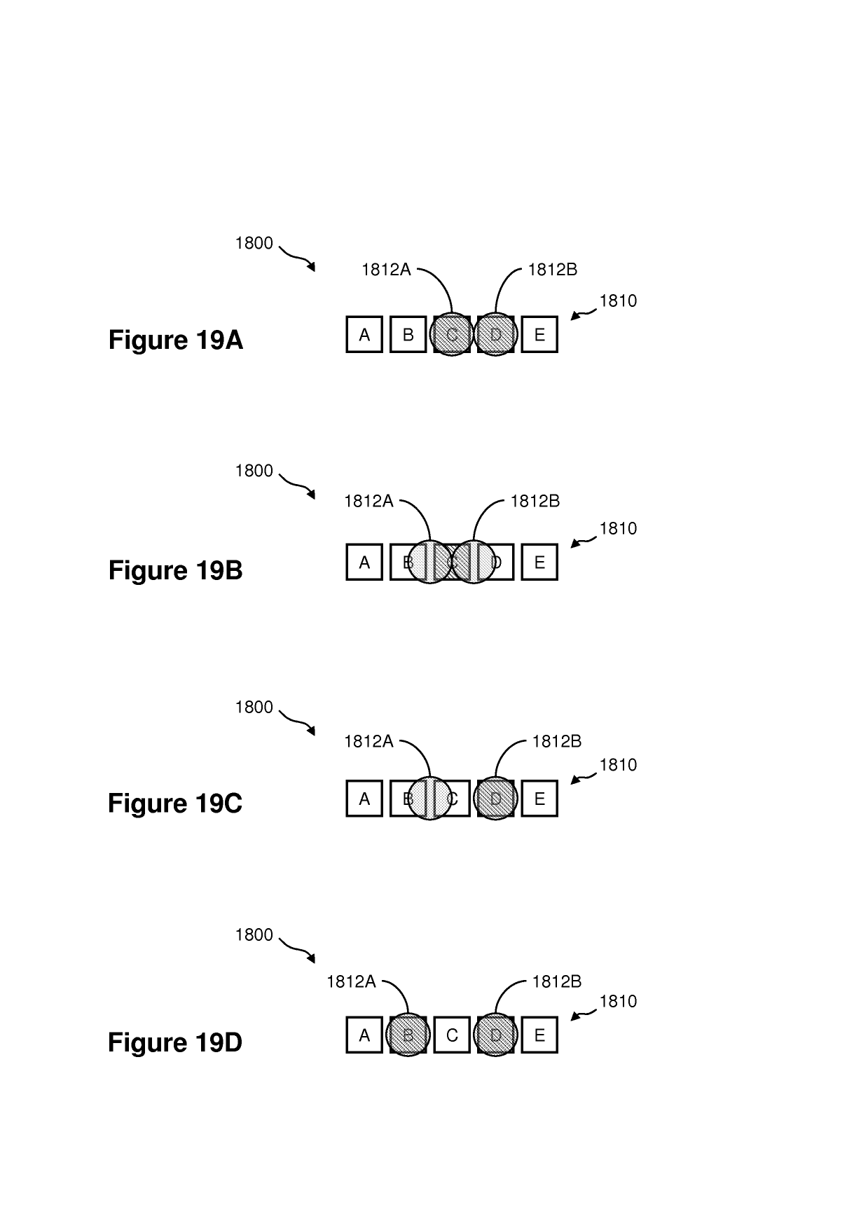

FIGS. 18A through 18D illustrate a top view of an example of an electrode arrangement 1800 and show a process of validating a droplet merge operation in which the merge operation is successful. By contrast FIGS. 19A through 19D illustrate the same process of validating a droplet merge operation, but when the merge operation is not successful. Electrode arrangement 1800 may be patterned on a substrate of a droplet actuator (not shown). Electrode arrangement 1800 includes an arrangement of droplet operations electrodes 1810A, 1810B, 1810C, 1810D, and 1810E (e.g., electro wetting electrodes). Droplet operations are conducted atop droplet operations electrodes 1810 in a droplet operations gap (not shown).

Sometimes droplet merge operations are not successful. For example, sometimes in the merge process, droplets may come together and remain separate droplets sitting side-by-side, but without merging. Therefore, droplet merge validation is needed. The impedance detection processes that are currently used do not provide a reliable method of determining whether a droplet merge operation is successful. This is because impedance detection is based on droplet coverage over the surface area of an electrode. Therefore, impedance detection cannot differentiate between two separate droplets (e.g., two 1X droplets) sitting side-by-side on one or more electrodes vs. one larger droplet (e.g., one 2X droplet) sitting on the same one or more electrodes. Consequently, a visual inspection process (a manual process), may be needed to validate droplet merge operations, which is inconvenient and inefficient. Accordingly, the invention provides a novel method of using impedance detection to reliably validate droplet merge operations. For example, the invention relates to a method of using impedance detection to distinguish between a pair of distinct droplets and a single merged droplet.

A process of using impedance detection to reliably validate droplet merge operations in which the merge operation is successful is described as follows. FIG. 18A shows a 2X droplet 1812, which is a droplet that results from the successful merging of two 1X droplets. At a first step of the process, FIG. 18A shows 2X droplet 1812 sitting atop droplet operations electrodes 1810C and 1810D, which are activated. Droplet operations electrodes 1810A, 1810B, and 1810E are not activated.

At another step of the process, FIG. 18B shows that one of the two activated droplet operations electrodes 1810C and 1810D is deactivated. For example, droplet operations electrode 1810D is deactivated, leaving only the single droplet operations electrode 1810C activated. As a result, the position of 2X droplet 1812 shifts toward the remaining droplet operations electrode 1810C that is still activated.

At another step of the process, FIG. 18C shows that droplet operations electrode 1810C is deactivated while at the same time the adjacent droplet operations electrode 1810D is activated. This action causes 2X droplet 1812 to move from droplet operations electrode 1810C to droplet operations electrode 1810D.

At another step of the process, after a small time delay, such as a delay of about 100 ms, FIG. 18D shows that droplet operations electrode 1810B is activated in addition to droplet operations electrode 1810D. This action causes no movement of 2X droplet 1812, which remains at droplet operations electrode 1810D. At the end of this step, both electrodes that are adjacent to the original single activated droplet operations electrode 1810C of FIG. 18B are activated, while the original single activated droplet operations electrode 1810C remains deactivated.

At still another step of the process, an impedance detection operation is performed on droplet operations electrode 1810B, droplet operations electrode 1810C, and droplet operations electrode 1810D. The results of the impedance detection operation indicate that no droplet is present at droplet operations electrode 1810B, no droplet is present at droplet operations electrode 1810C, and that a droplet is present at droplet operations electrode 1810D. This is the expected result of a successful droplet merge operation. In this manner, it is detected that the droplet merge operation is successful.

A process of using impedance detection to reliably validate droplet merge operations in which the merge operation is not successful is described as follows. The following process is substantially the same process described with reference to FIGS. 18A through 18D, but having a different result. FIG. 19A shows two separate and distinct droplets, 1X droplet 1812A and 1X droplet 1812B, which are droplets that remain after a failed merge operation. At a first step of the process, FIG. 19A shows 1X droplet 1812A and 1X droplet 1812B sitting side-by-side atop, for example, droplet operations electrode 1810C and 1810D, which are activated. Droplet operations electrodes 1810A, 1810B, and 1810E are not activated.

At another step of the process, FIG. 19B shows that one of the two activated droplet operations electrodes 1810C and 1810D is deactivated. For example, droplet operations electrode 1810D is deactivated, leaving only the single droplet operations electrode 1810C activated. As a result, the position of the pair of 1X droplets 1812A and 1812B, which are side-by-side, shifts toward the remaining droplet operations electrode 1810C that is still activated.

At another step of the process, FIG. 19C shows that droplet operations electrode 1810C is deactivated while at the same time the adjacent droplet operations electrode 1810D is activated. This action causes 1X droplet 1812B, which is closest to droplet operations electrode 1810D, to move from droplet operations electrode 1810C to droplet operations electrode 1810D, while the position of 1X droplet 1812A remains substantially unchanged. Consequently, some separation now occurs between 1X droplet 1812A and 1X droplet 1812B.

At another step of the process, after a small time delay, such as a delay of about 100 ms, FIG. 19D shows that droplet operations electrode 1810B is activated in addition to droplet operations electrode 1810D. This action causes 1X droplet 1812A, which is closest to droplet operations electrode 1810B, to move onto droplet operations electrode 1812B. At the end of this step, both electrodes that are adjacent to the original single activated droplet operations electrode 1810C of FIG. 19B are activated, while the original single activated droplet operations electrode 1810C remains deactivated. 1X droplet 1812B is at droplet operations electrode 1810B and 1X droplet 1812B is at droplet operations electrode 1810D. Consequently, more separation now occurs between 1X droplet 1812A and 1X droplet 1812B.

At still another step of the process, an impedance detection operation is performed on droplet operations electrode 1810B, droplet operations electrode 1810C, and droplet operations electrode 1810D. The results of the impedance detection operation indicate that a droplet is present at droplet operations electrode 1810B, no droplet is present at droplet operations electrode 1810C, and that a droplet is present at droplet operations electrode 1810D. This is the expected result of an unsuccessful droplet merge operation. In this manner, it is detected that the droplet merge operation has failed.

The droplet merge validation process of the invention is not limited to 1X and 2X droplets only. The droplet merge validation process of the invention may be applied to other sized droplets, such as, but not limited to, 3X and 4X droplets, for determining successful merge operations.

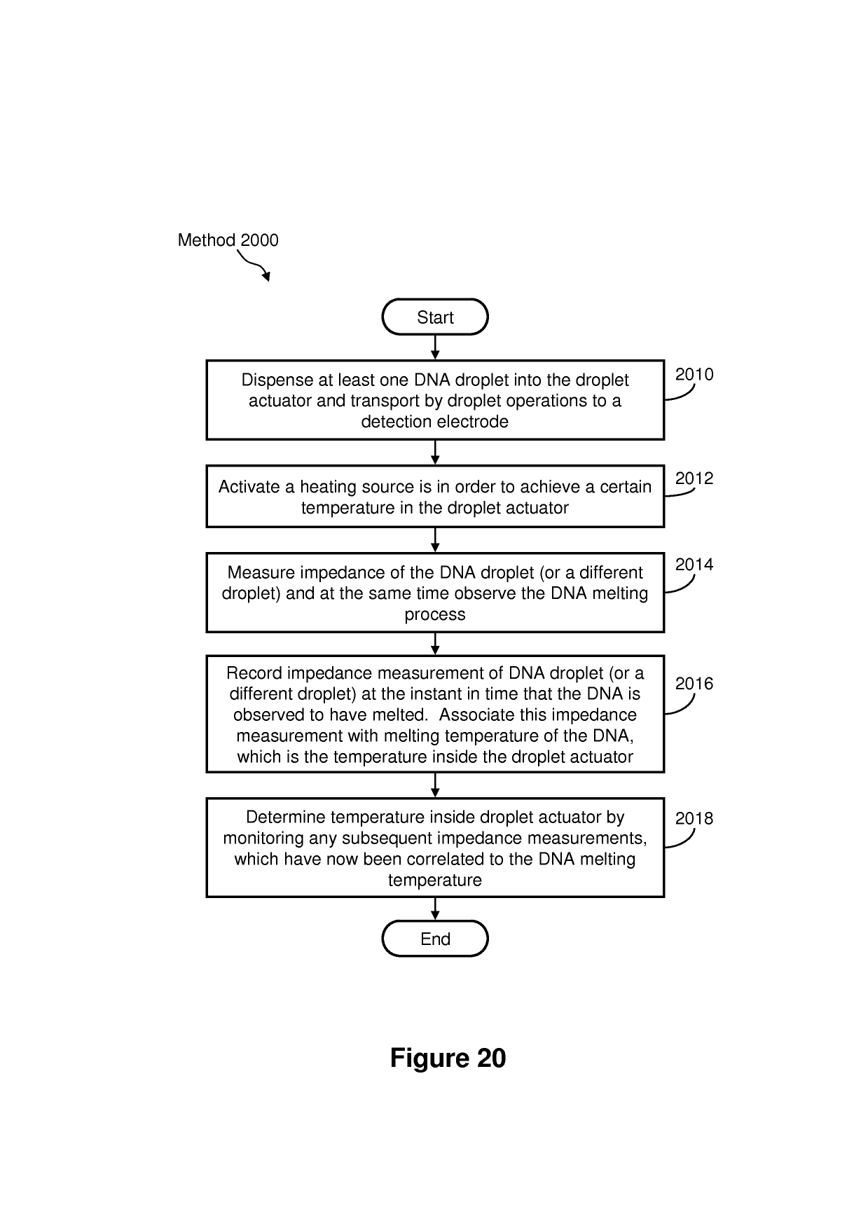

FIG. 20 illustrates a flow diagram of an example of a method 2000 of correlating impedance measurements with respect to the DNA melting process to determine the temperature in a droplet actuator. Method 2000 is not limited to using the DNA melting process only. Any visually observable signal of temperature change in the droplet may be used, DNA melting just being one example. In the DNA melting process, the double-stranded DNA separates into single-stranded DNA at a certain temperature. In short, the behavior of the DNA is dependent on the temperature. At certain temperatures, changes occur, such as separation of the double-stranded DNA into single strands, or annealing of single-stranded DNA into double strands. The method of the invention correlates impedance measurements with respect to the DNA melting process to determine the temperature in a droplet actuator. “Melting” means the separation of the DNA from double-stranded into single-stranded DNA. Method 2000 may include, but is not limited to, the following steps.

At step 2010, at least one DNA droplet is dispensed into the droplet actuator and transported by droplet operations to a detection electrode in the droplet operations gap of the droplet actuator.

At step 2012, a heating source is activated in order to achieve a certain temperature in the droplet actuator.

At step 2014, the impedance of the DNA droplet (or a different droplet) is measured while at the same time the DNA melting process is observed. The DNA melting process with respect to the DNA droplet may be observed by fluorescence detection operations.

At step 2016, an impedance measurement of the DNA droplet (or a different droplet) is recorded at the instant in time that the DNA in the DNA droplet is observed to have melted. This impedance measurement is then associated with the melting temperature of the DNA, which is the temperature inside the droplet actuator.

At step 2018, once the impedance measurement that correlates to the melting temperature of the DNA is determined and recorded in step 2016, the temperature inside the droplet actuator may be determined by monitoring any subsequent impedance measurements, and there is no further need for observing the DNA melting process.

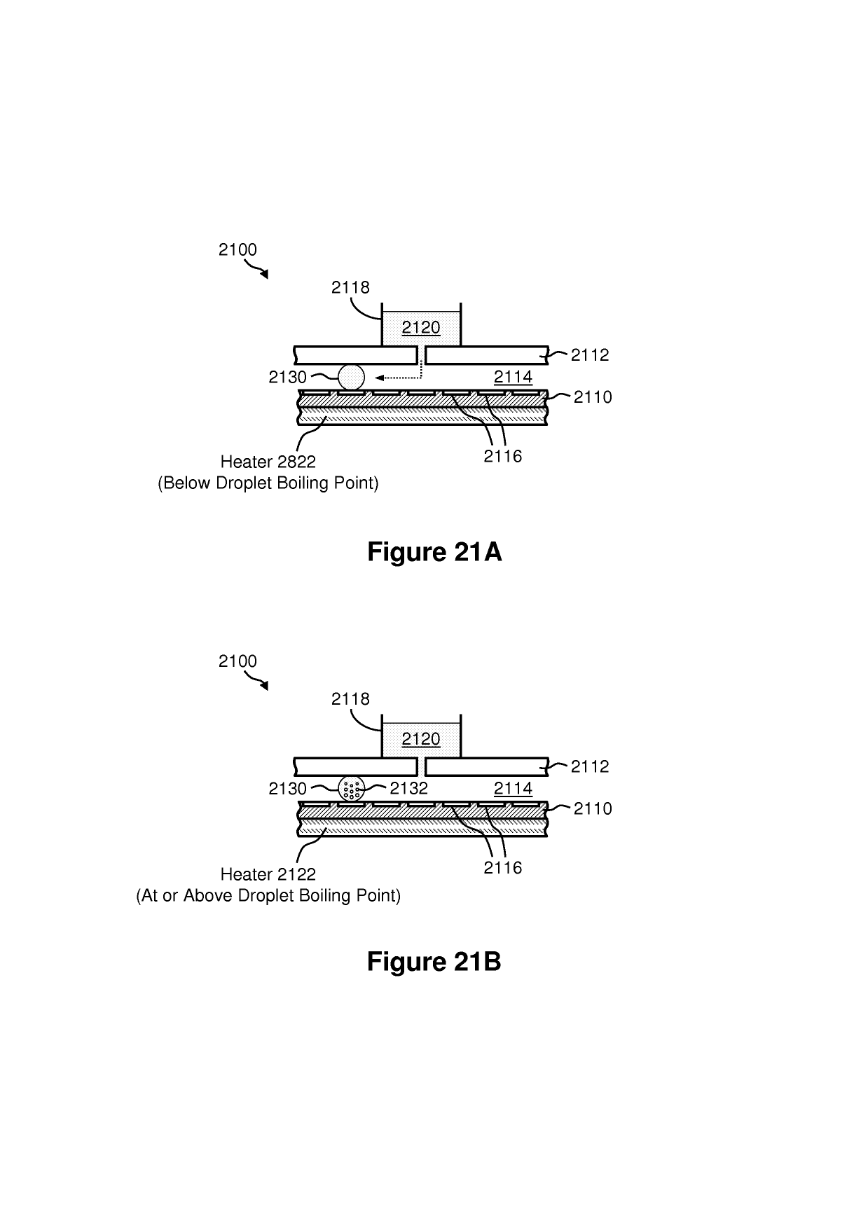

FIGS. 21A and 21B illustrate cross-sectional side views of an example of a droplet actuator 2100 and a process of using phase transitions to characterize, monitor, and/or calibrate droplet temperature. Droplet actuator 2100 may include a bottom substrate 2110 and a top substrate 2112 that are separated by a droplet operations gap 2114. Droplet actuator 2100 may include an arrangement of droplet operations electrodes 2116 (e.g., electrowetting electrodes) that may be associated with bottom substrate 2110, top substrate 2112, or both substrates. Droplet operations are conducted atop droplet operations electrodes 2116 in droplet operations gap 2114. A reservoir 2118 is coupled to or formed together with top substrate 2112 for holding an amount of liquid 2120, which may be dispensed into droplet operations gap 2114 of droplet actuator 2100.

Additionally, droplet actuator 2100 includes a heater 2122. Heater 2122 may be any heating mechanism that is capable of heating the droplet operations environment of droplet actuator 2100. In one example, FIGS. 21A and 21B show heater 2122 implemented as a heating element in thermal contact with bottom substrate 2110.

Currently, thermal control mechanisms may be provided in a droplet actuator for monitoring and/or controlling the temperature of the droplet actuator. These thermal control mechanisms, such as thermocouple devices, may add an amount of complexity to the droplet actuator design. Accordingly, the droplet actuator and method of the invention provide simplified thermal control in a droplet actuator. That is, the invention uses phase transitions of droplets in combination with impedance spectroscopy to characterize, monitor, and/or calibrate droplet temperature. Impedance changes as the phase transition occurs at a very specific liquid-dependent temperature. Impedance measurements may be used to indicate the temperature in the droplet actuator, particularly when the temperature is substantially at the boiling point of a liquid.

For example and referring to FIG. 21A, heater 2122 is set such that the temperature inside droplet actuator 2100 is below the boiling point of a type of liquid 2120 in reservoir 2118. Because the temperature is below the boiling point of liquid 2120, FIG. 21A shows a liquid droplet 2130 dispensed from reservoir 2118.

Referring to FIG. 21B, heater 2122 is set such that the temperature inside droplet actuator 2100 is at or above the boiling point of the type of liquid 2120 in reservoir 2118. Because the temperature is at or above the boiling point of liquid 2120, FIG. 21B shows that the liquid droplet 2130 of FIG. 21A experiences a phase transition. For example, FIG. 21B shows that the liquid droplet 2130 includes bubbles 2132, which is the result of boiling.

When an impedance measurement is taken on the droplet operations electrode 2116 on which is sitting the liquid droplet 2130 of FIG. 21A, an amount of droplet coverage is indicated. By contrast, when an impedance measurement is taken on the droplet operations electrode 2116 on which is sitting the liquid droplet 2130 of FIG. 21B that is boiling, a reduced or no amount of droplet coverage is indicated.

By using impedance detection to monitor the phase change of a droplet at an electrode, the temperature of the droplet actuator may be characterized, monitored, and/or calibrated. In one example, if liquid droplet 2130 of FIG. 21A is a liquid that has a boiling point of 95° C., when the impedance detection process indicates the moment of phase change from not boiling to boiling, this indicates that the actual temperature inside the droplet actuator is currently 95° C. In an application for maintaining the 95° C. inside the droplet actuator, the type of liquid 2120 that is selected has a boiling point of 95° C. Then, by monitoring impedance measurements, heater 2122 is used to maintain liquid droplet 2130 at the point where the liquid starts to boil (i.e., the phase transition point). In this manner, the temperature of the droplet actuator may be maintained at about 95° C.

In another example, if liquid droplet 2130 of FIG. 21A is a liquid that has a boiling point of 100° C., when the impedance detection process indicates the moment of phase change from not boiling to boiling, this indicates that the actual temperature inside the droplet actuator is currently 100° C. In an application for maintaining the 100° C. inside the droplet actuator, the type of liquid 2120 that is selected has a boiling point of 100° C. Then, by monitoring impedance measurements, heater 2122 is used to maintain liquid droplet 2130 at the point where the liquid starts to boil (i.e., the phase transition point). In this manner, the temperature of the droplet actuator may be maintained at about 100° C.

The invention is not limited to one reservoir with one type of liquid 2120 that has one specific boiling point. Any number of reservoirs and different types of liquids that have different boiling points may be provided in the droplet actuator. Further, two or more types of liquids may be mixed in the droplet actuator to achieve yet other boiling points. In this manner, any number of temperature set points may be maintained in a droplet actuator by using impedance spectroscopy to monitor phase transitions of droplets. Additionally, those skilled in the art will recognize that liquid boiling points also have some dependency on vapor pressure, which should be considered when determining/controlling the temperature of the droplet actuator according to the invention.

### 7.2.4 Local Heating Mechanisms in Droplet Actuators

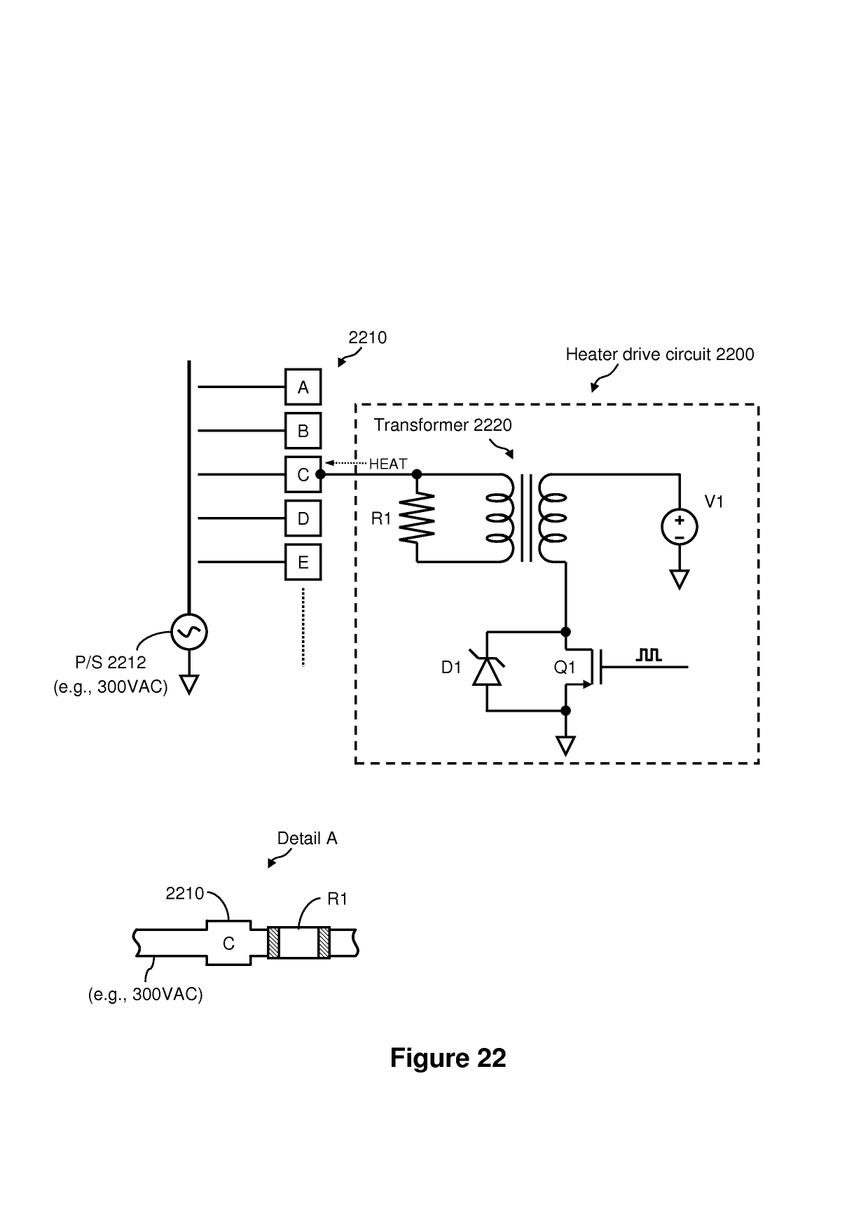

FIG. 22 illustrates a schematic diagram of an example of a heater drive circuit 2200 for supplying heat directly to an electrode of a droplet actuator. There is a need for techniques for providing targeted heat in a droplet actuator. For example, it may be beneficial to deliver heat directly to a droplet location in a droplet actuator. Accordingly, the invention provides a method of supplying heat directly to one or more electrodes in a droplet actuator.

For example, FIG. 22 shows heater drive circuit 2200 in combination with an arrangement of droplet operations electrodes 2210 (e.g., electrowetting electrodes) that are driven by a P/S 2212 (e.g., a 300VAC power supply). Heater drive circuit 2200 may be any standard drive circuit that includes an isolation transformer to inductively drive an on-chip resistor that is used to directly heat electrodes. For example, heater drive circuit 2200 may include, for example, a transformer 2220. The primary winding of transformer 2220 may be electrically connected to a DC power supply V1 and any gating components, such as a transistor Q1 and a zener diode D1, for generating an alternating current. The secondary winding of transformer 2220 may be electrically connected across a resistor R1. Additionally, one side of resistor R1 is thermally and electrically connected to a droplet operations electrode 2210 that is designated for heating droplets. For example, resistor R1 is thermally and electrically connected to a droplet operations electrode 2210C of droplet operations electrodes 2210A through 2210E.

In operation, the isolation transformer 2220 is used to separate heater drive circuit 2200 from the high voltage (e.g., P/S 2212) that is used to drive droplet operations electrodes 2210. By this scheme, it is possible to pump heat into a specific electrode (e.g., droplet operations electrode 2210C) without altering droplet operations performance at that electrode. Further, the designated electrode (e.g., droplet operations electrode 2210C) may be used as both a normal droplet operations electrode and as a targeted heat source to a droplet.

Referring to “Detail A” of FIG. 22, resistor R1 may be implemented as a chip resistor that is thermally and electrically connected to droplet operations electrode 2210C by a thermally and electrically conductive trace (e.g., a copper or aluminum trace). In this manner, heat may pass directly from resistor R1 to the droplet operations electrode 2210C, which is a thermally and electrically conductive pad. Consequently, any droplet (not shown) that is sitting atop droplet operations electrode 2210C may be heated. In this example, a control signal at transistor Q1 of heater drive circuit 2200 may be used for controlling the amount of heat generated at resistor R1 and/or droplet operations electrode 2210C.

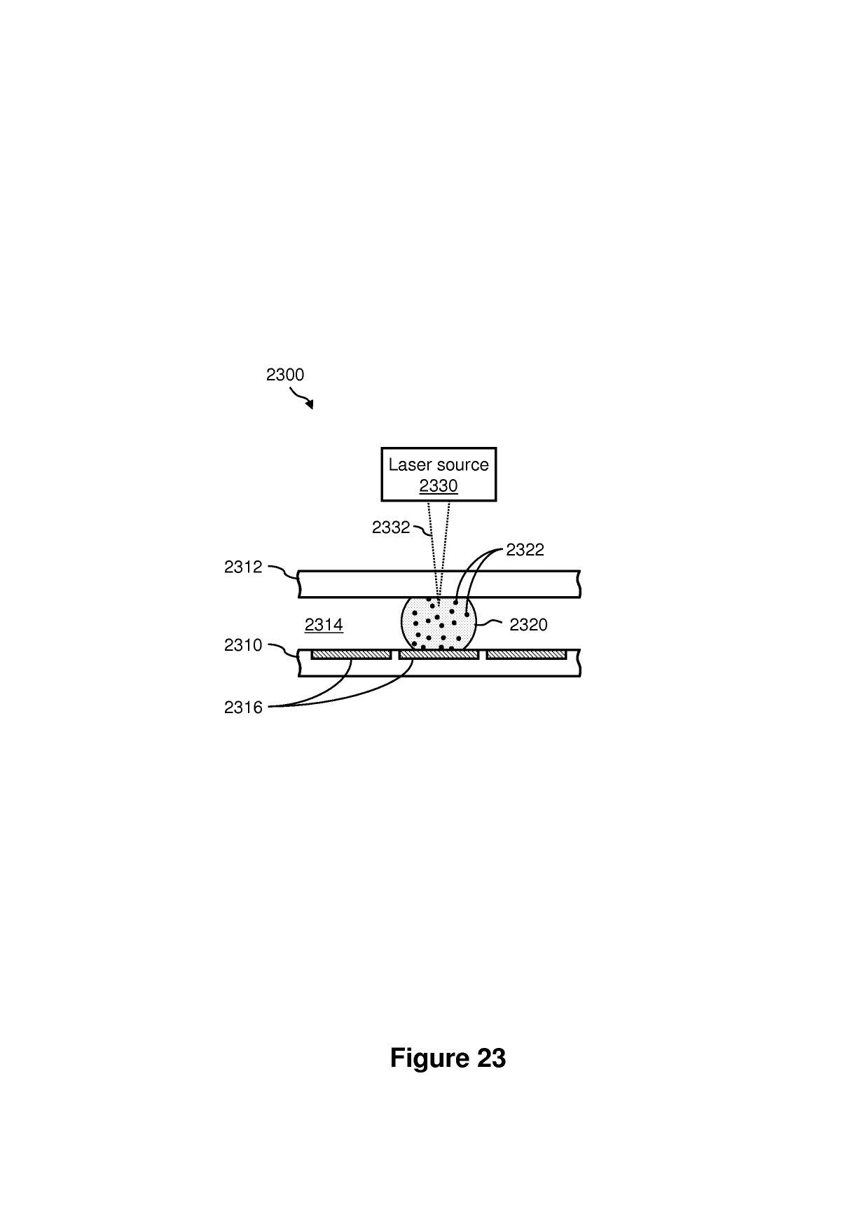

FIG. 23 illustrates a cross-sectional side view of a portion of droplet actuator 2300 and shows an example of using a laser as a heat source and/or for promoting cell lysis. Droplet actuator 2300 may include a bottom substrate 2310 and a top substrate 2312 that are separated by a droplet operations gap 2314. Droplet actuator 2300 may include an arrangement of droplet operations electrodes 2316 (e.g., electrowetting electrodes) that may be associated with bottom substrate 2310, top substrate 2312, or both substrates. Droplet operations are conducted atop droplet operations electrodes 2316 in droplet operations gap 2314.

FIG. 23 also shows a laser source 2330 that is emitting laser energy 2332 through top substrate 2312 of droplet actuator 2300. Top substrate 2312 is substantially transparent to laser energy 2332. Optionally, at least one substrate may include unfilled via holes or other openings through which laser energy 2332 may pass. Laser source 2330 may be, for example, an infrared (IR) pulsed laser source. In one example, laser source 2330 has a power rating of about 20 milliwatts (mW). The height of droplet operations gap 2314 of droplet actuator 2300 may be about equal to the wavelength (2) of laser energy 2332 that is emitted by laser source 2330. In another example, the height of droplet operations gap 2314 may be about one half λ.

A droplet 2320 is situated in droplet operations gap 2314 of droplet actuator 2300. Droplet 2320 may contain absorptive materials with respect to the IR spectrum. For example, magnetically responsive beads 2322, which have high IR absorption characteristics, may be suspended in droplet 2320. When laser source 2330 is activated, laser energy 2332 impinges on the bead-containing droplet 2320 and causes local heating to occur therein. The amount of heating may be controlled by the duration and/or power level of laser energy 2332. In this manner, the invention provides a laser source that is used to radiatively heat droplets by targeting absorptive materials contained therein.

In another example, droplet 2320 may contain a quantity of cells to be lysed (with or without magnetically responsive beads 2322). When laser source 2330 is activated, laser energy 2332 impinges on the cell-containing sample droplet 2320 and causes local heating and pressure pulses to occur therein. The presence of local heating and pressure pulses induces cavitation in droplet 2320, thereby promoting cell lysis in droplet 2320.

In another example, droplet 2320 may contain no special absorbers. For example, water itself absorbs light in the IR spectrum. When laser source 2330 is activated, laser energy 2332 impinges on the aqueous droplet 2320 and causes local heating to occur therein.

In summary, the invention provides a method to implement thermal control on a droplet actuator using a laser. The use of the laser is non-contact, efficient, and may simplify the mechanical instrumentation surrounding the droplet actuator.

### 7.2.5 Droplet Imaging in Droplet Actuators

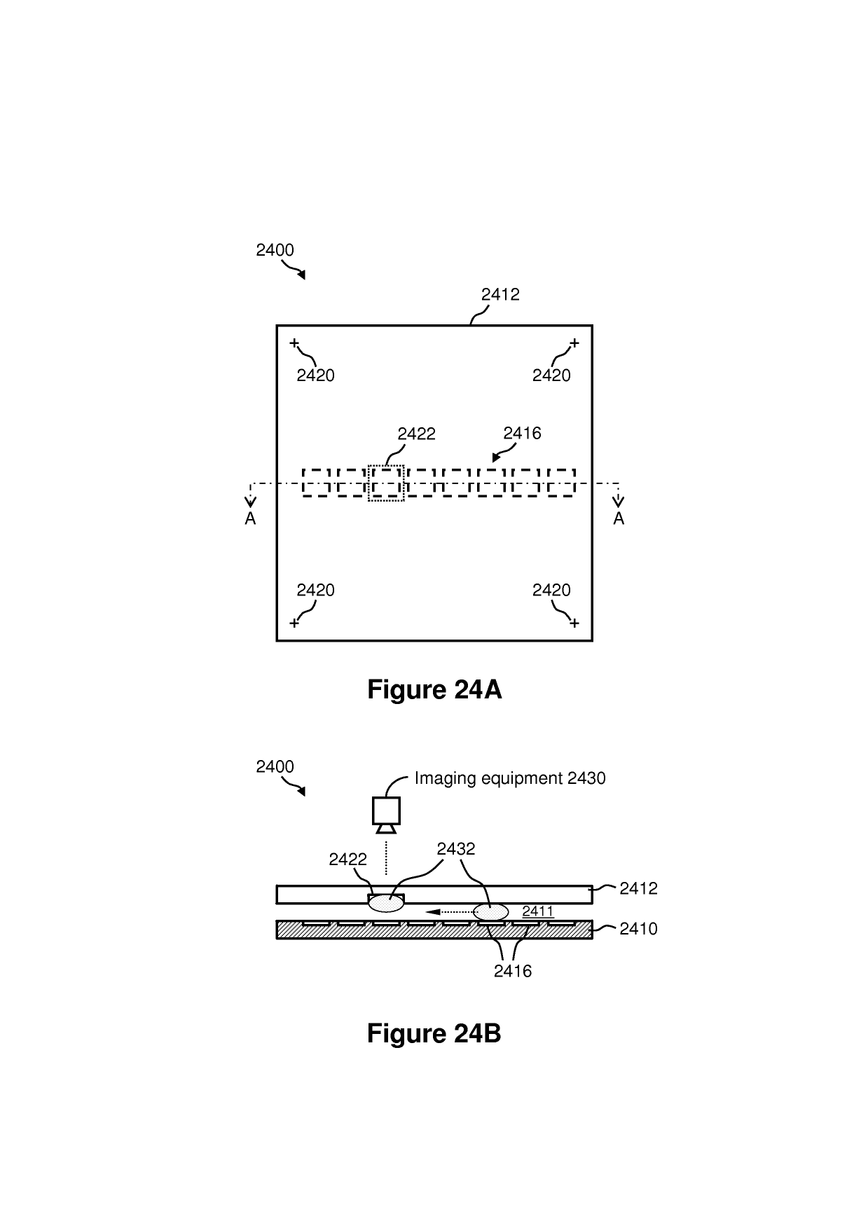

FIGS. 24A and 24B illustrate a top view and a cross-sectional side view, respectively, of an example of a droplet actuator 2400 that includes a hydrophilic reservoir for use in droplet imaging operations. Additionally, FIG. 24B is a cross-sectional view of droplet actuator 2400 taken along line AA of FIG. 24A. Currently, it is sometimes difficult to align droplet actuators (x, y, and z axis) to imaging optics. This may be due, for example, to tolerance stack up with the instrument deck, droplet actuator cartridge, and imaging apparatus. Accordingly, the invention provides a hydrophilic reservoir in the top substrate of the droplet actuator. The hydrophilic reservoir is in a known position in the top substrate with respect to other alignment features and, therefore, may be easily aligned with imaging apparatus. A droplet may be transported to the reservoir by droplet operations and it will settle into the reservoir due to the hydrophilic characteristic of the surface of the reservoir, thereby aligning the droplet with imaging apparatus 2430.

Droplet actuator 2400 of the invention may include a bottom substrate 2410 and a top substrate 2412 that are separated by droplet operations gap 2411. Droplet actuator 2400 may include an arrangement of droplet operations electrodes 2416 (e.g., electrowetting electrodes) that may be associated with bottom substrate 2410, top substrate 2412, or both substrates. Droplet operations are conducted atop droplet operations electrodes 2416 in droplet operations gap 2411.

FIG. 24A shows that alignment features 2420 may be molded, etched, patterned or otherwise provided opposite a droplet operations side of top substrate 2412. Additionally, a hydrophilic reservoir 2422 is molded, etched, patterned, or otherwise formed together with top substrate 2412. Hydrophilic reservoir 2422 is provided on the surface of top substrate 2412 that is facing droplet operations gap 2411. Hydrophilic reservoir 2422 may be formed, for example, by masking off the hydrophobic coating (not shown) that is typically provided on the surface of top substrate 2412 that is facing droplet operations gap 2411. Hydrophilic reservoir 2422 is in a known position in top substrate 2412 with respect to alignment features 2420 and, therefore, may be easily aligned with imaging apparatus, such as imaging apparatus 2430 shown in FIG. 24B. Further, hydrophilic reservoir 2422 is substantially aligned with a droplet operations electrode 2416.

Referring to FIG. 24B, a droplet (e.g., droplet 2432) may be transported to hydrophilic reservoir 2422 where it is positioned in hydrophilic reservoir 2422 based on the hydrophilic features of the reservoir. In this manner, the position of droplet 2432 is aligned with imaging apparatus 2430. Optionally, imaging apparatus 2430 may be aligned with an alignment feature 2420 on top substrate 2412. Examples of alignment features include marks, divots, ridges, and other features that may be used to optically or mechanically align imaging apparatus 2430 so that it may image droplet 2432 when it is in position in hydrophilic reservoir 2422. In an alternative embodiment, hydrophilic reservoir 2422 may be replaced with a reservoir that is selectively hydrophilic, e.g., the reservoir may include one or more electrowetting electrodes and a hydrophobic surface such that when the one or more electrowetting electrodes is activated, the surface becomes hydrophilic and thereby situates the droplet within the reservoir 2422.

### 7.3 Fabrication-Related Processes of Droplet Actuators

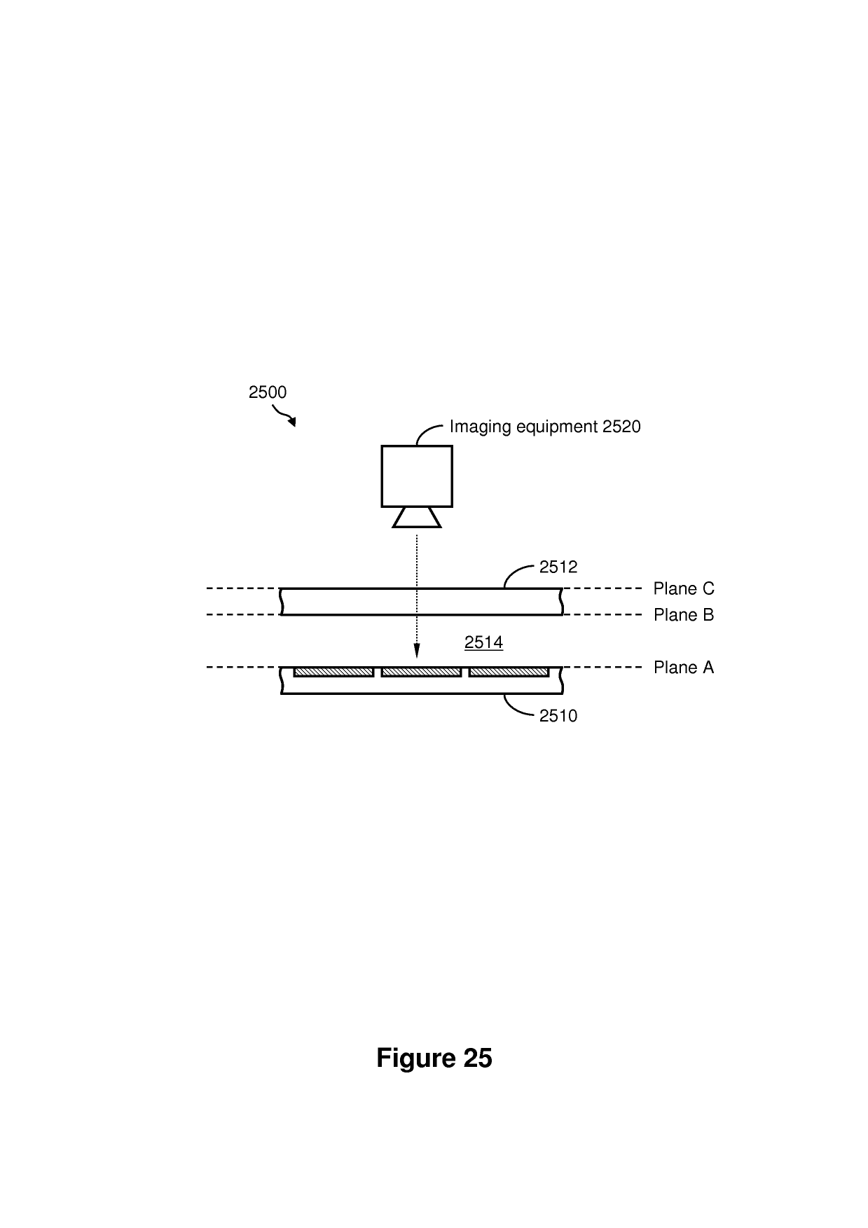

FIG. 25 illustrates a cross-sectional side view of an example of a droplet actuator 2500 and a process of measuring the gap height. Droplet actuator 2500 may include a bottom substrate 2510 and a top substrate 2512 that are separated by a droplet operations gap 2514. Top substrate 2512 is an optically transparent substrate. Additionally, FIG. 25 indicates three planes that are associated with the stack up of droplet actuator 2500. For example, plane A indicates the gap-facing surface of bottom substrate 2510, plane B indicates the gap-facing surface of top substrate 2512, and plane C indicates the outer surface of top substrate 2512.

This invention also provides imaging apparatus 2520 that is used as a gap height measuring tool. A method of the invention uses optics to locate the three planes in one dimension. In one example, imaging apparatus 2520 may be a camera that has a lens with a small depth of field to accurately locate the positions of these planes. Further, an XY stage (not shown) may be associated with droplet actuator 2500 and imaging apparatus 2520. For example, droplet actuator 2500 may be provided on the XY stage and moved in relation to imaging apparatus 2520. In this manner, imaging apparatus 2520 may capture images at different locations of droplet actuator 2500. Accordingly, imaging apparatus 2520 is used to measure the gap height at multiple locations across the area of droplet actuator 2500.

For example, imaging apparatus 2520 may be mounted on a Z-stage (not shown) for auto-focusing. Software associated with imaging apparatus 2520 is used to move the camera Z-stage as well as to move the XY stage holding droplet actuator 2500. The software measures the focus using a 2-dimensional Fast Fourier transform (FFT). The software is then used to locate the peaks in the focus function to identify the relative positions of plane A, B, and C. The software is then used to perform a higher resolution scan to determine a precise position of planes A, B, and C. The gap height is then determined by subtracting the difference between the positions of planes A and B, which are the gap-facing surfaces of droplet actuator 2500. The software may also be used to generate a contour plot (not shown) of the gap height across the area of the entire droplet actuator 2500, where the plot indicates the topography of the relevant planes and thus the typography of the droplet operations gap. In some embodiments, features may be patterned or printed on the surfaces at the planes in order to facilitate imaging.

A microfluidics system may include a controller or processor that controls the droplet actuator. A microfluidics system may also include a deck or drive for mounting the droplet actuator during operation. The system also includes electrical contacts for establishing electrical communication between the droplet actuator and the controller or processor. Currently, decks may be formed of metal, making it difficult to ensure electrical isolation of the deck without sacrificing thermal control. Accordingly, the invention provides a deck that is formed of non-electrically conductive yet thermally conductive material.

For example, the deck of the invention may be formed of high-thermal-conductivity ceramic material. Ceramic material is not electrically conductive but at the same time has high thermal conductivity. The ceramic deck of the invention provides improved electrical isolation from other portions of the microfluidics system without sacrificing thermal control. That is, the ceramic deck of the invention provides improved electrical isolation while maintaining thermal conductivity. One advantage of using a deck formed of ceramic material is that heaters and thermistors may be patterned directly onto the deck using thick film processes to achieve high coupling of heat into the deck itself.

### 7.4 Droplet Actuator Processes

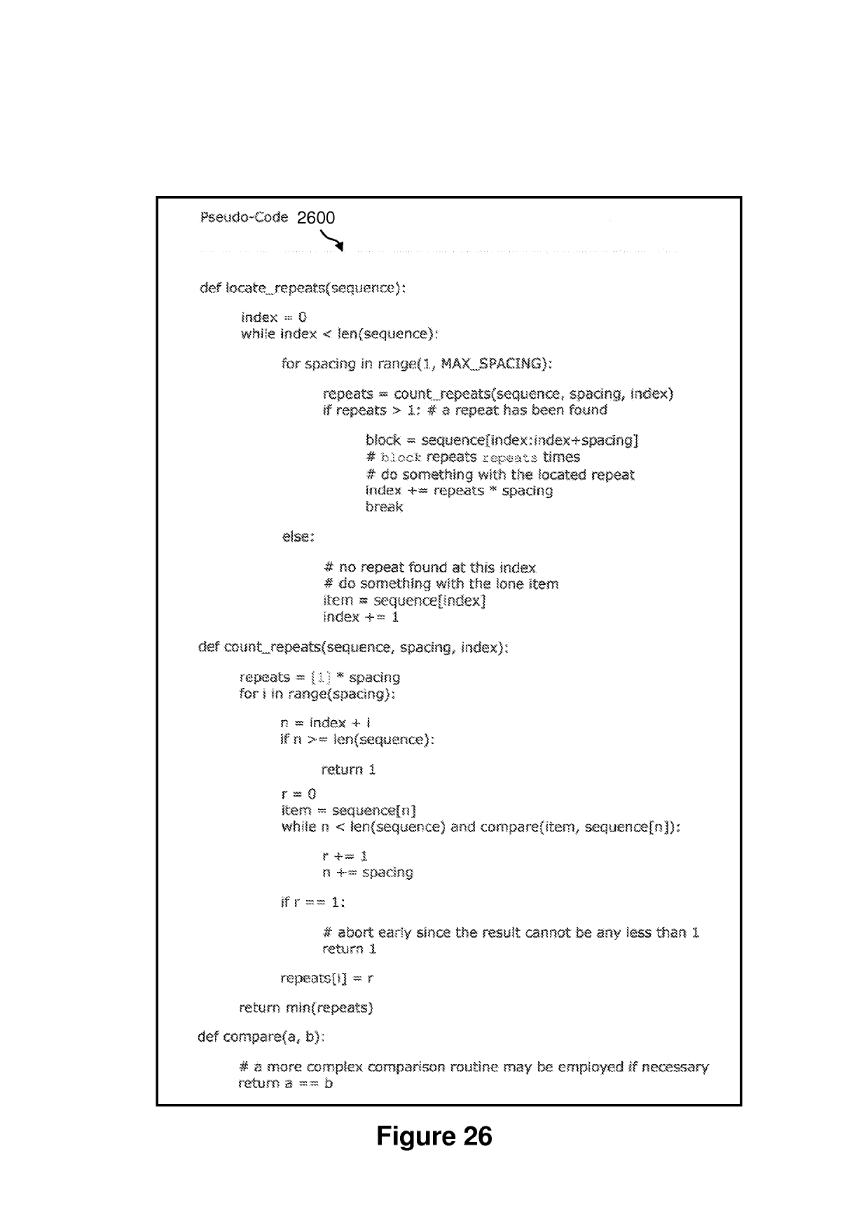

FIG. 26 illustrates pseudo code 2600, which is an example of pseudo code for implementing an algorithm for locating short tandem repeats in large sequences of assay protocols. Currently, programs for operating droplet actuators of microfluidics systems are unnecessarily large and contain many repeated vectors to be asserted. The invention provides an algorithm for locating short tandem repeats in large sequences of assay protocols. The invention provides benefits, such as, but not limited to, less time to transfer a program to the instrument, less memory consumed on the instrument for storing the program, allows larger programs to be executed, and allows easier examination and/or debug of programs when viewing bytecodes.

Suffix trees are often used to locate tandem repeats. However, constructing a suffix tree can be expensive, particularly when the sequence to be searched is very long. A less complicated approach may be employed, especially when searching for subsequences of relatively short length within a relatively long parent sequence. The algorithm may be used to locate repeats of identical instructions that can thus be reduced into a loop.

“Unrolling a loop” is expanding a loop into what are essentially tandem repeats of instructions to improve performance. However, the algorithm of the invention is doing the opposite: searching for such repeats so that they can be “rolled into a loop,” thereby reducing the number of instructions that must be stored in memory or sent over a communication link.

In applications in which droplet actuators have hundreds or thousands of electrodes being controlled by a smaller number of shared channels, ASSERT instructions often repeat in localized areas of a control sequence. Generally, this sharing of channels is considered a restriction in that it only allows types of operations to occur on the droplet actuator. However, it also creates a situation where programs can be heavily compressed using the algorithm of the invention. In one example, the use of the algorithm of the invention may achieve a program size reduction of from about 20% to about 80%.

Algorithm—the algorithm of the invention locates only the repeating subsequences up to a configurable maximum length. Increasing this maximum length will increase the runtime of the algorithm. Ideally, this length will be much less than the full length of the entire sequence.

Starting at the first item in the sequence, the algorithm tests whether a repeat starts at that location. First, subsequences of length 1 are tried, then 2, 3, etc. up to the maximum configured length. Repeats are located by looking ahead into the sequence as long as the items match. When the subsequence spacing being attempted is greater than one, each offset [0, spacing) is also compared.

The algorithm will continue searching at the end of the located repeat, by incrementing its search index by spacing * repeats, or 4*2=8, continuing at index 9 in this case. Again, pseudo code 3300 of FIG. 33 is an example of implementing the aforementioned algorithm.

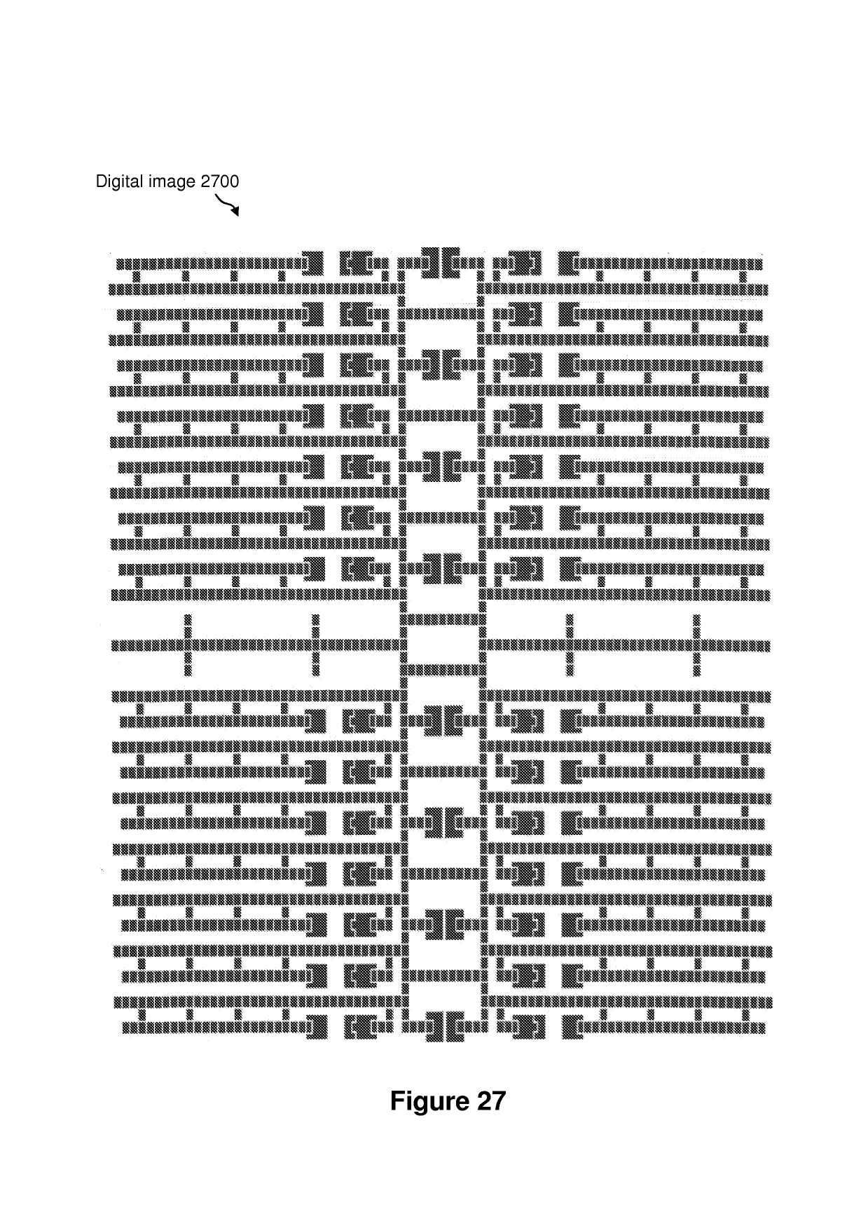

FIG. 27 shows a digital image 2700, which is an example of a digital image from which droplet actuator description files may be automatically generated using an algorithm of the invention. Digital image 2700 shows a portion of an electrode arrangement that may be patterned on a substrate of a droplet actuator (not shown). The invention provides a an algorithm for and method of automatically generating droplet actuator description files by analyzing digital images, such as, but not limited to, JPG (or JPEG), BMP, and TIFF images. The digital images may be acquired using any standard digital image capture devices, such as any digital camera that has suitable resolution.

When generating a program for controlling assay protocols in droplet actuators, droplet actuator description files are used to describe the contents, layout, and features of droplet actuators. For example, the description files specify what electrodes exist on the droplet actuator, their I/Os, their geometries, their types, their location, and their neighboring electrodes. Currently, these description files are large XML files that are extremely difficult to create manually. Consequently, tools are used to create these files automatically. For example, one tool uses a Microsoft® Excel spreadsheet as a tool for generating the description files. However, this method is limited because electrode geometry and electrode type information has to be added manually. Additionally, this process does not support droplet actuator layouts that don't fit nicely into a grid pattern, such as droplet actuators that have electrodes of different sizes and pitches.

The algorithm for and method of the invention of automatically generating droplet actuator description files by analyzing digital images substantially overcomes these limitations. For example, the algorithm for and method of the invention uses a digital image (e.g., digital image 2700) that represents the droplet actuator as input and uses automated image processing to automatically locate electrodes, determine their shape and location, and then automatically generate a droplet actuator description file that requires substantially no manual editing.

### Features of the Invention:

Finds electrodes represented in the image;
Determines the position and geometry of each electrode, storing off unique geometries as not to repeat common shapes;
Determines neighboring and “friend” (diagonal) electrodes and includes these relationships in the output; and
Determines which electrodes appear to be dispenser reservoirs and includes these “groups” in the output.

### Image Requirements of the Invention:

Black and white image*;
White background with black areas representing electrodes; and
Neighboring electrodes have exactly one (1) pixel of white background between them. Alternatively, electrodes may be colored—each color representing a unique pin assignment.

### Algorithm of the Invention:

1) Find all electrodes;
   Starting in one corner of the image (e.g., the upper left), the image is scanned pixel by pixel;
   When a black (electrode) pixel is first encountered, a flood fill is performed to find all pixels belonging to that electrode. All of these pixels are marked as “processed” and will not be considered anymore in this search step;
   An algorithm (e.g., standard image processing algorithms, such as edge detection, line detection, and/or boundary detection algorithms) is applied to the set of all pixels to leave only the perimeter pixels;
   An algorithm is applied to the set of perimeter pixels to leave only the vertices of the polygon, so a minimal set of pixels are maintained to keep the shape of the electrode;
   The vertex pixels are sorted by y and then x coordinate, and a lookup table is checked to see whether this shape has been seen before (common shapes are reused in the description file);
   The offset of this shape for this pixel is stored, so the position of the electrode is known; and
   This process is repeated to locate all electrodes.
2) Find neighbor relationships;
   The image is scanned again pixel by pixel;
   White pixels (background pixels) are examined to see whether the top/bottom neighbor are both black or the left/right neighbor are both black. In these cases, this white pixel is between two (or 4) neighboring electrodes;
   A lookup table is used to determine which electrodes are represented by those black pixels; and
   The two electrodes are marked as neighbors.
3) Find friend relationships;
   For each electrode E:
      Examine all pairs (A, B) of this electrode's neighbors; and
      If the orientation (horizontal or vertical, as determined by comparing the center coordinates of each electrode) of (A, E) does not match the orientation of (B, E)—(i.e., both vertical or both horizontal), then E forms a corner with A and B—therefore, A and B are “friends” on a diagonal.
4) Find reservoirs; and
   Electrodes with a pixel area greater than some threshold that have exactly one neighbor are considered to be reservoir electrodes.
5) Generate output.
The data model built up by the previous processes is fed to a template that generates the final XML output.

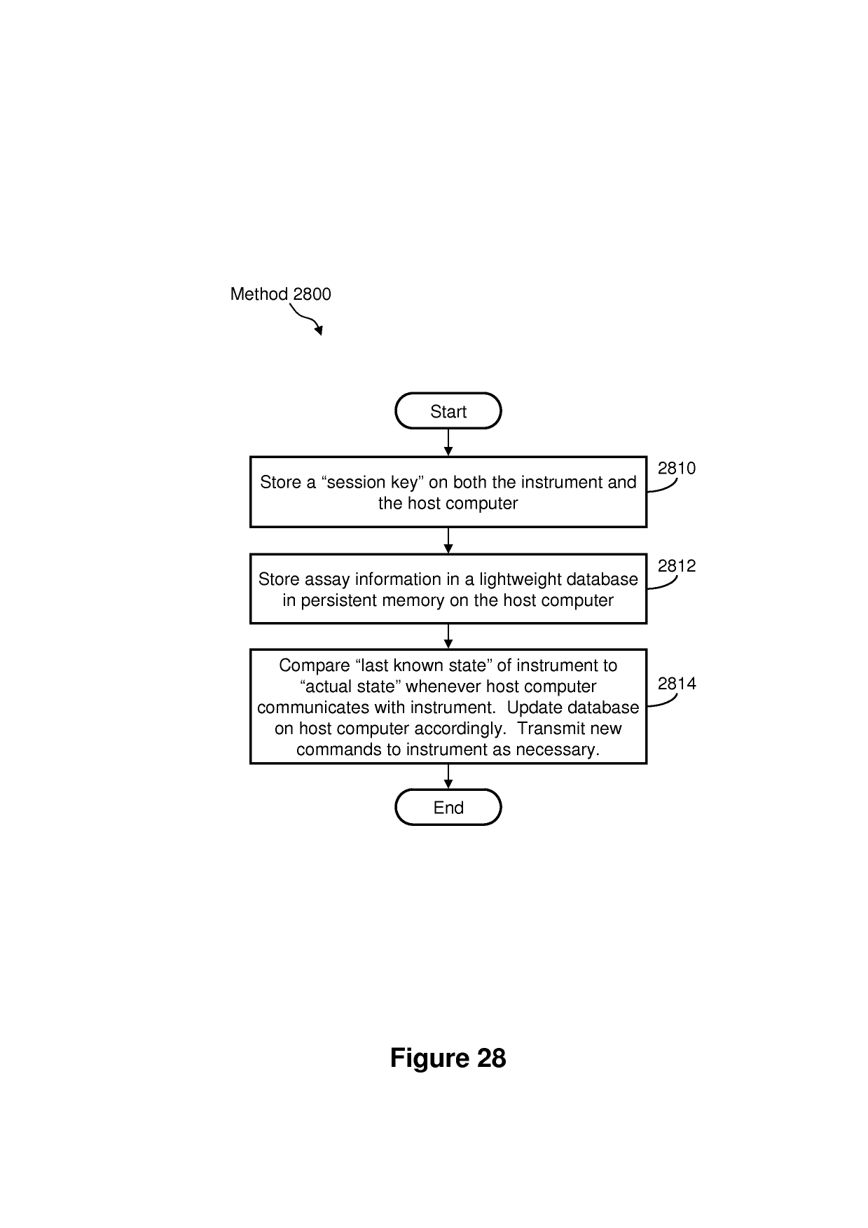

FIG. 28 illustrates a flow diagram of an example of a method 2800 of handling instrument/computer communication interruptions in a microfluidics system. Currently, software implementations with respect to microfluidics systems require a continuous communication link between, for example, a host computer and the instrument. For example, if the computer application is accidentally closed, the host computer crashes, the host computer loses power while the instrument is running a program, the software is accidently closed by the user, the USB cable is unplugged, and the like, there may be loss of assay data. Accordingly, the method of the invention provides a method of handling instrument/computer communication interruptions without loss of assay data. The method of the invention is facilitated by maintaining a database of instrument/assay information on the host computer. Method 2800 may include, but is not limited to, the following steps.

At step 2810, a “session key” is stored on both the instrument and the host computer.

At step 2812, assay information is stored in a database, e.g., a lightweight database in persistent memory (e.g., hard drive) on the host computer.

At step 2814, the “last known state” of the instrument is compared to the “actual state” of the instrument whenever the host computer communicates with the instrument. The database on the host computer is then updated accordingly. New commands are transmitted to the instrument as necessary.

In summary, method 2800 of the invention provides a means for the software to resume where it left off by re-establishing a connection to the instrument, asking the instrument what program/work unit it is running, and reading any results from the instrument.

By use of method 2800 of the invention, a persistent connection is no longer needed. For example, the host computer may be connected/updated/disconnected at a scheduled interval. Further, the instrument/computer interface is more robust than current scenarios. Additionally, assay data is not lost unless the instrument itself loses power.

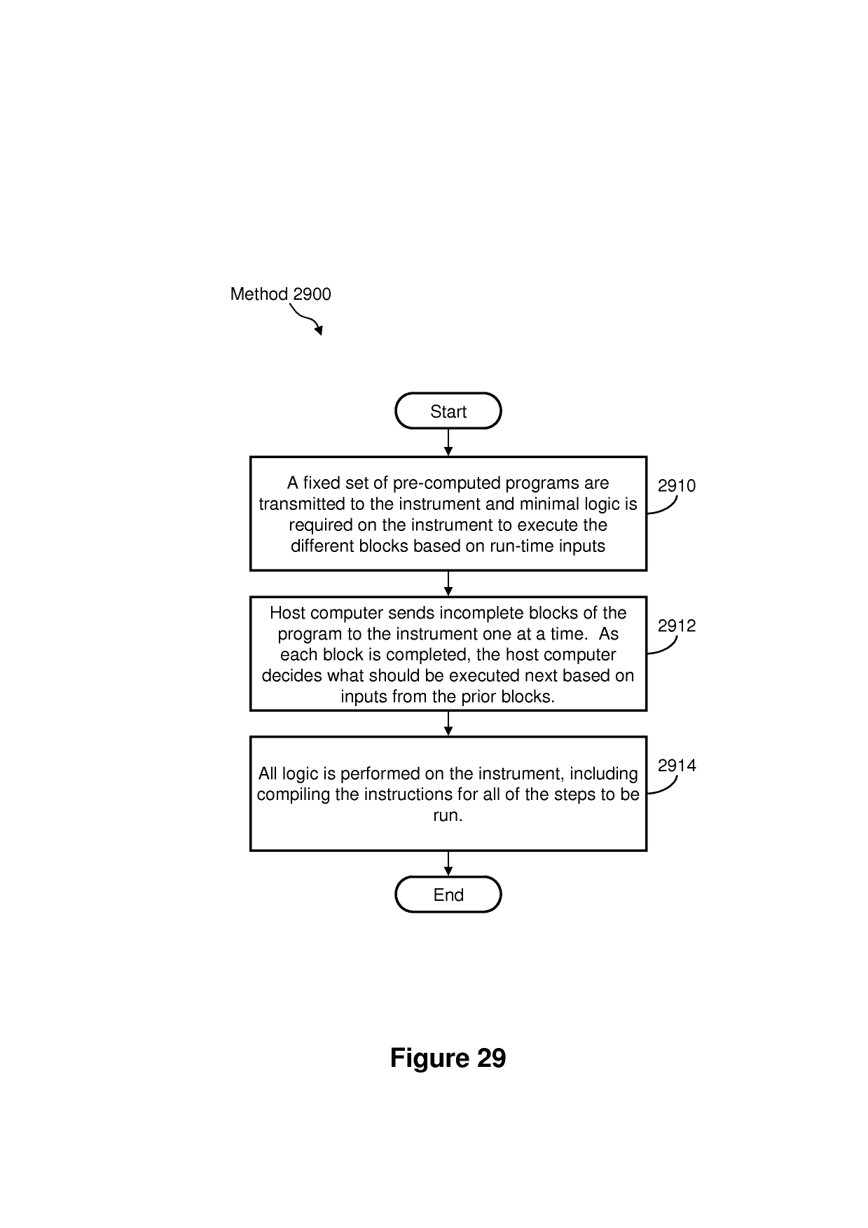

FIG. 29 illustrates a flow diagram of an example of a method 2900 of executing conditional droplet operations actions in a microfluidics system based on inputs at run-time. Current programming models are limited to running static programs that are completely determined at compile-time. For example, conditional branching is not supported. Accordingly, the invention provides a method of executing conditional droplet operations actions in a microfluidics system based on inputs at run-time. Method 2900 may include, but is not limited to, the following steps.

At step 2910, a fixed set of pre-computed programs are transmitted to the instrument and minimal logic is required on the instrument to execute the different blocks based on run-time inputs.

At step 2912, the host computer sends incomplete blocks of the program to the instrument one at a time. As each block is completed, the host computer decides what should be executed next based on inputs from the prior blocks.

At step 2914, all logic is performed on the instrument, including compiling the instructions for all of the steps to be run.

Use cases may benefit from the capability to execute conditional droplet operations actions in a microfluidics system according to the invention. Examples of uses cases that may benefit include, but are not limited to, the following.
Re-try dispense if a droplet is not detected via impedance measurement, or is detected to be of incorrect volume.
Execute a lane clean-up procedure if a droplet malfunction is detected in a localized area on the droplet actuator.
Perform extra actions if a droplet is detected at a level (e.g., fluorescence level, chemiluminescence level, etc.)
Re-route droplets if bubbles/obstructions/malfunctioning electrodes are detected.

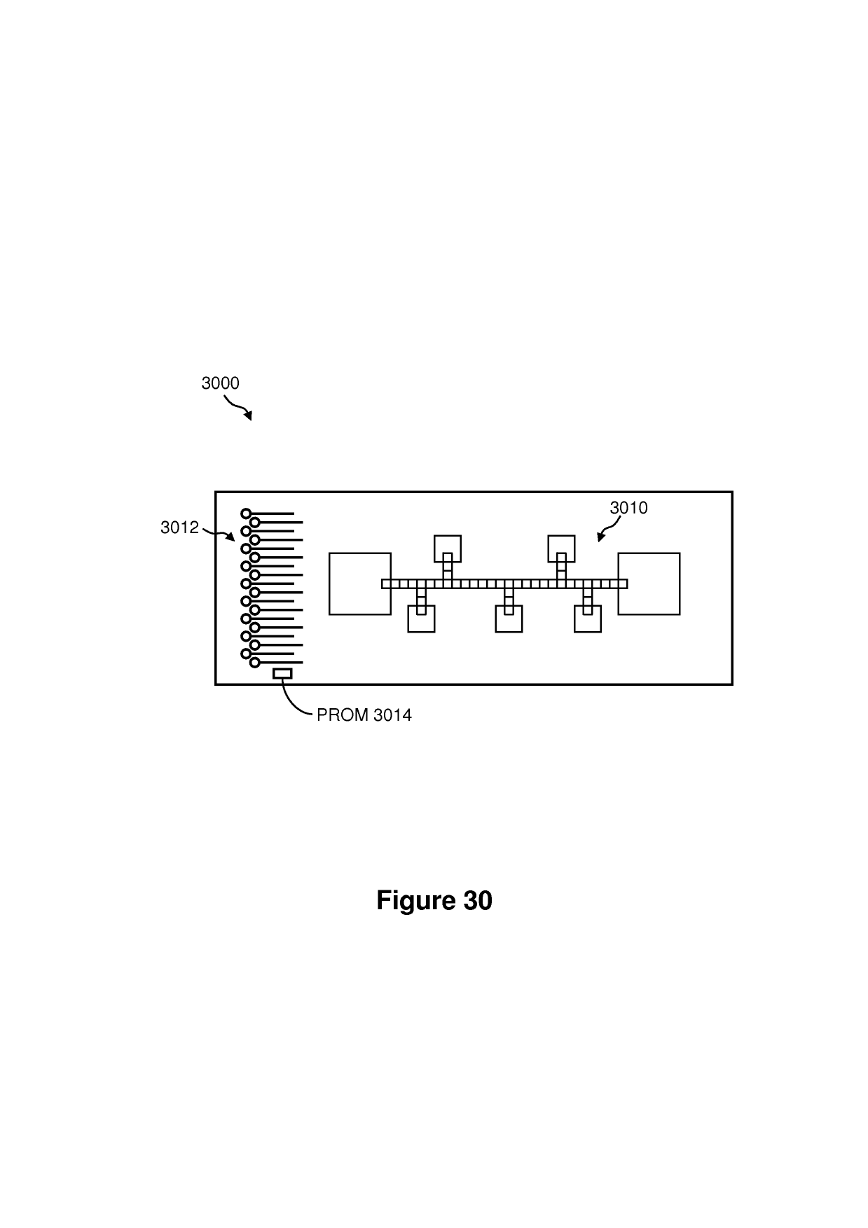

FIG. 30 illustrates a top view of an example of a substrate 3000 of a droplet actuator (not shown) that includes a mechanism for indicating a droplet actuator end-of-life condition. In this example, substrate 3000 is a PCB that includes an electrode arrangement 3010 and control channels 3012. Control channels 3012 are used for controlling the electrode arrangement 3010, such as for applying electrowetting voltages. Currently, the safeguards for preventing the unauthorized re-use of droplet actuators are inadequate. What is needed are better techniques for ensuring that droplet actuators are only used in a way that is compliant with established standards and/or regulations. Accordingly, the invention provides a mechanism for indicating a droplet actuator end-of-life condition in a manner that is easily detectable and substantially irreversible.

For example, substrate 3000 may include a mechanism for indicating a droplet actuator end-of-life condition. In one example, this mechanism is a fuse 3014. Fuse 3014 may be implemented, for example, as a thin copper trace. The invention is not limited to installing fuse 3014 on substrate 3000. In another embodiment, fuse 3014 may be provided on the top substrate (not shown) that is associated with substrate 3000.

The state of fuse 3014 may be machine-readable (e.g., using capacitance detection) by an external computing device. In this example, the “not blown” state of fuse 3014 indicates a ready-for-use condition of a droplet actuator. By contrast, the “blown” state of fuse 3014 indicates the end-of-life condition of a droplet actuator. The presence of the end-of-life condition based on the state of fuse 3014 may be used to electronically invalidate droplet actuators with the intention of preventing re-use for reasons of support and regulatory compliance. Substrate 3000 (or its corresponding top substrate) may be connected to the instrument through fuse 3014 that may be selectively and irreversibly burned (or blown) by the instrument hardware in order to render the droplet actuator useless upon the completion of a protocol. Fuse 3014 is simple and very inexpensive to implement. Additionally, fuse 3014 may be placed on the bottom or top substrate such that it is substantially impossible to replace without physically destroying the droplet actuator.

### 7.5 Systems

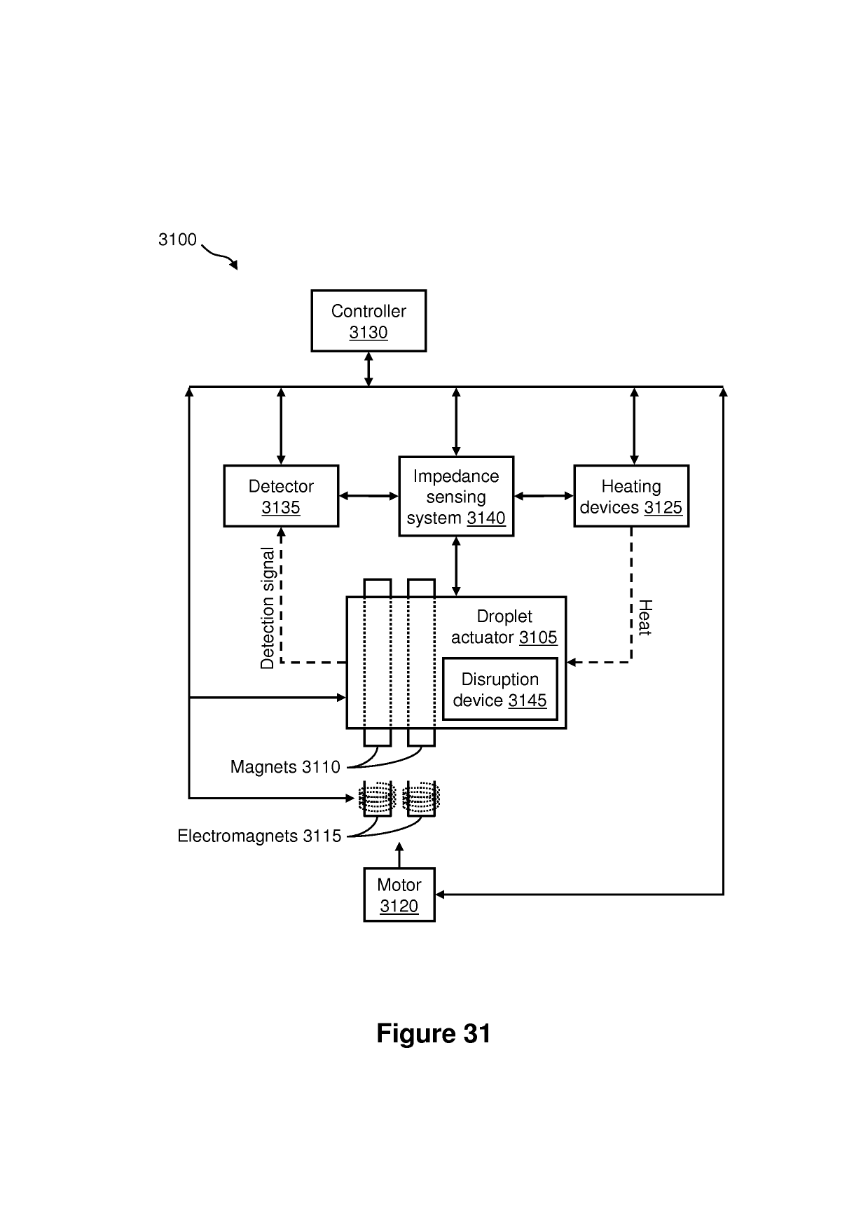

FIG. 31 illustrates a functional block diagram of an example of a microfluidics system 3100 that includes a droplet actuator 3105. Digital microfluidic technology conducts droplet operations on discrete droplets in a droplet actuator, such as droplet actuator 3105, by electrical control of their surface tension (electrowetting). The droplets may be sandwiched between two substrates of droplet actuator 3105, a bottom substrate and a top substrate separated by a droplet operations gap. The bottom substrate may include an arrangement of electrically addressable electrodes. The top substrate may include a reference electrode plane made, for example, from conductive ink or indium tin oxide (ITO). The bottom substrate and the top substrate may be coated with a hydrophobic material. The space around the droplets (i.e., the droplet operations gap between bottom and top substrates) may be filled with an immiscible inert fluid, such as silicone oil, to prevent evaporation of the droplets and to facilitate their transport within the device. Other droplet operations may be effected by varying the patterns of voltage activation; examples include merging, splitting, mixing, and dispensing of droplets.

Droplet actuator 3105 may be designed to fit onto an instrument deck (not shown) of microfluidics system 3100. The instrument deck may hold droplet actuator 3105 and house other droplet actuator features, such as, but not limited to, one or more magnets and one or more heating devices. For example, the instrument deck may house one or more magnets 3110, which may be permanent magnets. Optionally, the instrument deck may house one or more electromagnets 3115. Magnets 3110 and/or electromagnets 3115 are positioned in relation to droplet actuator 3105 for immobilization of magnetically responsive beads. Optionally, the positions of magnets 3110 and/or electromagnets 3115 may be controlled by a motor 3120. Additionally, the instrument deck may house one or more heating devices 3125 for controlling the temperature within, for example, certain reaction and/or washing zones of droplet actuator 3105. In one example, heating devices 3125 may be heater bars that are positioned in relation to droplet actuator 3105 for providing thermal control thereof.

A controller 3130 of microfluidics system 3100 is electrically coupled to various hardware components of the invention, such as droplet actuator 3105, electromagnets 3115, motor 3120, and heating devices 3125, as well as to a detector 3135, an impedance sensing system 3140, and any other input and/or output devices (not shown). Controller 3130 controls the overall operation of microfluidics system 3100. Controller 3130 may, for example, be a general purpose computer, special purpose computer, personal computer, or other programmable data processing apparatus. Controller 3130 serves to provide processing capabilities, such as storing, interpreting, and/or executing software instructions, as well as controlling the overall operation of the system. Controller 3130 may be configured and programmed to control data and/or power aspects of these devices. For example, in one aspect, with respect to droplet actuator 3105, controller 3130 controls droplet manipulation by activating/deactivating electrodes.

In one example, detector 3135 may be an imaging system that is positioned in relation to droplet actuator 3105. In one example, the imaging system may include one or more light-emitting diodes (LEDs) (i.e., an illumination source) and a digital image capture device, such as a charge-coupled device (CCD) camera.

Impedance sensing system 3140 may be any circuitry for detecting impedance at a specific electrode of droplet actuator 3105. In one example, impedance sensing system 3140 may be an impedance spectrometer. Impedance sensing system 3140 may be used to monitor the capacitive loading of any electrode, such as any droplet operations electrode, with or without a droplet thereon. For examples of suitable capacitance detection techniques, see Sturmer et al., International Patent Publication No. WO/2008/101194, entitled “Capacitance Detection in a Droplet Actuator,” published on Aug. 21, 2008; and Kale et al., International Patent Publication No. WO/2002/080822, entitled “System and Method for Dispensing Liquids,” published on Oct. 17, 2002; the entire disclosures of which are incorporated herein by reference.

Droplet actuator 3105 may include disruption device 3145. Disruption device 3145 may include any device that promotes disruption (lysis) of materials, such as tissues, cells and spores in a droplet actuator. Disruption device 3145 may, for example, be a sonication mechanism, a heating mechanism, a mechanical shearing mechanism, a bead beating mechanism, physical features incorporated into the droplet actuator 3105, an electric field generating mechanism, a thermal cycling mechanism, and any combinations thereof. Disruption device 3145 may be controlled by controller 3130.

It will be appreciated that various aspects of the invention may be embodied as a method, system, computer readable medium, and/or computer program product. Aspects of the invention may take the form of hardware embodiments, software embodiments (including firmware, resident software, micro-code, etc.), or embodiments combining software and hardware aspects that may all generally be referred to herein as a “circuit,” “module” or “system.” Furthermore, the methods of the invention may take the form of a computer program product on a computer-usable storage medium having computer-usable program code embodied in the medium.

Any suitable computer useable medium may be utilized for software aspects of the invention. The computer-usable or computer-readable medium may be, for example but not limited to, an electronic, magnetic, optical, electromagnetic, infrared, or semiconductor system, apparatus, device, or propagation medium. The computer readable medium may include transitory and/or non-transitory embodiments. More specific examples (a non-exhaustive list) of the computer-readable medium would include some or all of the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission medium such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device.

Program code for carrying out operations of the invention may be written in an object oriented programming language such as Java, Smalltalk, C++ or the like. However, the program code for carrying out operations of the invention may also be written in conventional procedural programming languages, such as the “C” programming language or similar programming languages. The program code may be executed by a processor, application specific integrated circuit (ASIC), or other component that executes the program code. The program code may be simply referred to as a software application that is stored in memory (such as the computer readable medium discussed above). The program code may cause the processor (or any processor-controlled device) to produce a graphical user interface (“GUI”). The graphical user interface may be visually produced on a display device, yet the graphical user interface may also have audible features. The program code, however, may operate in any processor-controlled device, such as a computer, server, personal digital assistant, phone, television, or any processor-controlled device utilizing the processor and/or a digital signal processor.

The program code may locally and/or remotely execute. The program code, for example, may be entirely or partially stored in local memory of the processor-controlled device. The program code, however, may also be at least partially remotely stored, accessed, and downloaded to the processor-controlled device. A user's computer, for example, may entirely execute the program code or only partly execute the program code. The program code may be a stand-alone software package that is at least partly on the user's computer and/or partly executed on a remote computer or entirely on a remote computer or server. In the latter scenario, the remote computer may be connected to the user's computer through a communications network.

The invention may be applied regardless of networking environment. The communications network may be a cable network operating in the radio-frequency domain and/or the Internet Protocol (IP) domain. The communications network, however, may also include a distributed computing network, such as the Internet (sometimes alternatively known as the “World Wide Web”), an intranet, a local-area network (LAN), and/or a wide-area network (WAN). The communications network may include coaxial cables, copper wires, fiber optic lines, and/or hybrid-coaxial lines. The communications network may even include wireless portions utilizing any portion of the electromagnetic spectrum and any signaling standard (such as the IEEE 802 family of standards, GSM/CDMA/TDMA or any cellular standard, and/or the ISM band). The communications network may even include powerline portions, in which signals are communicated via electrical wiring. The invention may be applied to any wireless/wireline communications network, regardless of physical componentry, physical configuration, or communications standard(s).

Certain aspects of invention are described with reference to various methods and method steps. It will be understood that each method step can be implemented by the program code and/or by machine instructions. The program code and/or the machine instructions may create means for implementing the functions/acts specified in the methods.

The program code may also be stored in a computer-readable memory that can direct the processor, computer, or other programmable data processing apparatus to function in a particular manner, such that the program code stored in the computer-readable memory produce or transform an article of manufacture including instruction means which implement various aspects of the method steps.

The program code may also be loaded onto a computer or other programmable data processing apparatus to cause a series of operational steps to be performed to produce a processor/computer implemented process such that the program code provides steps for implementing various functions/acts specified in the methods of the invention.

### 8 CONCLUDING REMARKS

The foregoing detailed description of embodiments refers to the accompanying drawings, which illustrate specific embodiments of the invention. Other embodiments having different structures and operations do not depart from the scope of the present invention. The term “the invention” or the like is used with reference to specific examples of the many alternative aspects or embodiments of the applicants' invention set forth in this specification, and neither its use nor its absence is intended to limit the scope of the applicants' invention or the scope of the claims. This specification is divided into sections for the convenience of the reader only. Headings should not be construed as limiting of the scope of the invention. The definitions are intended as a part of the description of the invention. It will be understood that various details of the present invention may be changed without departing from the scope of the present invention. Furthermore, the foregoing description is for the purpose of illustration only, and not for the purpose of limitation.

1-37. (canceled)

38. A method of transporting a droplet, the method comprising:
(a) providing a droplet at a charged electrode on a droplet actuator;
(b) attempting to transport the droplet away from the charged electrode;
(c) determining one or more transport characteristics of the droplet comprising the time from initiation of the attempting step until the droplet is successfully transported away from the charged electrode and/or one or more electrical properties required to successfully transport the droplet away from the charged electrode; and
(d) correlating the one or more transport characteristics of the droplet with a physical or chemical property of the droplet.

39. The method of claim 38, wherein step (b) comprises activating an adjacent electrowetting electrode while deactivating the charged electrode.

40. The method of claim 38, wherein step (b) comprises dielectrophoretic transport of the droplet.

41. The method of claim 38, further comprising changing the temperature of the droplet during step (b).

42. The method of claim 38, wherein step (b) comprises activating an adjacent electrowetting electrode while discharging the charged electrode.

43. The method of claim 39 wherein the activating comprises gradually increasing voltage at the adjacent electrode, and the method further comprises measuring the voltage at which the droplet is successfully transported away from the charged electrode.

44. The method of claim 38, wherein (c) comprises monitoring impedance at a position on the droplet actuator which is adjacent to the charged electrode.

45. The method of claim 38, wherein the timing of transport is correlated with a physical or chemical property of the droplet.

46. The method of claim 38, wherein one or more electrical characteristics required to induce transport is/are correlated with a physical or chemical property of the droplet.

47. (canceled)

48. The method of claim 38, wherein the droplet comprises an assay droplet.

49. The method of claim 38, wherein the one or more electrical properties comprise voltage applied to the adjacent electrode.

50. The method of claim 38, wherein the one or more electrical properties comprise amperage applied to the adjacent electrode.

51. The method of claim 38, wherein the one or more electrical properties comprise one or more specific electrical waveforms applied to the adjacent electrode.

52.-63. (canceled)
